(19) United States
(12) Patent Application Publication
(10) Pub. No.: US 2024/0327703 A1
(43) Pub. Date: Oct. 3, 2024

(54) IRIDIUM COMPLEX, ORGANIC LIGHT EMITTING ELEMENT, DISPLAY DEVICE, IMAGING DEVICE, ELECTRONIC DEVICE, LIGHTING DEVICE, AND MOVING BODY

(71) Applicant: CANON KABUSHIKI KAISHA, Tokyo (JP)

(72) Inventors: KATSUYUKI HOTTA, Kanagawa (JP); YUTO ITO, Tokyo (JP); Yuka KIMURA, Fukui (JP)

(21) Appl. No.: 18/680,443

(22) Filed: May 31, 2024

Related U.S. Application Data
(63) Continuation of application No. PCT/JP2022/041935, filed on Nov. 10, 2022.

(30) Foreign Application Priority Data
Dec. 3, 2021 (JP) 2021-197120

(51) Int. Cl. C09K 11/06; C09D 5/22; H10K 50/115; H10K 85/30; H10K 101/10

(52) U.S. Cl. CPC C09K 11/06; C09D 5/22; H10K 50/115; H10K 85/342; C09K 2211/185; H10K 2101/10

(57) ABSTRACT

The present disclosure provides an iridium complex represented by General Formula [1] or [2].

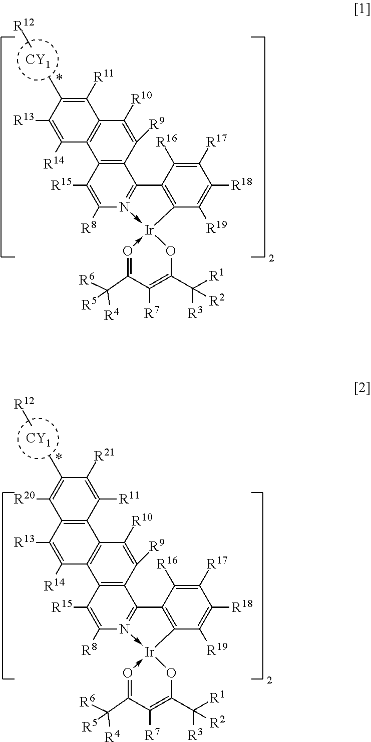

In General Formulae [1] and [2], R¹ to R²¹ each independently represent a hydrogen atom or a substituent. CY₁ represents a group represented by any of Chemical Formulae [3-1] to [3-3]. In Chemical Formulae [3-1] to [3-3], R²² to R²⁷ each independently represent a hydrogen atom or a substituent. X₁ to X₆ represent a carbon atom or a nitrogen atom.

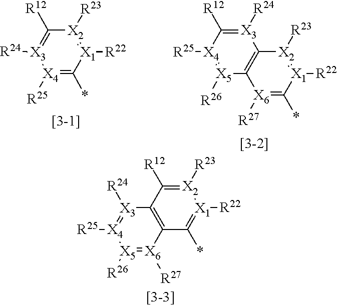

### CROSS-REFERENCE TO RELATED APPLICATIONS

This application is a Continuation of International Patent Application No. PCT/JP2022/041935, filed Nov. 10, 2022, which claims the benefit of Japanese Patent Application No. 2021-197120, filed Dec. 3, 2021, both of which are hereby incorporated by reference herein in their entirety.

### TECHNICAL FIELD

The present disclosure relates to an iridium complex with high durability, and an organic light emitting element, a display device, an imaging device, an electronic device, a lighting device, and a moving body, which contain the iridium complex.

### BACKGROUND ART

An organic light emitting element (also referred to as “organic electroluminescence element” (organic EL element)) is an electron element including a pair of electrodes and an organic compound layer disposed between these electrodes. When electrons and positive holes are injected from the pair of these electrodes, excitons of a light emitting organic compound in the organic compound layer are generated, and the organic light emitting element emits light in a case where the excitons return to a ground state.

The recent progress in organic light emitting elements is remarkable, and the organic light emitting elements have characteristics such as a low drive voltage, various emission wavelengths, high-speed responsiveness, and an ability to make light emitting devices thinner and lighter.

Recently, phosphorescence emission is suggested to be used as an attempt to improve emission efficiency of an organic EL element. An organic EL element that uses phosphorescence emission is expected to theoretically improve emission efficiency by about four times as compared with the improvement of emission efficiency in a case of using fluorescence emission. Therefore, phosphorescent organometallic complexes have been actively created until now. The reason for this is that creation of organometallic complexes with excellent light emitting properties is important in providing high-performance organic light emitting elements. Further, in recent years, alignment control of molecules of light emitting materials is also known to be important in order to improve light extraction efficiency of elements.

PTL 1 describes the following compound 1-a and PTL 2 describes the following compounds 2-a and 2-b, as organometallic complexes that have been created so far.

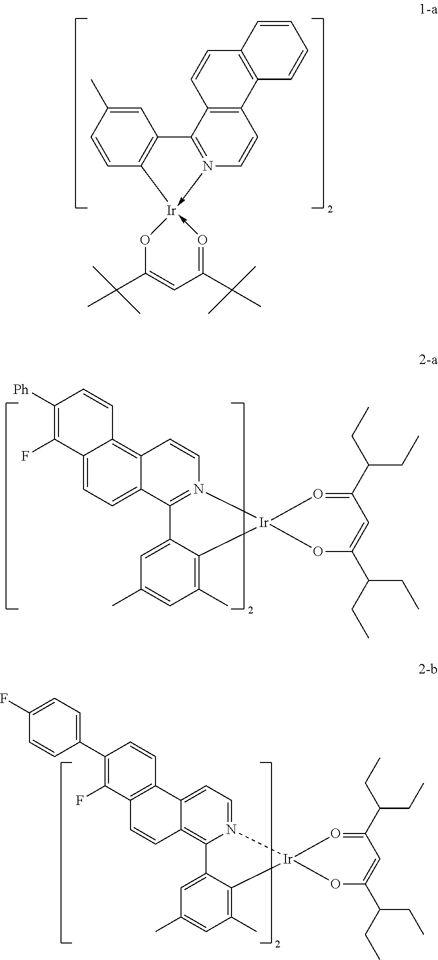

### CITATION LIST

### Patent Literature

PTL 1 Japanese Patent Laid-Open No. 2009-114137 PTL 2 Japanese Patent Laid-Open No. 2020-164863

The exemplary compounds described in PTL 1 are organometallic compounds having a main ligand with a benzoisoquinoline skeleton. In these exemplary compounds, since the molecular volume is small and the permanent dipole moment of molecules is large, there is room for improvement in the control of molecular aligning properties.

Further, the exemplary compounds described in PTL 2 are organometallic compounds having a main ligand that contains at least one fluoro group (—F) in a benzoisoquinoline skeleton or a C5-C60 carbocyclic ring or a C1-C60 heterocyclic group bonded in the form of Ir—C, and have a large permanent dipole moment, and accordingly, there is room for improvement in the control of molecular aligning properties.

### SUMMARY OF INVENTION

The present invention has been made in consideration of the above-described problems, and an object thereof is to provide an iridium complex with a small permanent dipole moment.

According to the present invention, there is provided an organic compound which is represented by the following general formulae.

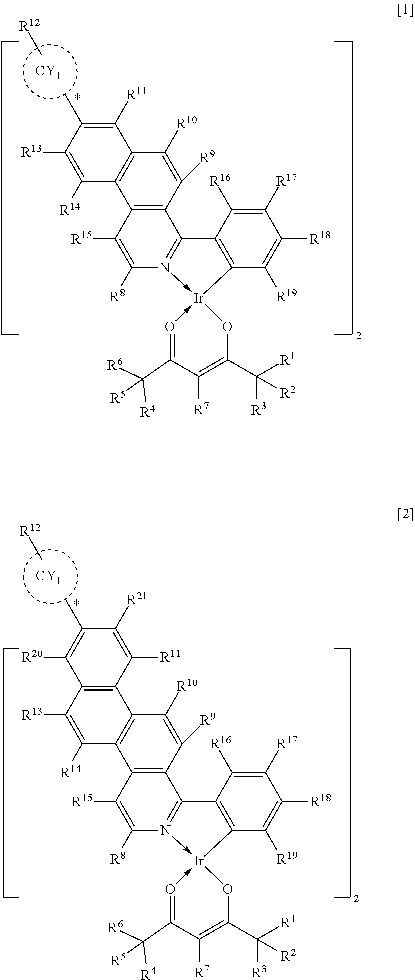

In General Formulae [1] and [2], R¹ to R²¹ each independently represent a hydrogen atom, a deuterium atom, a halogen atom, a substituted or unsubstituted alkyl group, a substituted or unsubstituted aryl group, a substituted or unsubstituted heterocyclic group, a substituted or unsubstituted alkoxy group, a substituted or unsubstituted aryloxy group, a substituted or unsubstituted amino group, a cyano group, or a silyl group. CY₁ represents a benzene ring (phenyl group), a naphthalene ring (naphthyl group), or a heterocyclic group having 4 to 10 carbon atoms. Further, CY₁ represents a group represented by any of Chemical Formulae [3-1] to [3-3].

In Chemical Formulae [3-1] to [3-3], R²² to R²⁷ each independently represent a hydrogen atom, a deuterium atom, a halogen atom, a substituted or unsubstituted alkyl group, a substituted or unsubstituted aryl group, a substituted or unsubstituted heterocyclic group, a substituted or unsubstituted alkoxy group, a substituted or unsubstituted aryloxy group, a cyano group, or a silyl group. X₁ to X₆ represent a carbon atom or a nitrogen atom.

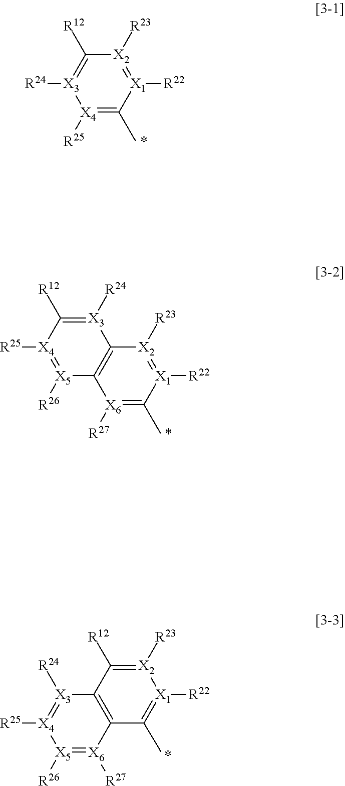

Further features of the present invention will become apparent from the following description of exemplary embodiments with reference to the attached drawings.

### BRIEF DESCRIPTION OF DRAWINGS

FIG. 1A is a schematic cross-sectional view showing an example of pixels of a display device according to an embodiment of the present invention.

FIG. 1B is a schematic cross-sectional view showing an example of a display device formed of an organic light emitting element according to an embodiment of the present invention.

FIG. 2 is a schematic view showing an example of a display device according to an embodiment of the present invention.

FIG. 3A is a schematic view showing an example of an imaging device according to an embodiment of the present invention.

FIG. 3B is a schematic view showing an example of an electronic device according to an embodiment of the present invention.

FIG. 4A is a schematic view showing an example of a display device according to an embodiment of the present invention.

FIG. 4B is a schematic view showing an example of a foldable display device.

FIG. 5A is a schematic view showing an example of a lighting device according to an embodiment of the present invention.

FIG. 5B is a schematic view showing an example of an automobile that includes a lamp for a vehicle according to an embodiment of the present invention.

FIG. 6A is a schematic view showing an example of a wearable device according to an embodiment of the present invention.

FIG. 6B is a schematic view showing an example of a wearable device in a form of having an imaging device according to an embodiment of the present invention.

### DESCRIPTION OF EMBODIMENTS

The present invention relates to an organic compound represented by the following general formulae.

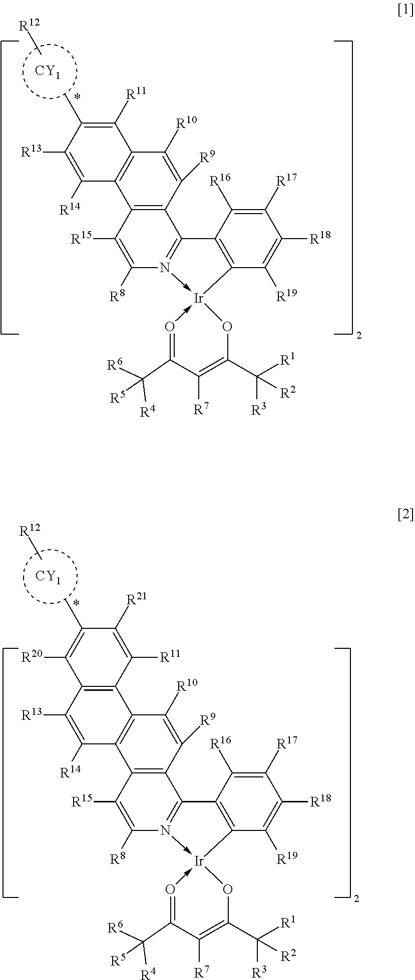

In General Formulae [1] and [2], R¹ to R²¹ each independently represent a hydrogen atom, a deuterium atom, a halogen atom, a substituted or unsubstituted alkyl group, a substituted or unsubstituted aryl group, a substituted or unsubstituted heterocyclic group, a substituted or unsubstituted alkoxy group, a substituted or unsubstituted aryloxy group, a substituted or unsubstituted amino group, a cyano group, or a silyl group.

CY₁ represents a group represented by any of Chemical Formulae [3-1] to [3-3]. In Chemical Formulae [3-1] to [3-3], R²² to R²⁷ each independently represent a hydrogen atom, a deuterium atom, a halogen atom, a substituted or unsubstituted alkyl group, a substituted or unsubstituted aryl group, a substituted or unsubstituted heterocyclic group, a substituted or unsubstituted alkoxy group, a substituted or unsubstituted aryloxy group, a substituted or unsubstituted amino group, a cyano group, or a silyl group. X₁ to X₆ represent a carbon atom or a

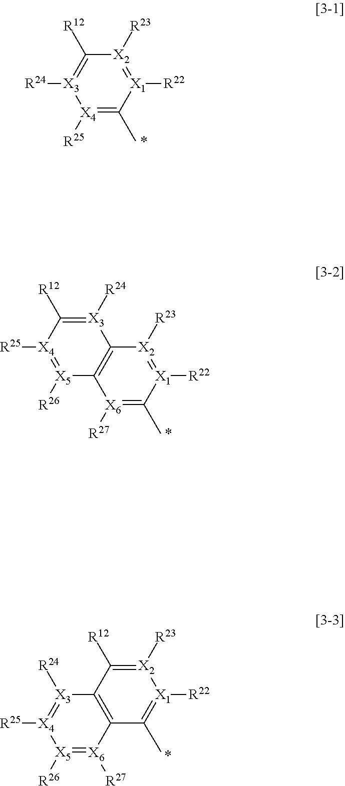

In the present specification, examples of the halogen atom include fluorine, chlorine, bromine, and iodine, but the present invention is not limited thereto.

In the present specification, examples of the alkyl group include an alkyl group having 1 to 10 carbon atoms, and an alkyl group having 1 to 8 carbon atoms is more preferable and an alkyl group having 1 to 4 carbon atoms is still more preferable. Specific examples thereof include a methyl group, an ethyl group, a normal propyl group, an isopropyl group, a normal butyl group, a tertiary butyl group, a secondary butyl group, an octyl group, a cyclopentyl group, a cyclohexyl group, a 1-adamantyl group, and a 2-adamantyl group, but the present invention is not limited thereto.

In the present specification, examples of the alkoxy group include an alkoxy group having 1 to 10 carbon atoms, and an alkoxy group having 1 or more and 6 or less carbon atoms is more preferable and an alkoxy group having 1 to 4 carbon atoms is still more preferable. Specific examples thereof include a methoxy group, an ethoxy group, a propoxy group, a 2-ethyl-hexyloxy group, and a benzyloxy group, but the present invention is not limited thereto.

In the present specification, examples of the amino group include unsubstituted amino groups and amino groups substituted with any of an alkyl group, an aryl group, and an amino group. The alkyl group, the aryl group, and the amino group may have a halogen atom as a substituent. The aryl group and the amino group may have an alkyl group as a substituent. The amino group and the substituted alkyl group may be bonded to each other to form a ring. Specific examples of the amino group include a N-methylamino group, a N-ethylamino group, a N,N-dimethylamino group, a N,N-diethylamino group, a N-methyl-N-ethylamino group, a N-benzylamino group, a N-methyl-N-benzylamino group, a N,N-dibenzylamino group, an anilino group, a N,N-diphenylamino group, a N,N-dinaphthylamino group, a N,N-difluorenylamino group, a N-phenyl-N-tolylamino group, a N,N-ditolylamino group, a N-methyl-N-phenylamino group, a N,N-dianisolylamino group, a N-mesityl-N-phenylamino group, a N,N-dimesitylamino group, a N-phenyl-N-(4-tert-butylphenyl)amino group, a N-phenyl-N-(4-trifluoromethylphenyl)amino group, and a N-piperidyl group, but the present invention is not limited thereto.

In the present specification, examples of the aryl group include an aryl group having 6 to 18 carbon atoms. Specific examples thereof include a phenyl group, a naphthyl group, an indenyl group, a biphenyl group, a terphenyl group, a fluorenyl group, a phenanthryl group, and a triphenylenyl group.

In the present specification, the heterocyclic group include a heterocyclic group having 3 to 15 carbon atoms. The heterocyclic group may have nitrogen, sulfur, or oxygen as a heteroatom. Specific examples thereof include a pyridyl group, a pyrazyl group, a pyrimidyl group, a triazyl group, an imidazolyl group, an oxazolyl group, an oxadiazolyl group, a thiazolyl group, a thiadiazolyl group, a carbazolyl group, an acridinyl group, a phenanthrolyl group, a furanyl group, a thiophenyl group, a dibenzofuranyl group, and a dibenzothiophenyl group, but the present invention is not limited thereto.

In the present specification, examples of the aryloxy group include a phenoxy group and a thienyloxy group, but the present invention is not limited thereto.

In the present specification, examples of the silyl group include a trimethylsilyl group and a triphenylsilyl group, but the present invention is not limited thereto.

The alkyl group, the alkoxy group, the amino group, the aryl group, the heterocyclic group, and the aryloxy group may have a halogen atom as a substituent. Examples of the halogen atom include fluorine, chlorine, bromine, and iodine. In addition, these groups may have a fluorine atom as a substituent. Particularly the alkyl group may be a trifluorinated methyl group by having a fluorine atom.

The amino group, the aryl group, the heterocyclic group, and the aryloxy group may have an alkyl group as a substituent. The alkyl group may have 1 to 10 carbon atoms. More specifically, the alkyl group may be a methyl group, an ethyl group, a normal propyl group, an isopropyl group, a normal butyl group, or a tertiary butyl group.

The alkyl group, the alkoxy group, the amino group, the aryl group, the heterocyclic group, and the aryloxy group may have an aryl group as a substituent. The aryl group may have 6 to 12 carbon atoms. More specifically, the aryl group may be a phenyl group, a biphenyl group, or a naphthyl group.

The alkyl group, the alkoxy group, the amino group, the aryl group, the heterocyclic group, and the aryloxy group may have a heterocyclic group as a substituent. The heterocyclic group may have 3 or more and 9 or less carbon atoms. The heterocyclic group may have nitrogen, sulfur, or oxygen as a heteroatom. More specifically, the heterocyclic group may be a pyridyl group or a pyrrolyl group.

The alkyl group, the alkoxy group, the amino group, the aryl group, the heterocyclic group, and the aryloxy group may have an amino group as a substituent. The amino group may have alkyl groups or aryl groups, and the alkyl groups may be bonded to each other to form a ring. Specific examples thereof include a dimethylamino group, a diethylamino group, a dibenzylamino group, a diphenylamino group, and a ditolylamino group.

The alkyl group, the alkoxy group, the amino group, the aryl group, the heterocyclic group, and the aryloxy group may have an aralkyl group such as a benzyl group, an alkoxy group such as a methoxy group, an ethoxy group, or a propoxy group, an aryloxy group such as a phenoxy, or a cyano group as a substituent. The substituent is not limited thereto.

### <<Iridium Complex According to Present Invention>>

The iridium complex according to the present invention has high molecular aligning properties of a light emitting material in a light emitting layer of an organic light emitting element and thus can improve the emission efficiency of an organic EL element. Here, the molecular alignment in the present invention denotes that the transition dipole moment of light emitting molecules (iridium complexes) doped into host molecules of the light emitting layer of the organic light emitting element is aligned in the horizontal direction with respect to a surface of a substrate of the organic light emitting element. In this case, the permanent dipole moment of the light emitting molecules is perpendicular to the substrate. Since the direction in which light is emitted from the light emitting molecules is mainly a direction perpendicular to the transition dipole moment of the molecules, optical loss due to a substrate mode, a waveguide mode, or a surface plasmon polariton mode is reduced in a case of a light emitting material with high molecular aligning properties, and thus an out-coupling mode (light extraction efficiency) is improved.

The present inventors have found that a light emitting material with a small permanent dipole moment in which the para-position with respect to the nitrogen atom (N) of a benzoisoquinoline ligand or a naphthoisoquinoline ligand is a benzene ring or a naphthalene ring, or a heterocyclic group has high molecular aligning properties in a light emitting layer of an organic light emitting element and has high emission efficiency.

The aligning properties of the light emitting molecules are considered to be determined by which of the two kinds of interactions, a nonpolar interaction and a polar interaction, working between the light emitting molecules and the host molecules is dominant. Here, the dipole-dipole interaction, which is a main factor of the polar interaction between the light emitting molecules and the host molecules, is represented by Equation [1].

$$E = \frac{1}{4 πϵ} \{ \frac{\vec{{μ}_{1}} \cdot \vec{{μ}_{2}}}{{\vert \vec{r} \vert}^{3}} - \frac{3 ( \vec{{μ}_{1}} \cdot \vec{r} ) ( \vec{{μ}_{2}} \cdot \vec{r} )}{{\vert \vec{r} \vert}^{5}} \} \qquad Equation [ 1 ]$$

Here, μ1, μ2, and r respectively represent the dipole moment of the light emitting molecules, the dipole moment of the host molecules, and the direction vector connecting the centers of gravity of both molecules. Therefore, the polar interaction between the light emitting molecules and the host molecules increases as the permanent dipole moment increases, but the polar interaction therebetween decreases as the molecular volume or the molecular weight of the light emitting molecules increases due to an increase in the intermolecular distance.

Further, the host molecules having a ring structure have a permanent dipole moment, and the permanent dipole moment and the ring structure are aligned horizontally to the surface of the substrate. In a case where the permanent dipole moment per volume or molecular weight of the light emitting molecules is large, the polar interaction dominantly works between the light emitting molecules and the host molecules. Therefore, the light emitting molecules are aligned such that the permanent dipole moment of the light emitting molecules and the permanent dipole moment of a plurality of the host molecules present in the periphery thereof are oriented in the same direction. That is, in a case where the light emitting molecules are used with host molecules having a ring structure, the permanent dipole moment of the light emitting molecules is horizontal to the surface of the substrate. That is, since the permanent dipole moment of the light emitting molecules is not perpendicular to the surface of the substrate, the proportion of the component in which the light extraction direction is not perpendicular to the substrate increases in the light emitting molecules. Meanwhile, in a case where the permanent dipole moment per volume or molecular weight of the light emitting molecules is small, the nonpolar interaction dominantly works between the light emitting molecules and the host molecules. In this case, the molecular alignment is determined such that the nonpolar interaction is maximized. In a case of the iridium complex according to the present invention, the light emitting molecules are aligned such that the ring structure of the host molecules and the benzoisoquinoline ligand or the naphthoisoquinoline ligand in the ligand which is the largest ring structure of the light emitting molecules are in parallel with each other. Since the transition dipole moment is in a direction connecting the iridium atom and the nitrogen atom of the benzoisoquinoline ligand or the naphthoisoquinoline ligand, that is, the transition dipole moment is in a direction horizontal to the iridium atom and the benzoisoquinoline ligand or the naphthoisoquinoline ligand, the transition dipole moment of the light emitting molecules in this case is aligned horizontally to the ring structure of the host molecules and the surface of the substrate. That is, the light emitting molecules are in a desired molecular alignment state, and the molecular aligning properties are high.

Therefore, high molecular aligning properties and high emission efficiency can be realized by using, as the light emitting material, the organic light emitting element formed of an organometallic compound represented by General Formula [1] or [2] as described above.

The permanent dipole moment of the iridium complex according to the present invention is particularly preferably 1.5 or less, and a light emitting material having a permanent dipole moment of 1.0 or less is more preferable. As a result of a decrease in the permanent dipole moment, the alignment degree is preferably 90% or greater and more preferably 92% or greater.

Here, the permanent dipole moment of the organometallic compound represented by General Formulae [1] and [2] can be determined by calculation based on a density functional theory in which the generic function is set to B3PW91 and the basis function is set to LANL2DZ. For example, the calculation can be carried out by using Gaussian 09, Revision D.01. The permanent dipole moment determined by calculation is also referred to as the permanent dipole moment calculation value. Gaussian 09, Revision D.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2013.

It has been found that the permanent dipole moment can be decreased by introducing a strong electron-withdrawing substituent to a specific position (R¹²) in the benzoisoquinoline skeleton represented by General Formula [1] and the naphthoisoquinoline skeleton represented by General Formula [2], and thus the emission efficiency can be further improved. The electron-withdrawing property can be expressed by a Hammett constant op, and the emission efficiency of the organic light emitting element can be improved by providing an electron-withdrawing substituent having a para Hammett constant op of 0.5 or greater. Among examples, —CF₃, —CN, —COF, —CF(CF₃)₂, —OCF₃, or —SiF₃ is preferable, and —CF₃ is particularly preferable.

Further, the benzoisoquinoline skeleton represented by General Formula [1] is preferable, and CY₁ represents preferably a benzene ring (phenyl group) or a naphthalene ring (naphthyl group) and more preferably a benzene ring (phenyl group).

In the iridium complex according to the present invention, R¹⁷ and R¹⁹ represent preferably a substituent or unsubstituted alkyl group, more preferably an alkyl group having 1 to 4 carbon atoms, and particularly preferably a methyl group. R¹ to R⁷ represent preferably a substituted or unsubstituted alkyl group and more preferably an alkyl group having 1 or more and 4 or less carbon atoms. Further, it is particularly preferable that R¹, R³, R⁴, and R⁶ each independently represent an ethyl group, R² and R⁵ each independently represent a methyl group, and R⁷ represents a hydrogen atom.

In consideration of the description above, an iridium complex represented by the following structural formula is particularly preferable.

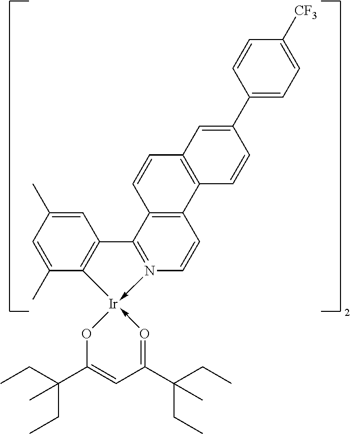

The iridium complex has CF₃ at the para-position as an electron-withdrawing substituent in the phenylbenzoisoquinoline skeleton having a benzene ring as a substituent and contains two methyl groups in the phenyl group bonded to an iridium atom. Further, the ligand having an oxygen atom, which is referred to as an auxiliary ligand, is provided with an ethyl group that is an alkyl group having 2 carbon atoms and a methyl group that is an alkyl group having 1 carbon atom. These alkyl groups may be substituted with hydrogen atoms. The emission efficiency of the element can be improved by providing a specific substituent at a position of a specific ligand as described above.

The iridium complex according to the present invention may be an ink composition used with a solvent. The solvent may be solvent that disperses or dissolves the iridium complex. The ink composition may have light emitting properties.

An embodiment of the present invention relates to an ink composition containing the iridium complex, a first organic compound, and a solvent. A host is preferable as the first organic compound. In a case where the host is a polymer, examples of the host include a block copolymer, a random copolymer, an alternating copolymer, and a graft copolymer. Examples of the solvent include a halogenated hydrocarbon-based solvent such as chloroform, dichloroethane, tetrachloroethane, chlorobenzene, or o-dichlorobenzene, an ether-based solvent such as tetrahydrofuran or ethylene glycol dimethyl ether, an aromatic hydrocarbon-based solvent such as toluene, xylene, or mesitylene, an aliphatic hydrocarbon-based solvent such as normal heptane, isoheptane, or methyl cyclohexane, a ketone-based solvent such as methyl ethyl ketone, 2-heptanone, or cyclohexanone, an ester-based solvent such as ethyl acetate, butyl acetate, γ-butyrolactone, or γ-valerolactone, a polyhydric alcohol-based solvent, an alcohol-based solvent, a sulfoxide-based solvent such as dimethyl sulfoxide or sulfolane, and an amide-based solvent such as N,N-dimethylformamide, N,N-dimethylacetamide, or 1-methyl-2-pyrrolidone. These organic solvents may be used alone or in combination of two or more kinds thereof. Among the organic solvents, from the viewpoint of easily obtaining a thin film with a uniform thickness, it is preferable to use an organic solvent having an appropriate evaporation rate and, specifically, an organic solvent having a boiling point of 70° C. to 200° C.

The ink composition can be used to form a film by a spin coating method, a bar coating method, a slit coating method, an ink jet method, a nozzle coating method, a casting method, a gravure printing method, or the like.

Hereinafter, examples of the iridium complex according to the present invention will be shown, but the present invention is not limited thereto.

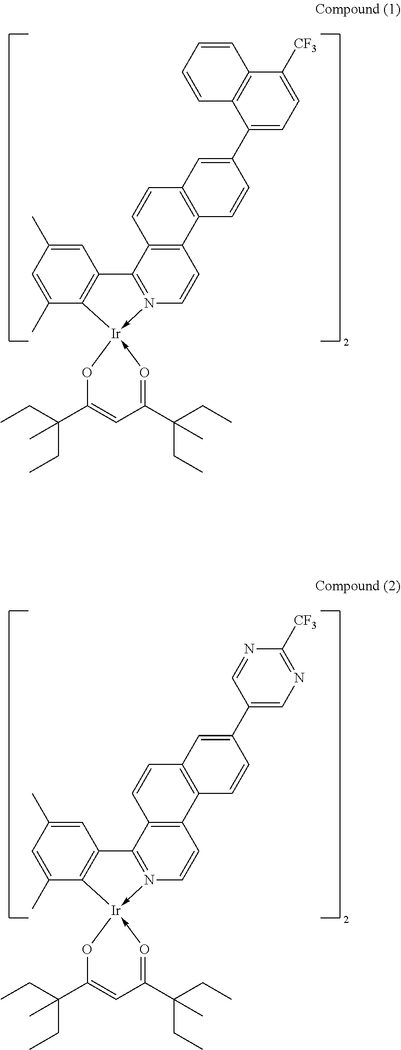

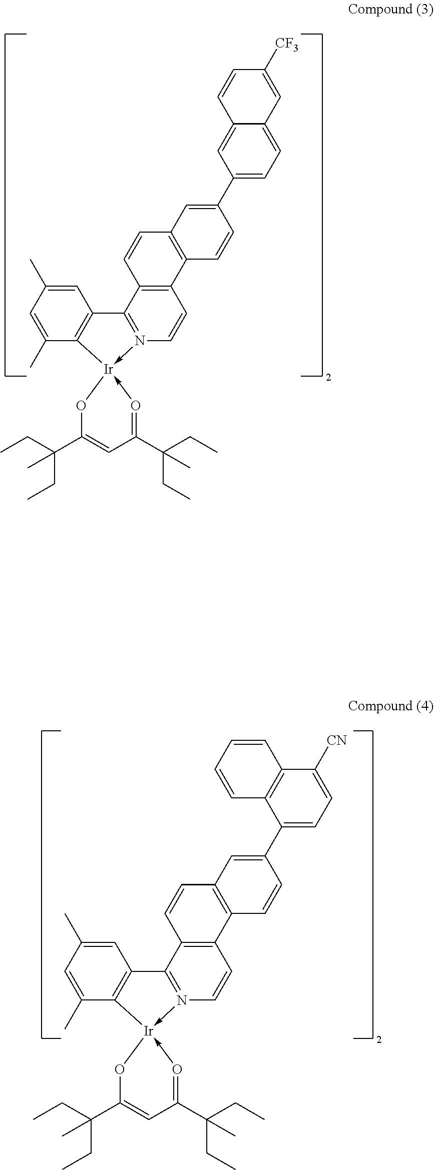

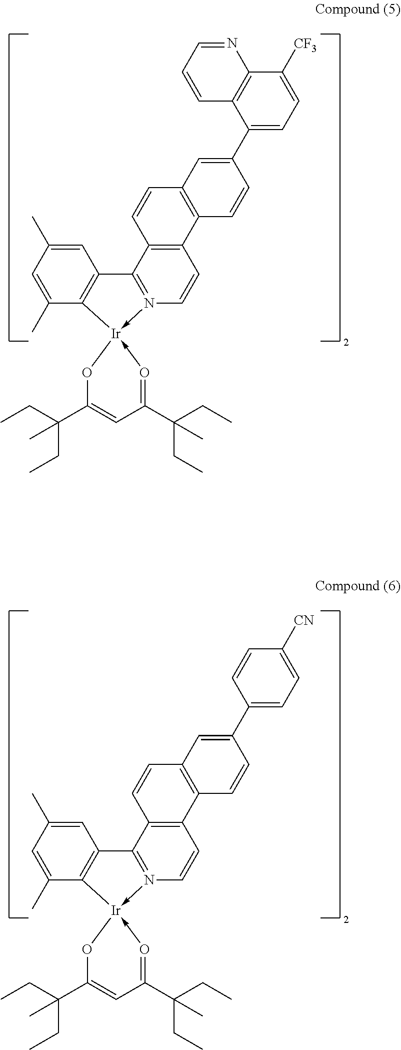

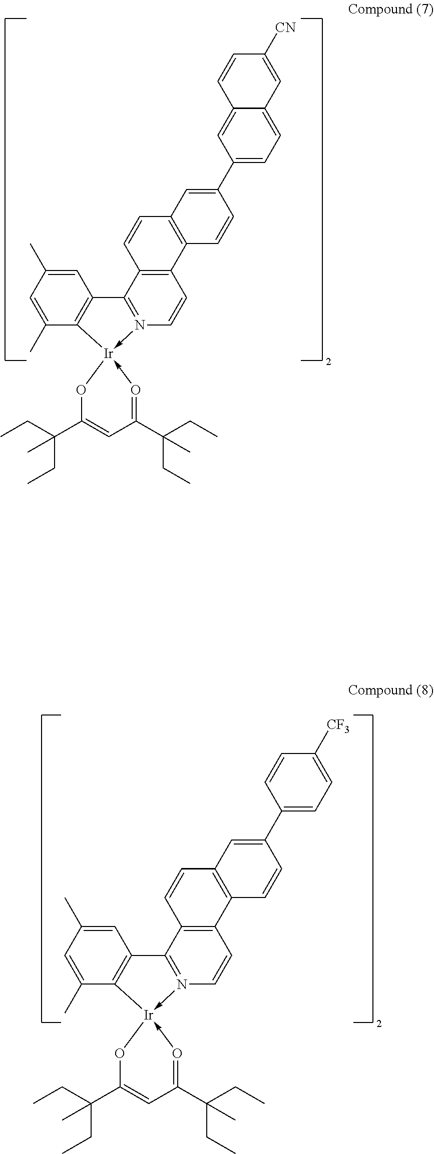

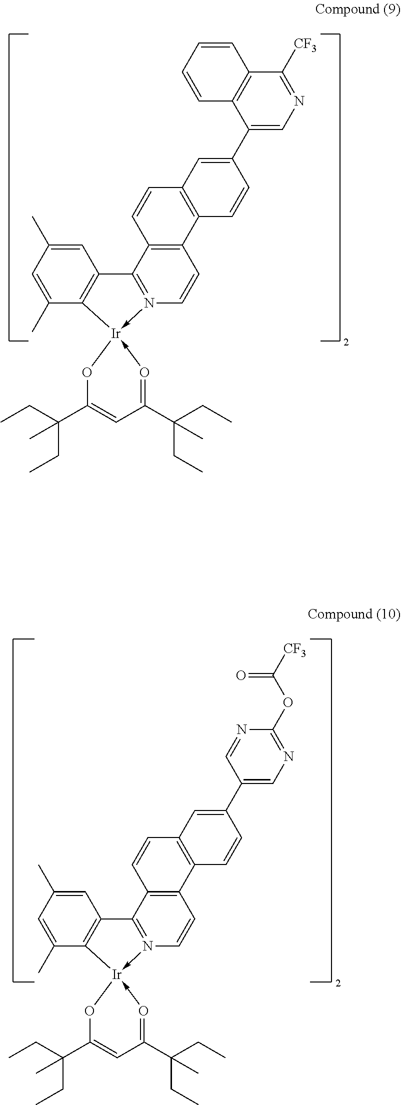

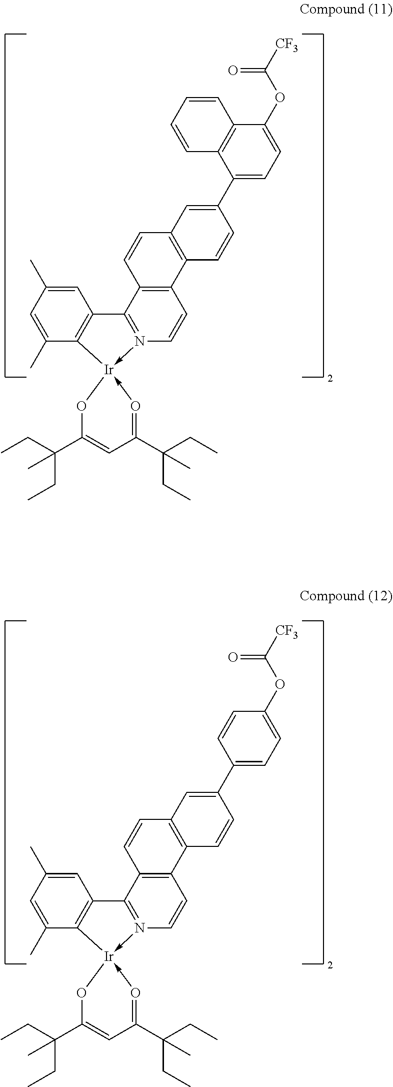

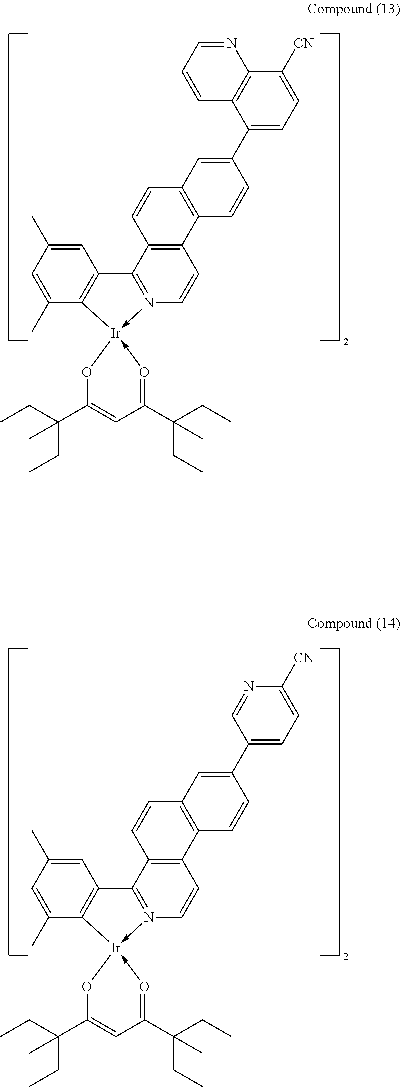

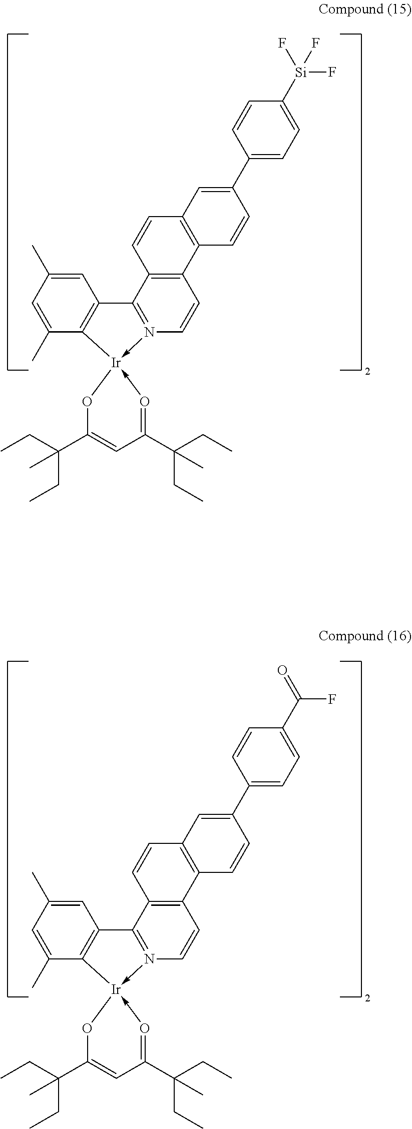

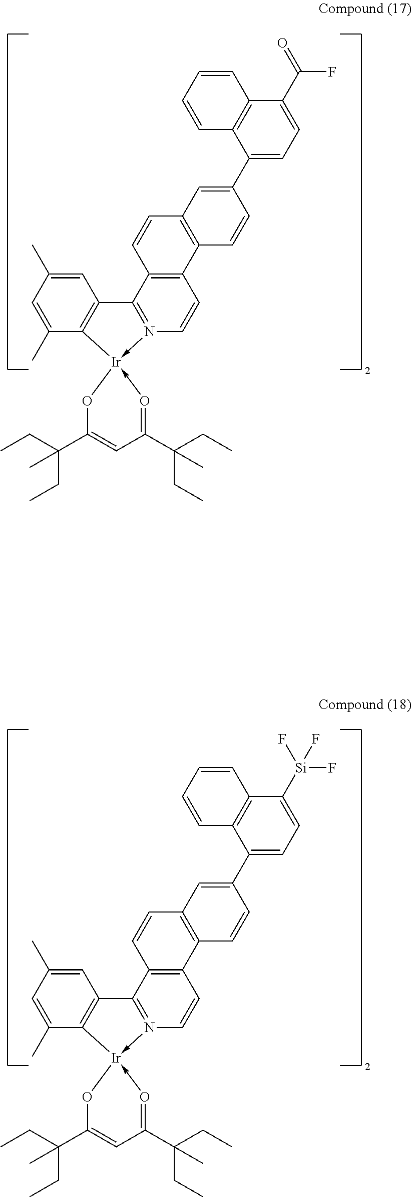

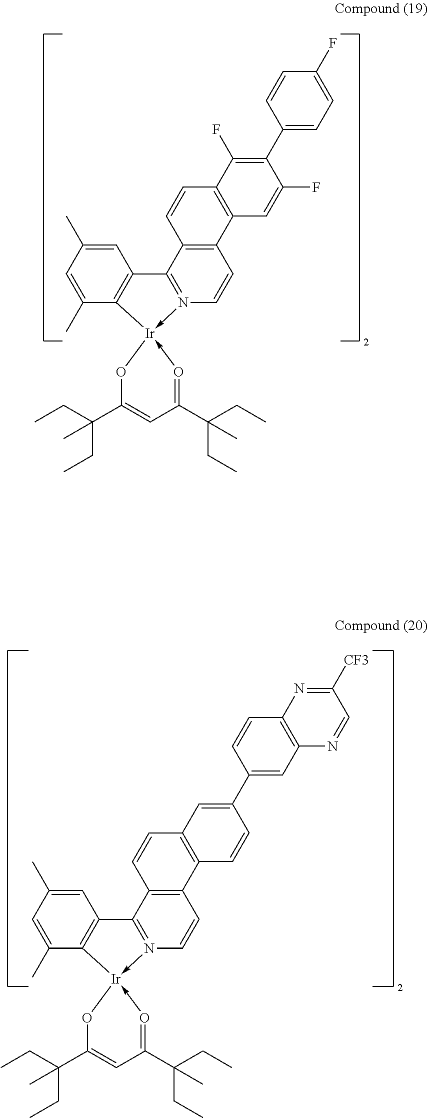

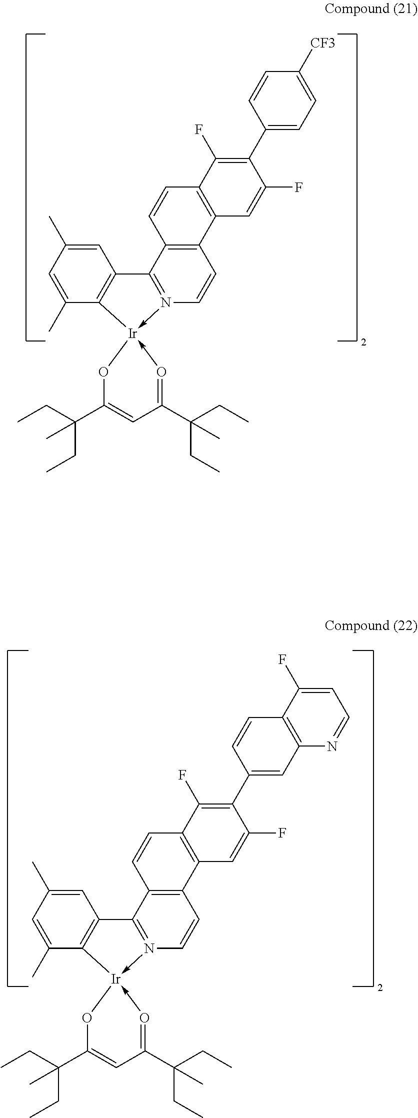

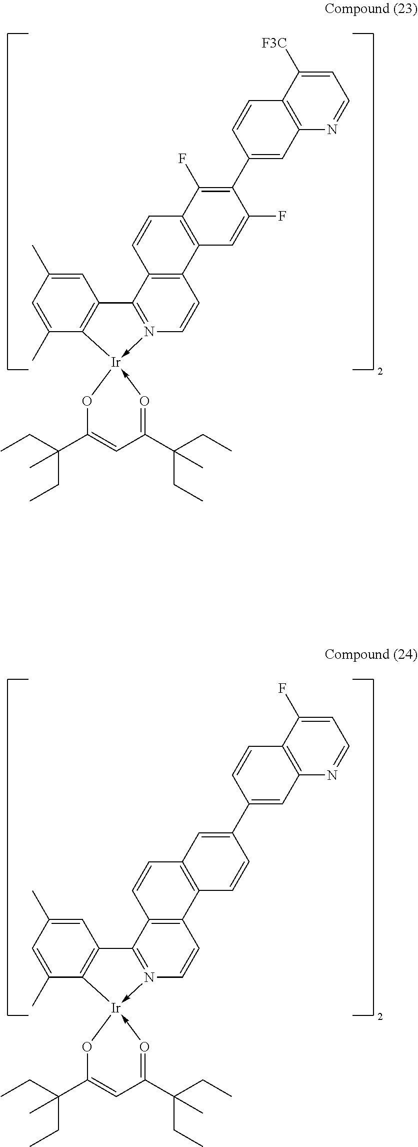

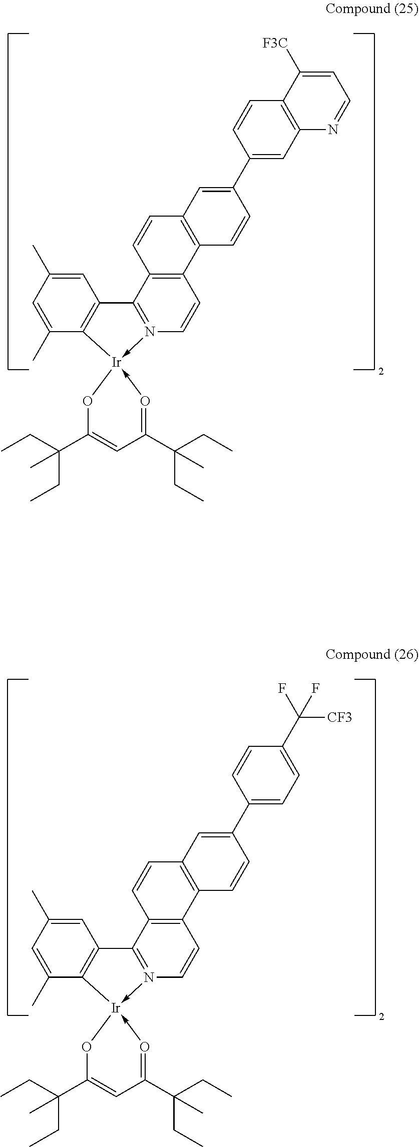

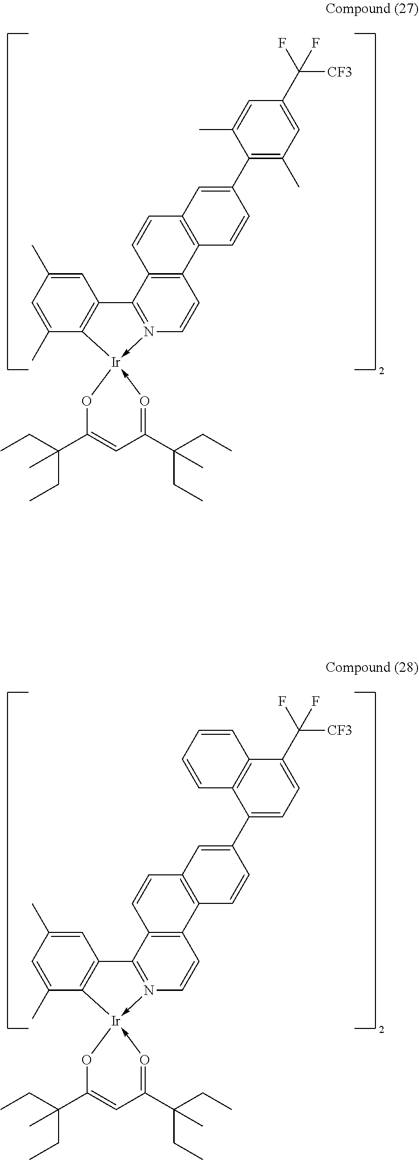

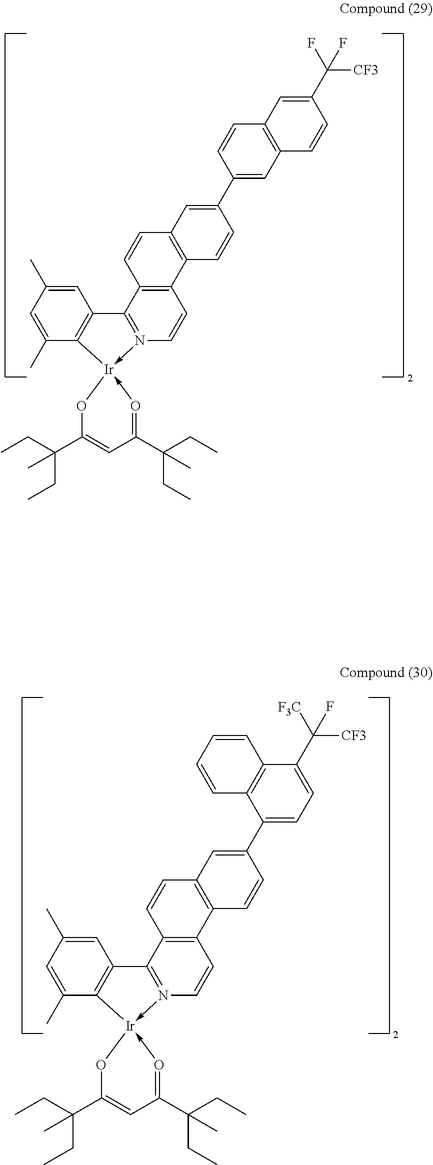

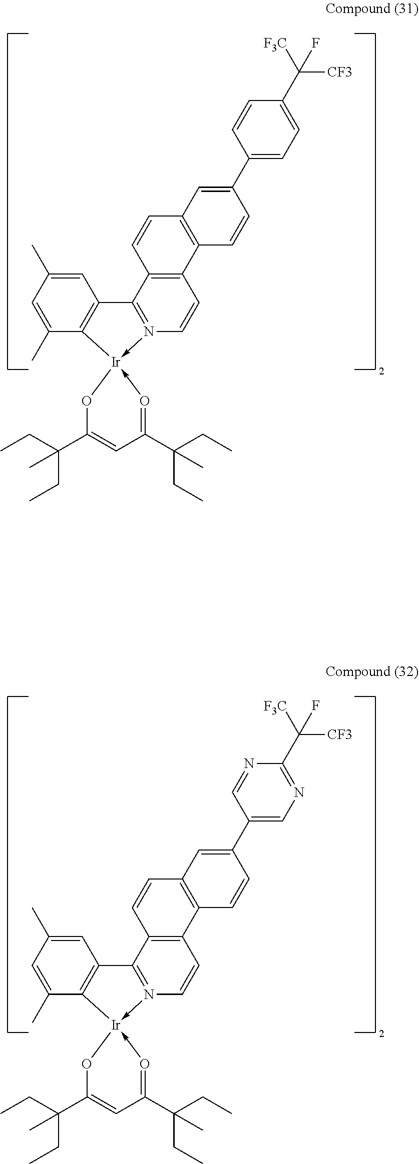

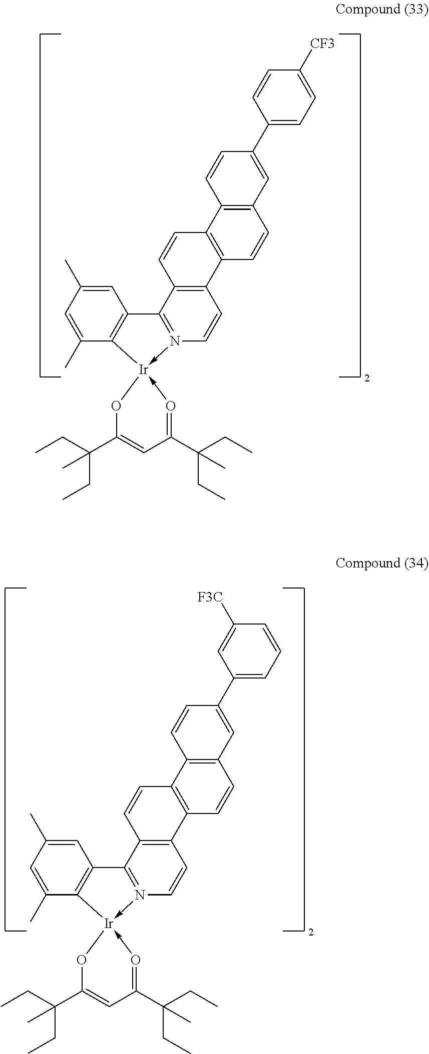

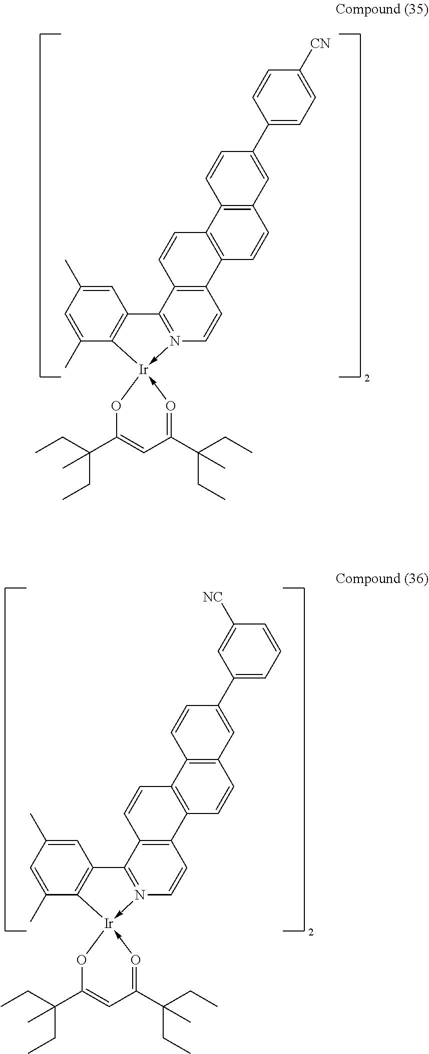

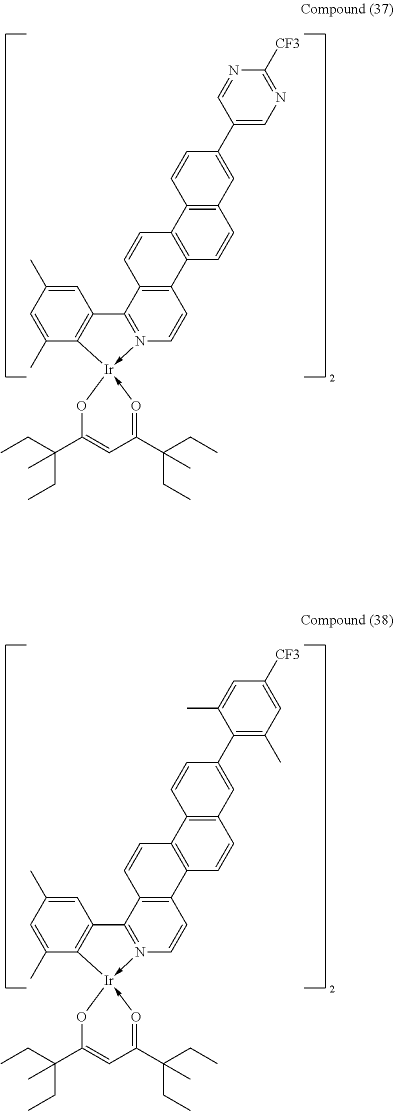

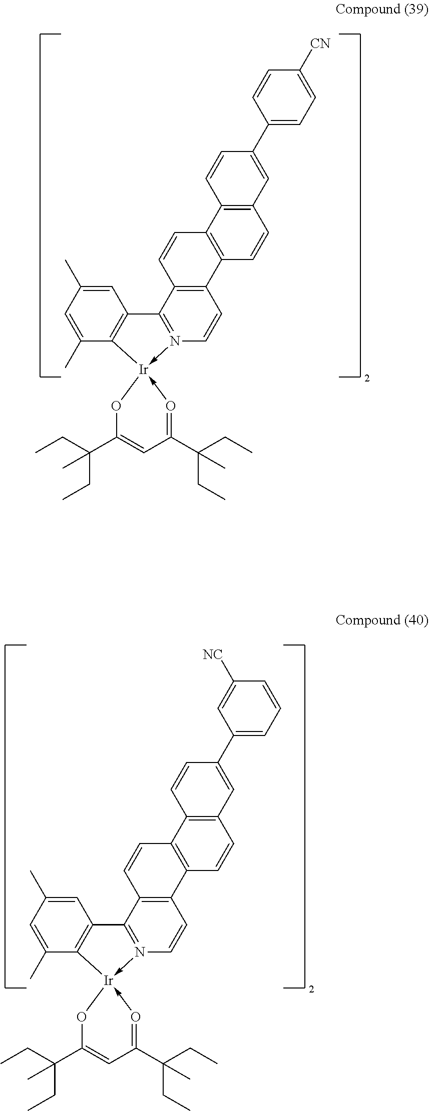

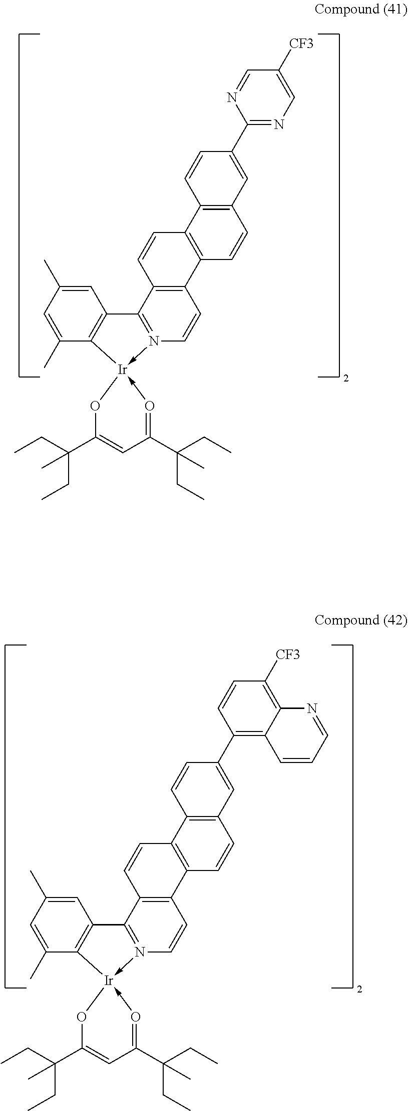

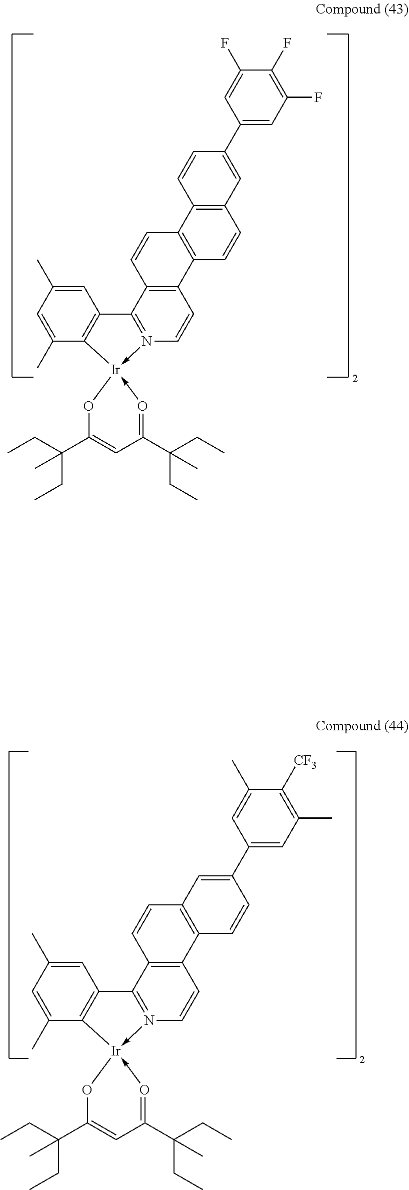

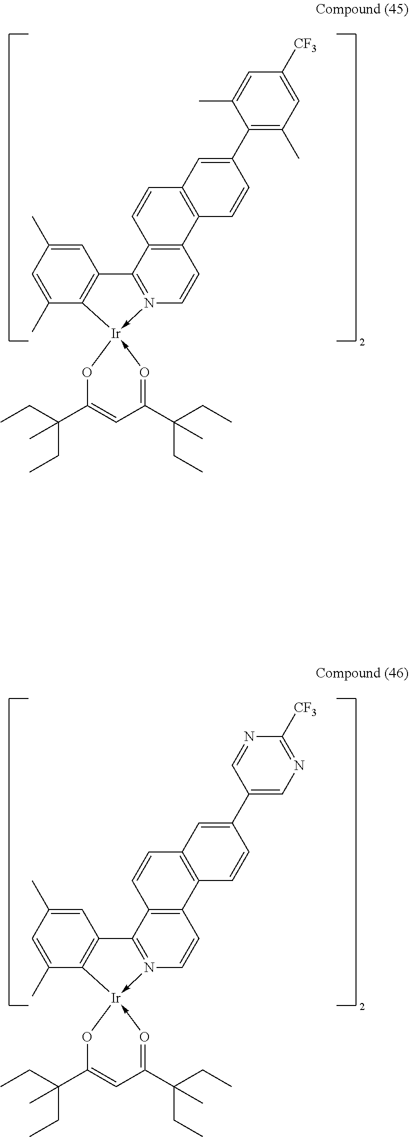

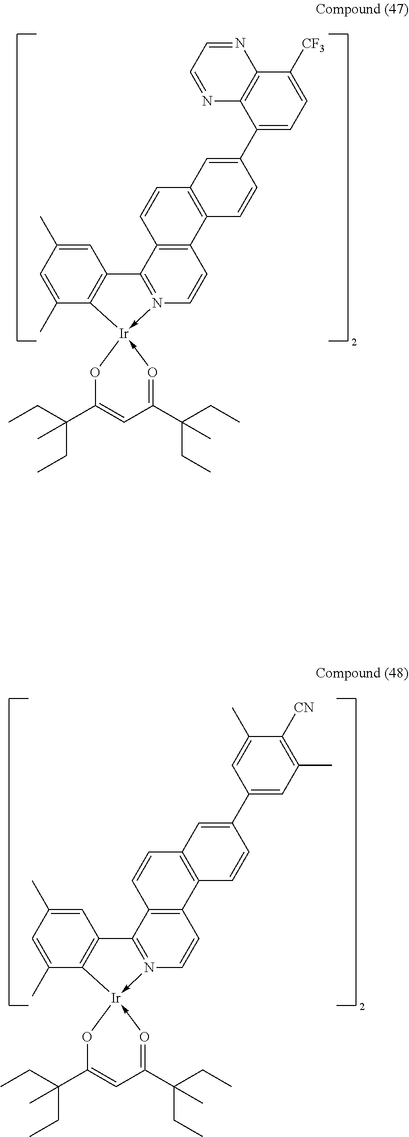

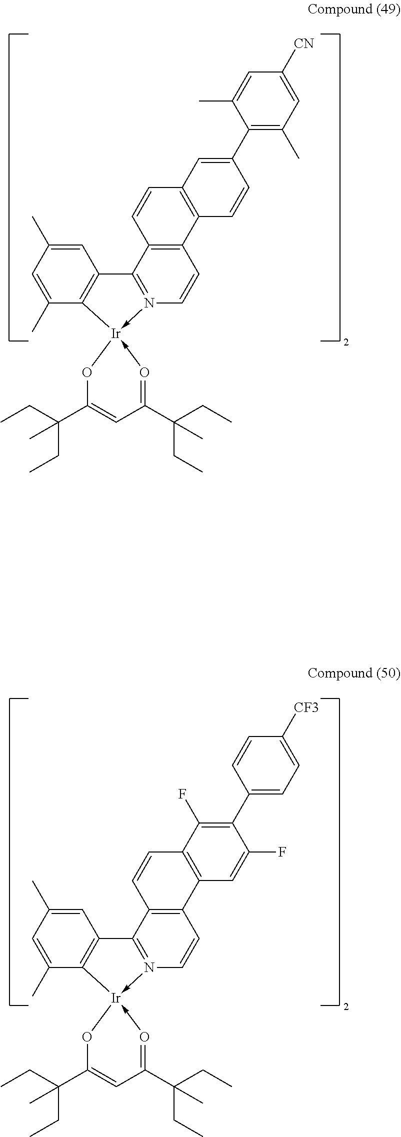

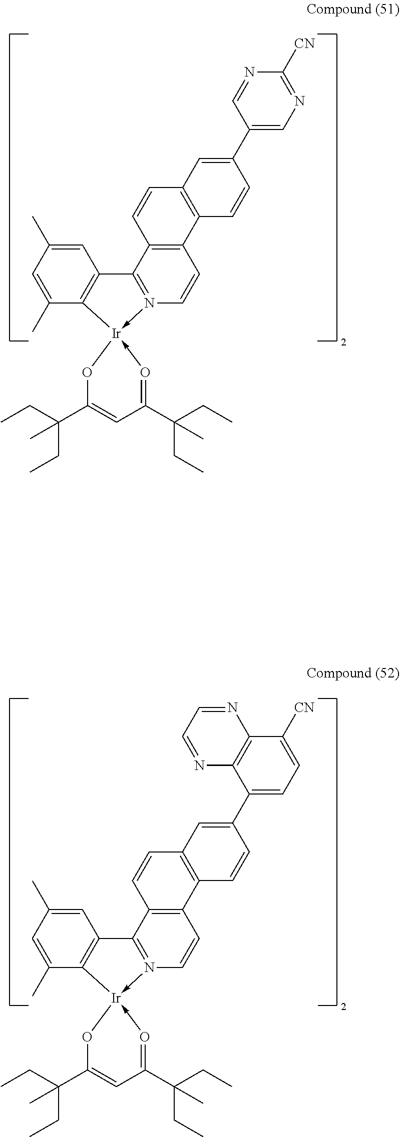

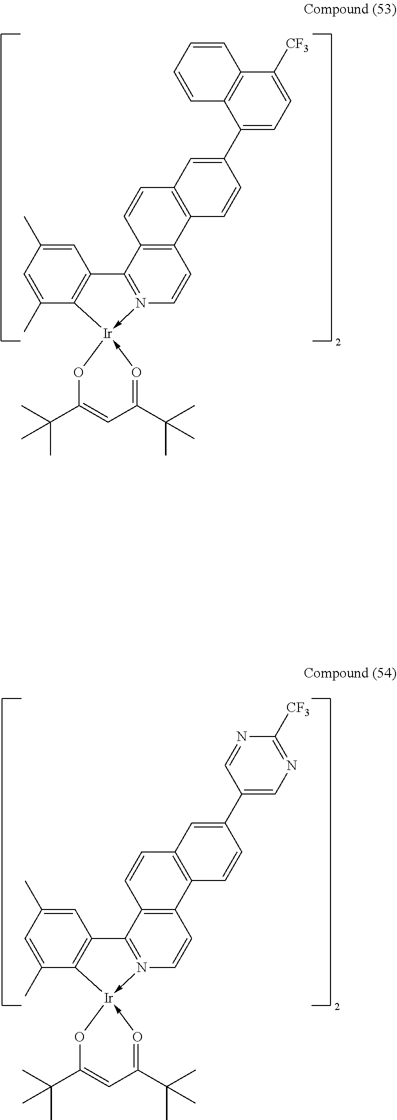

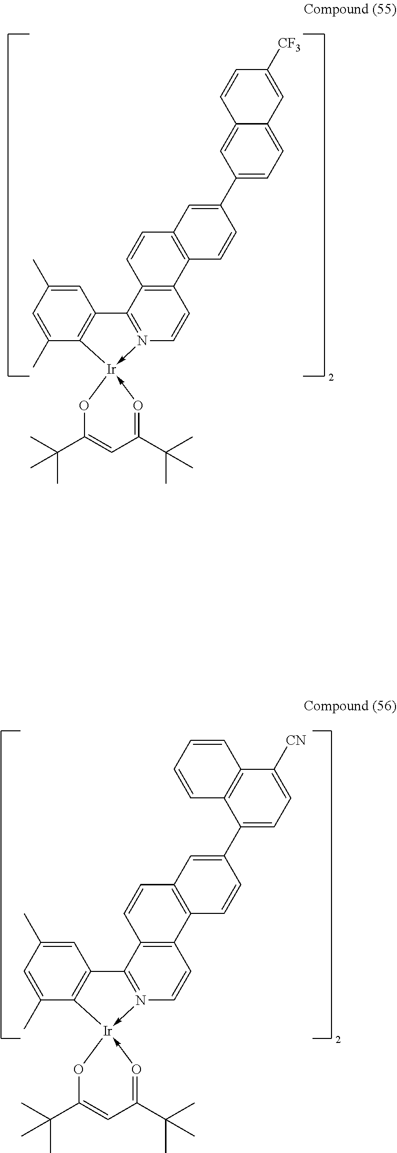

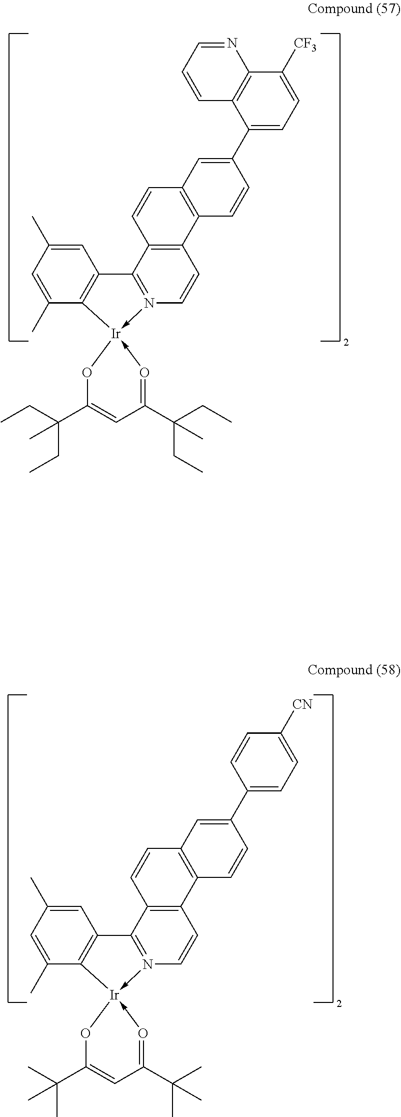

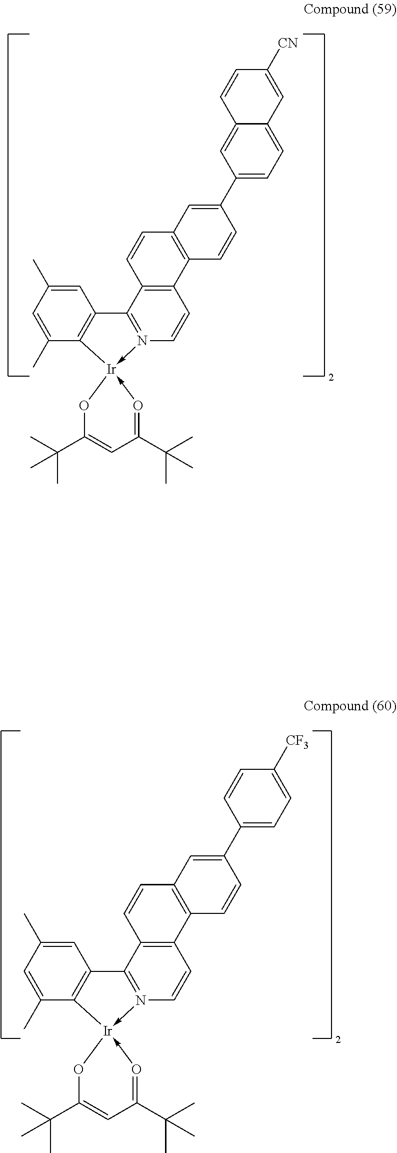

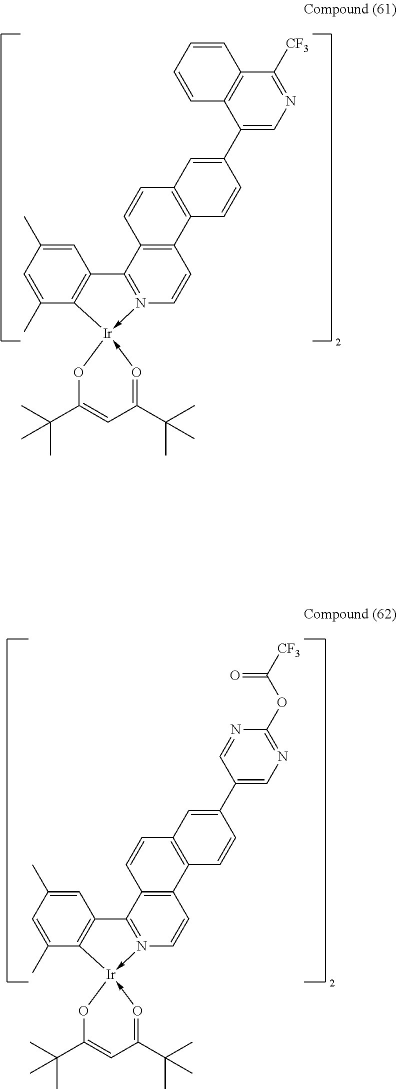

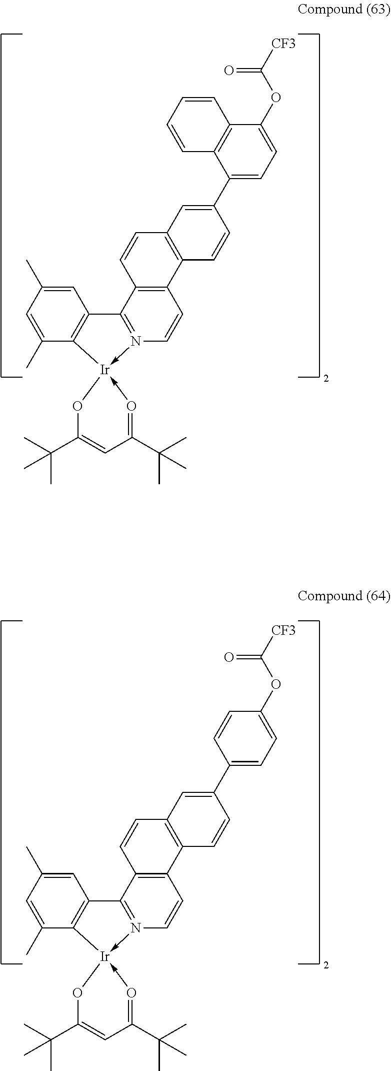

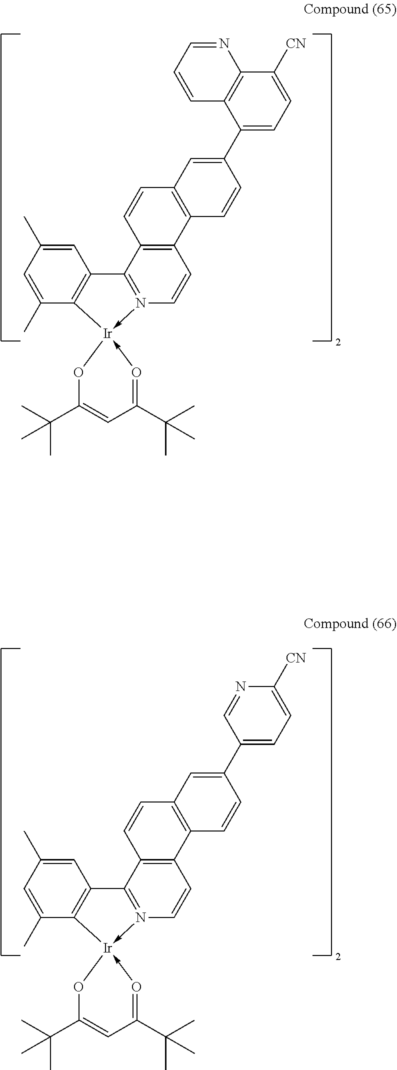

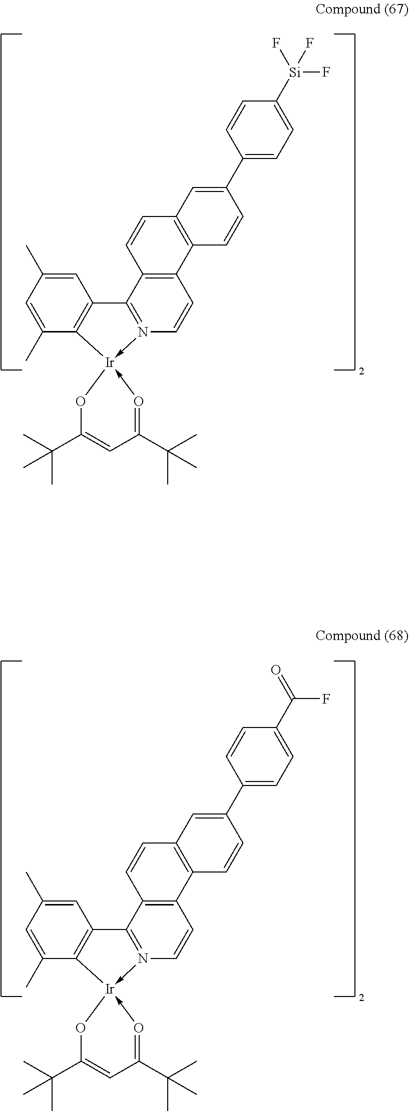

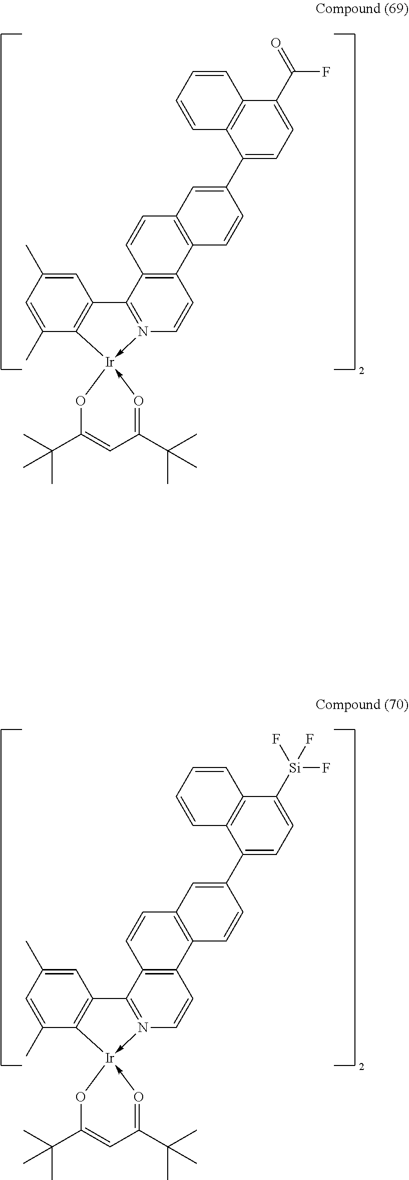

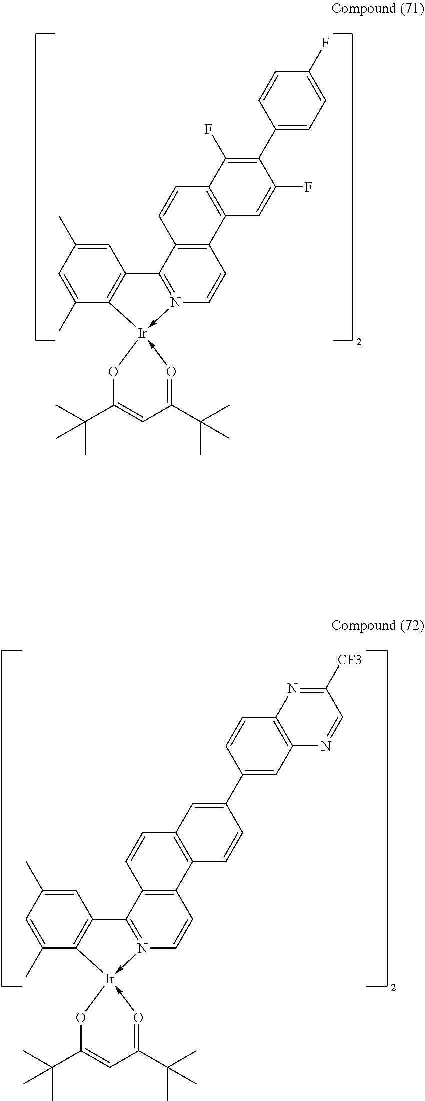

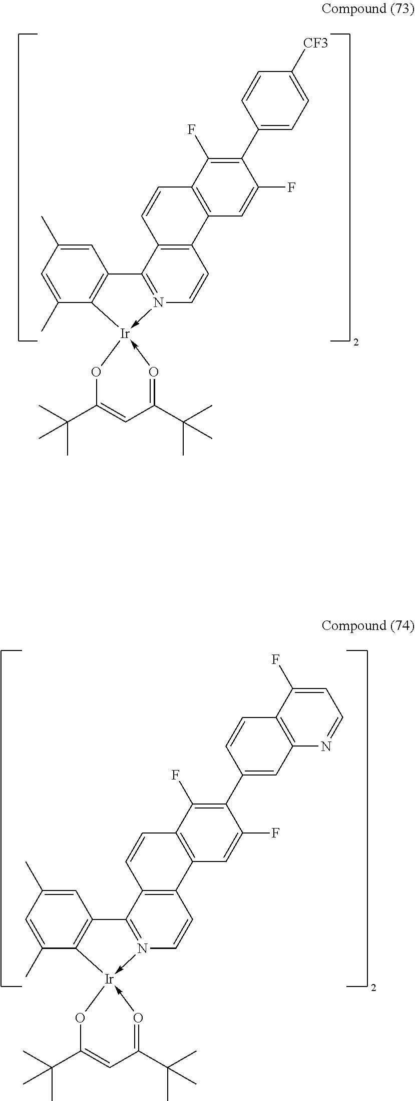

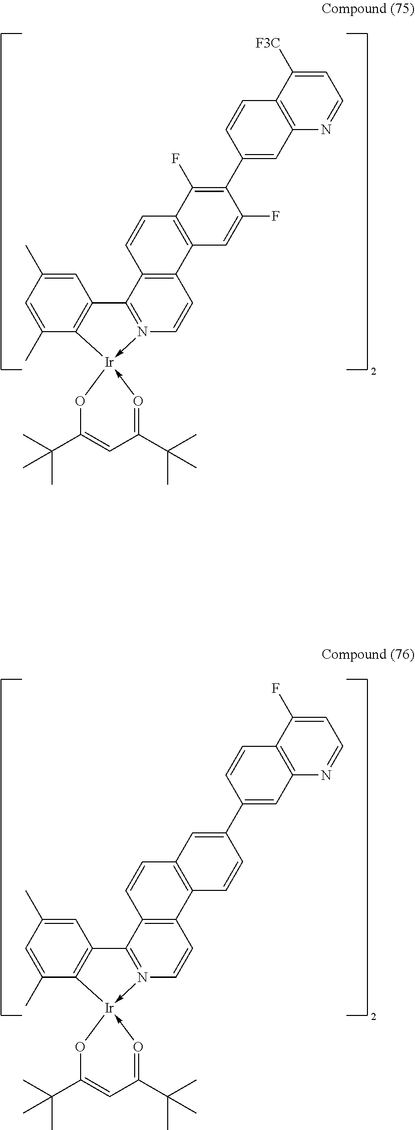

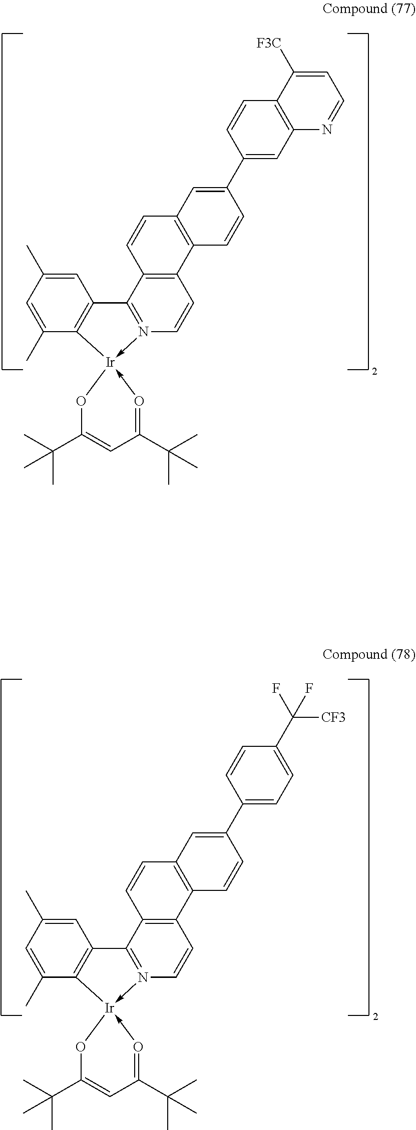

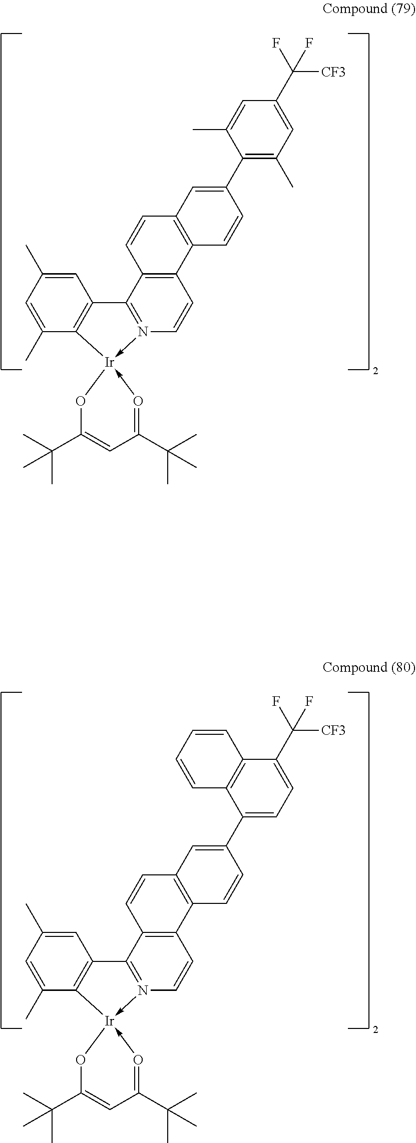

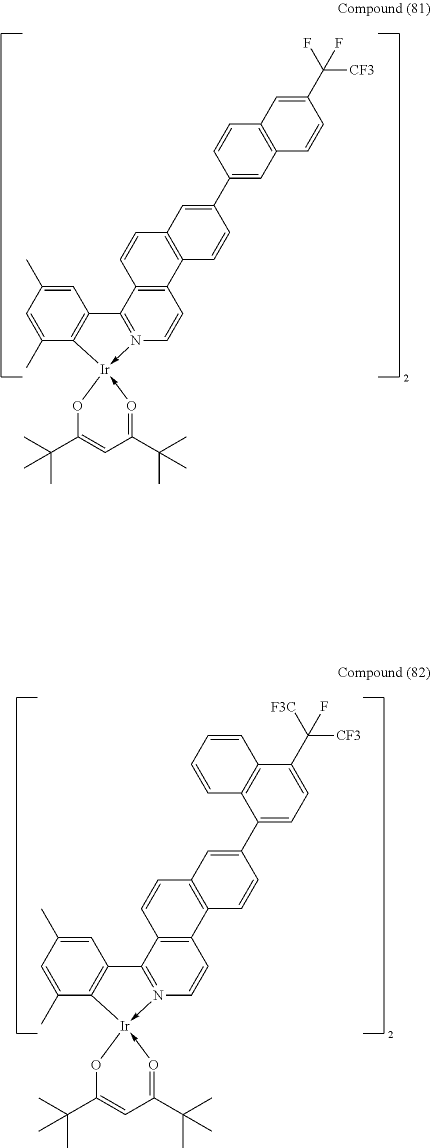

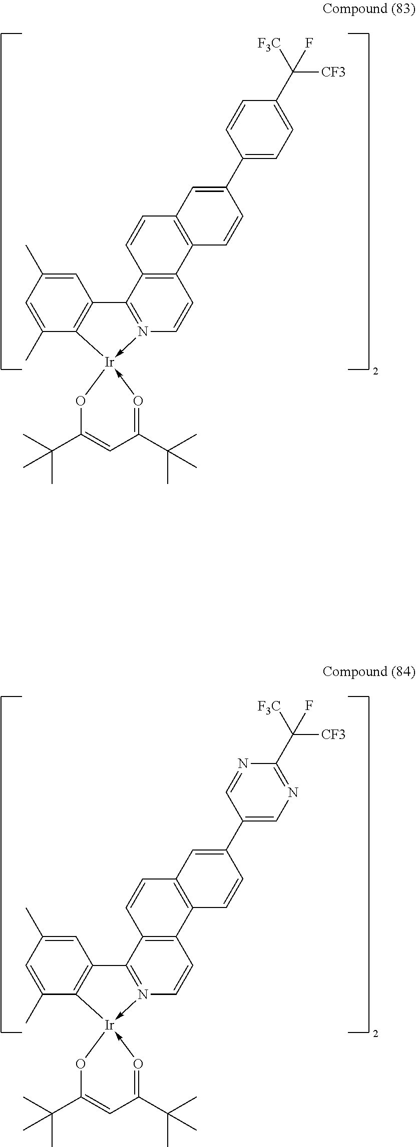

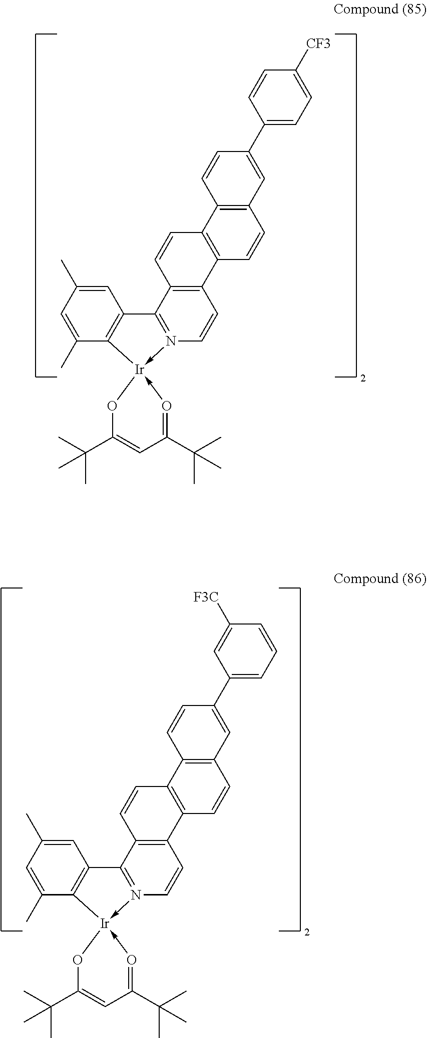

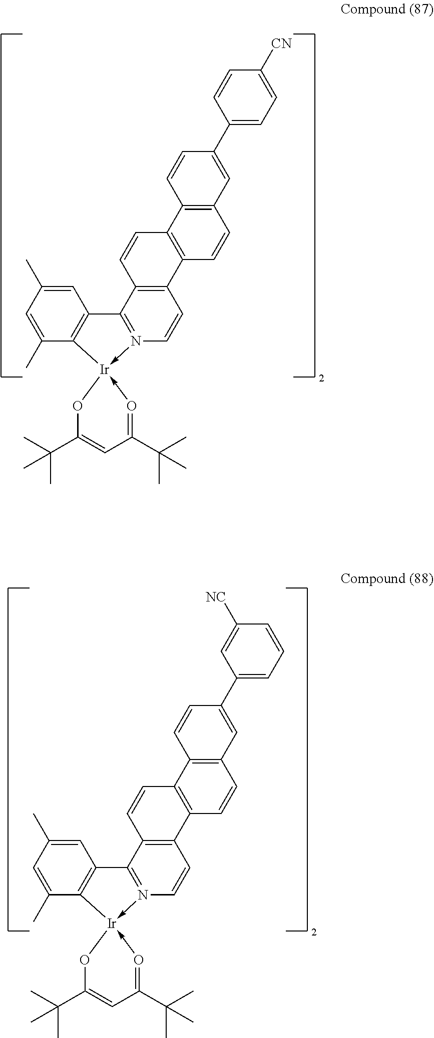

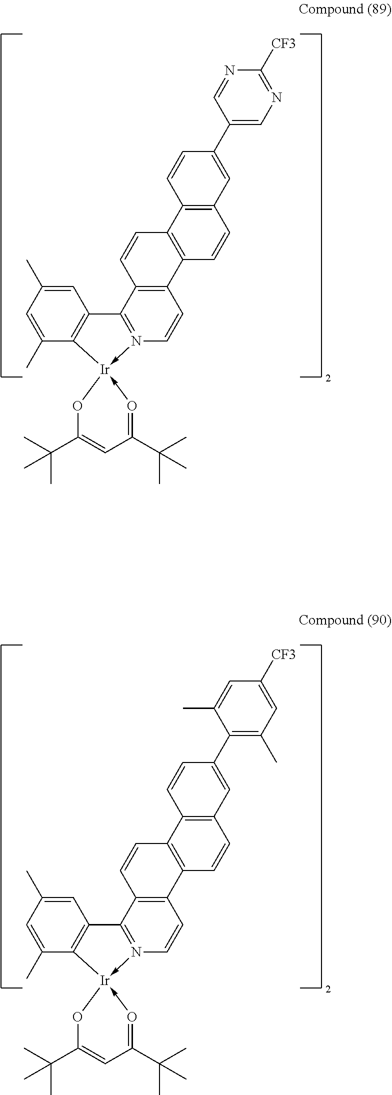

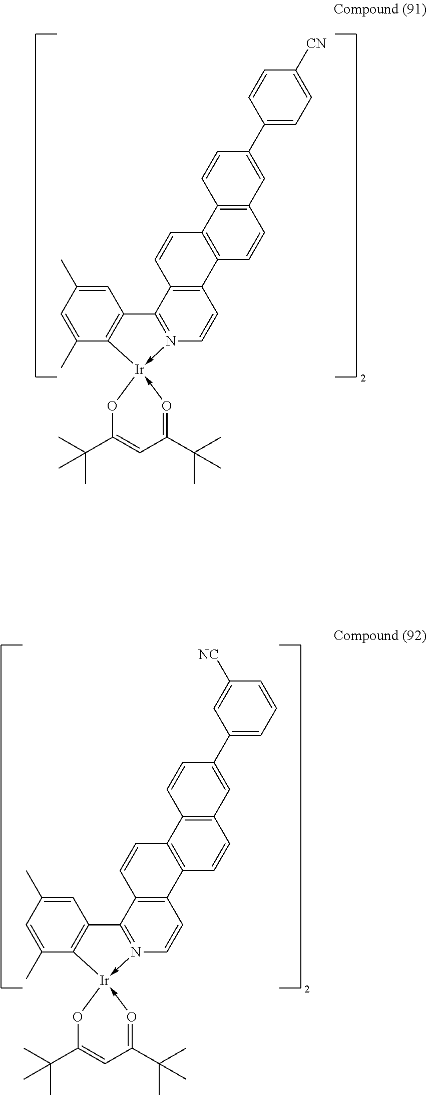

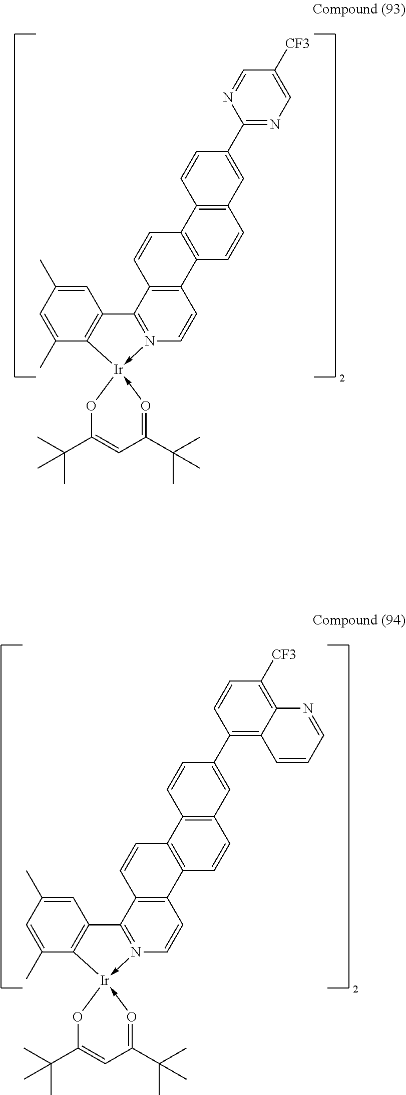

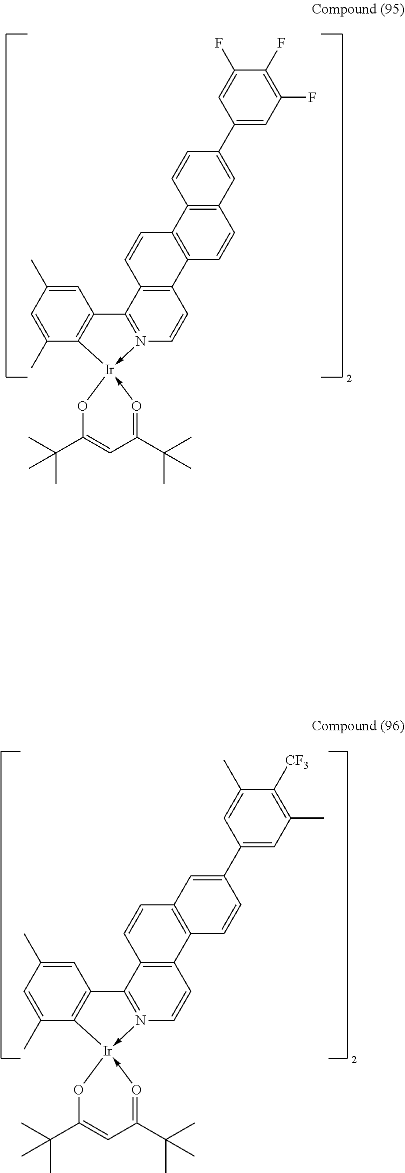

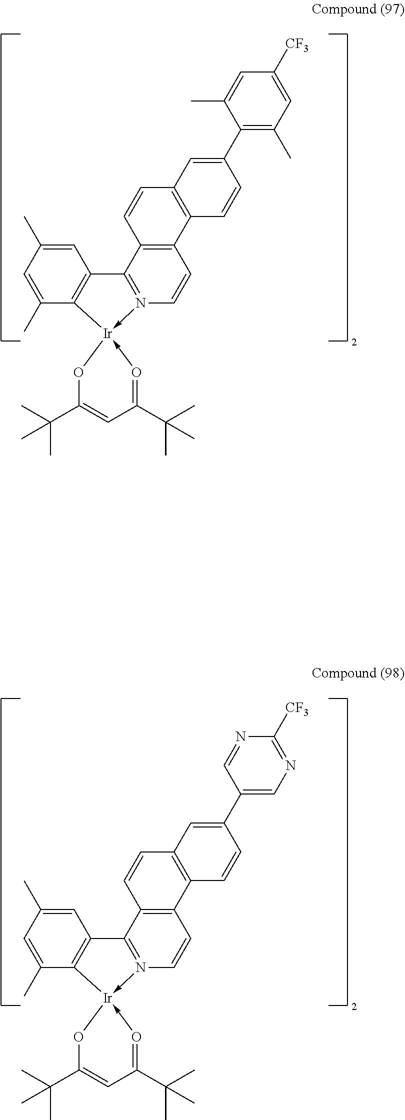

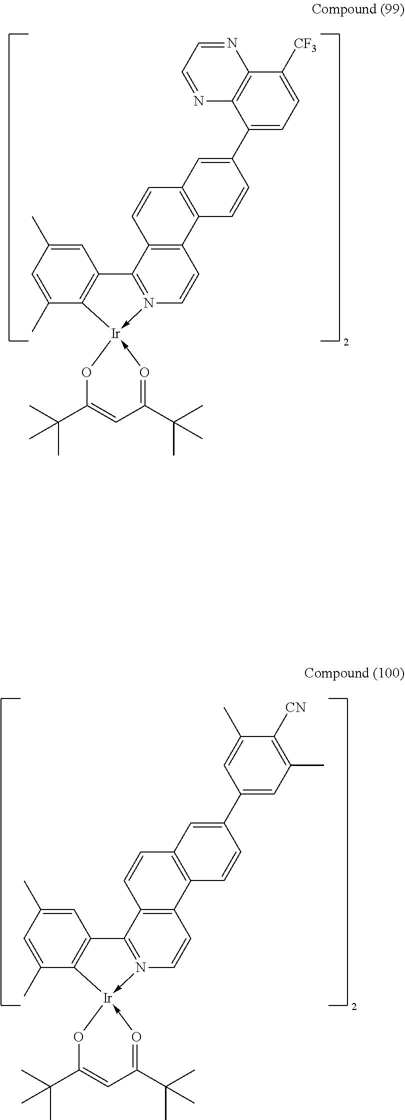

### <<Organic Light Emitting Element>>

Hereinafter, the organic light emitting element of the present embodiment will be described. The organic light emitting element of the present embodiment includes at least a first electrode and a second electrode and an organic compound layer disposed between these electrodes. One of the first electrode and the second electrode is an anode and the other is a cathode. In the organic light emitting element of the present embodiment, the organic compound layer may be a single layer or a laminate formed of a plurality of layers as long as the organic compound layer includes a light emitting layer. Here, when the organic compound layer is a laminate formed of a plurality of layers, the organic compound layer may include, in addition to the light emitting layer, a hole injection layer, a hole transport layer, an electron blocking layer, a hole/exciton blocking layer, an electron transport layer, and an electron injection layer. Further, the light emitting layer may be a single layer or a laminate formed of a plurality of layers.

In the organic light emitting element of the present embodiment, at least one of the organic compound layers described above contains the iridium complex of the present embodiment. Specifically, the organic compound according to the present embodiment is contained in any of the light emitting layer, the hole injection layer, the hole transport layer, the electron blocking layer, the hole/exciton blocking layer, the electron transport layer, or the electron injection layer described above. It is preferable that the organic compound according to the present embodiment be contained in a light emitting layer.

In the organic light emitting element of the present embodiment, when the organic compound according to the present embodiment is contained in a light emitting layer, the light emitting layer may be a layer formed of only the organic compound according to the present embodiment or a layer formed of the organometallic complex according to the present embodiment and other compounds. Here, when the light emitting layer is a layer formed of the organometallic complex according to the present embodiment and other compounds, the organic compound according to the present embodiment may be used as a host or a guest in the light emitting layer. Further, the organic compound may be used as an assist material that can be contained in the light emitting layer. Here, the host is a compound having the highest mass ratio among the compounds constituting the light emitting layer. Further, the guest is a compound that has a mass ratio less than that of the host among the compounds constituting the light emitting layer and is responsible for main light emission. Further, the assist material is a compound which has a mass ratio less than that of the host among the compounds constituting the light emitting layer and supports light emission of the guest. In addition, the assist material is referred to as a second host. The host material can be referred to as a first compound and the assist material can also be referred to as a second compound.

Here, when the organic compound according to the present embodiment is used as the guest of the light emitting layer, the concentration of the guest is preferably 0.01% by mass or greater and 20% by mass or less and more preferably 0.1% by mass or greater and 10% by mass or less with respect to the total concentration of the light emitting layer.

The light emitting layer according to the present embodiment contains an iridium complex and a first organic compound, and a compound having a minimum excited singlet energy greater than that of the iridium complex can be used as the first organic compound. The first organic compound is also referred to as a host. The weight ratio of the host in the light emitting layer may be greater than that of the iridium complex.

Further, the light emitting layer may contain a second organic compound different from the first organic compound. A compound having a minimum excited triplet energy less than that of the first organic compound and greater than that or the iridium complex can be used as the second organic compound. The second organic compound is also referred to as an assist. The weight ratio of the assist in the light emitting layer may be less than that of the host and less than that of the iridium complex.

As a result of various research conducted by the present inventors, it was found that when the organic compound according to the present embodiment is used as a host or a guest of the light emitting layer, particularly as a guest of the light emitting layer, an element that outputs light with high efficiency and high brightness and has extremely high durability can be obtained. The light emitting layer may be formed of a single layer or a plurality of layers, and emission colors can be mixed with a red emission color which is the emission color of the present embodiment by allowing the light emitting layer to contain light emitting materials having other emission colors. The plurality of layers denote a state where the light emitting layer and other light emitting layers are laminated. In this case, the emission color of the organic light emitting element is not limited to red. More specifically, the emission color may be white or an intermediate color. When the emission color is white, other light emitting layers emit light of colors other than red, that is, blue and green. Further, the film formation is also performed by a vapor deposition method or a coating film forming method. The details will be described in examples below.

The organometallic complex according to the present embodiment can be used as a constituent material for the organic compound layer other than the light emitting layer constituting the organic light emitting element of the present embodiment. Specifically, the organic compound may be used as a constituent material for an electron transport layer, an electron injection layer, a hole transport layer, a hole injection layer, a hole blocking layer, or the like. In this case, the emission color of the organic light emitting element is not limited to red. More specifically, the emission color may be white or an intermediate color.

Here, known low-molecular-weight and high-molecular-weight hole injecting compounds or hole transporting compounds, compounds serving as a host, light emitting compounds, electron injecting compounds, or electron transporting compounds of the related art can be used together as necessary in addition to the organic compound according to the present embodiment. Examples of such compounds will be described below.

A material with high hole mobility formed such that hole injection from an anode is easily carried out and the injected holes can be transported to the light emitting layer is preferable as the hole injecting and transporting material. Further, a material with a high glass transition temperature is preferable from the viewpoint of suppressing deterioration of the film quality such as crystallization in the organic light emitting element. Examples of the low-molecular-weight and high-molecular-weight materials having a hole injecting transporting ability include a triarylamine derivative, an arylcarbazole derivative, a phenylene diamine derivative, a stilbene derivative, a phthalocyanine derivative, a porphyrin derivative, poly(vinylcarbazole), poly(thiophene), and other conductive polymers. Further, the above-described hole injecting and transporting material is suitably used in the electron blocking layer. Specific examples of the compound used as the hole injecting and transporting material will be shown below, but the present invention is not limited thereto.

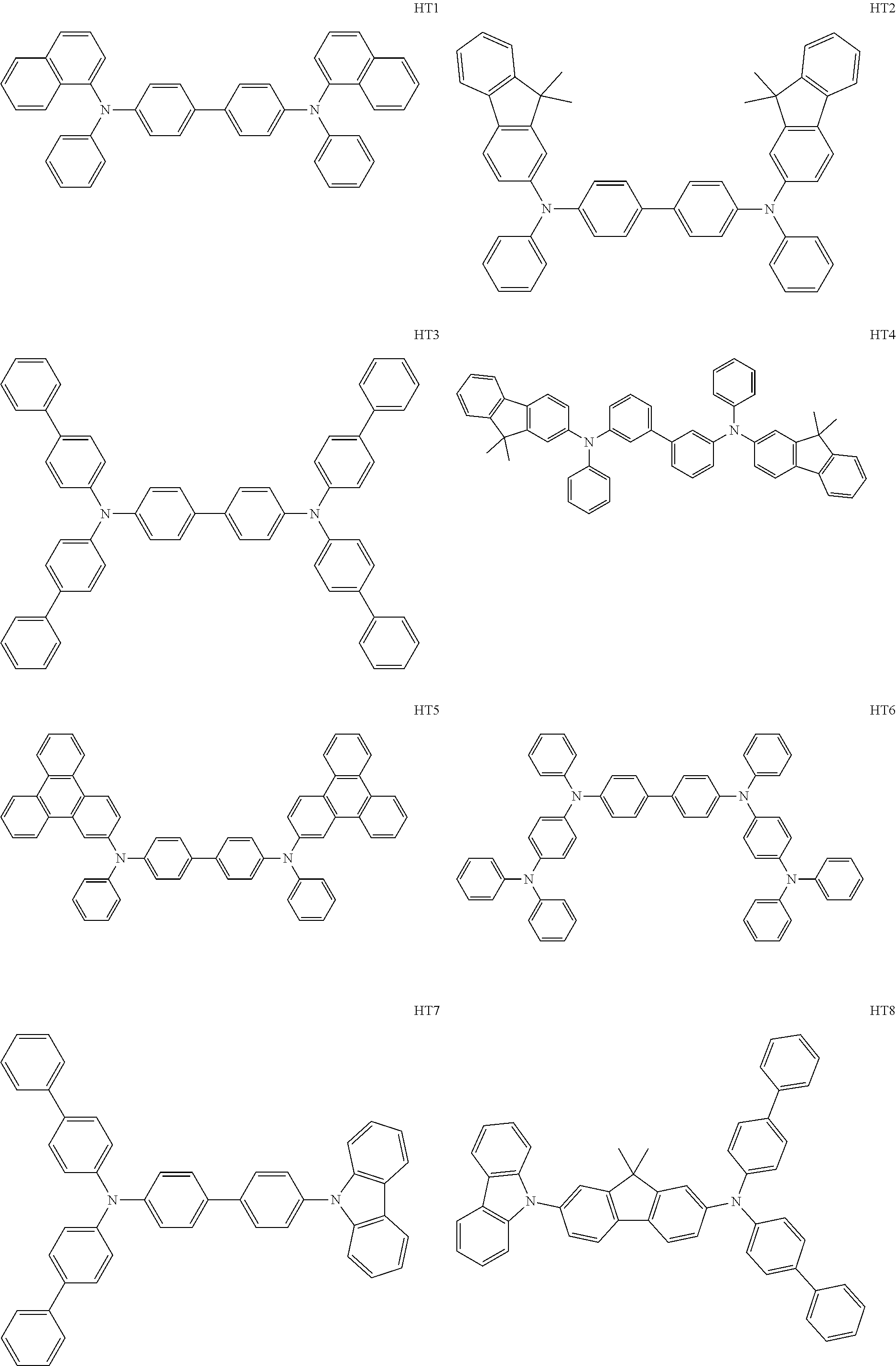

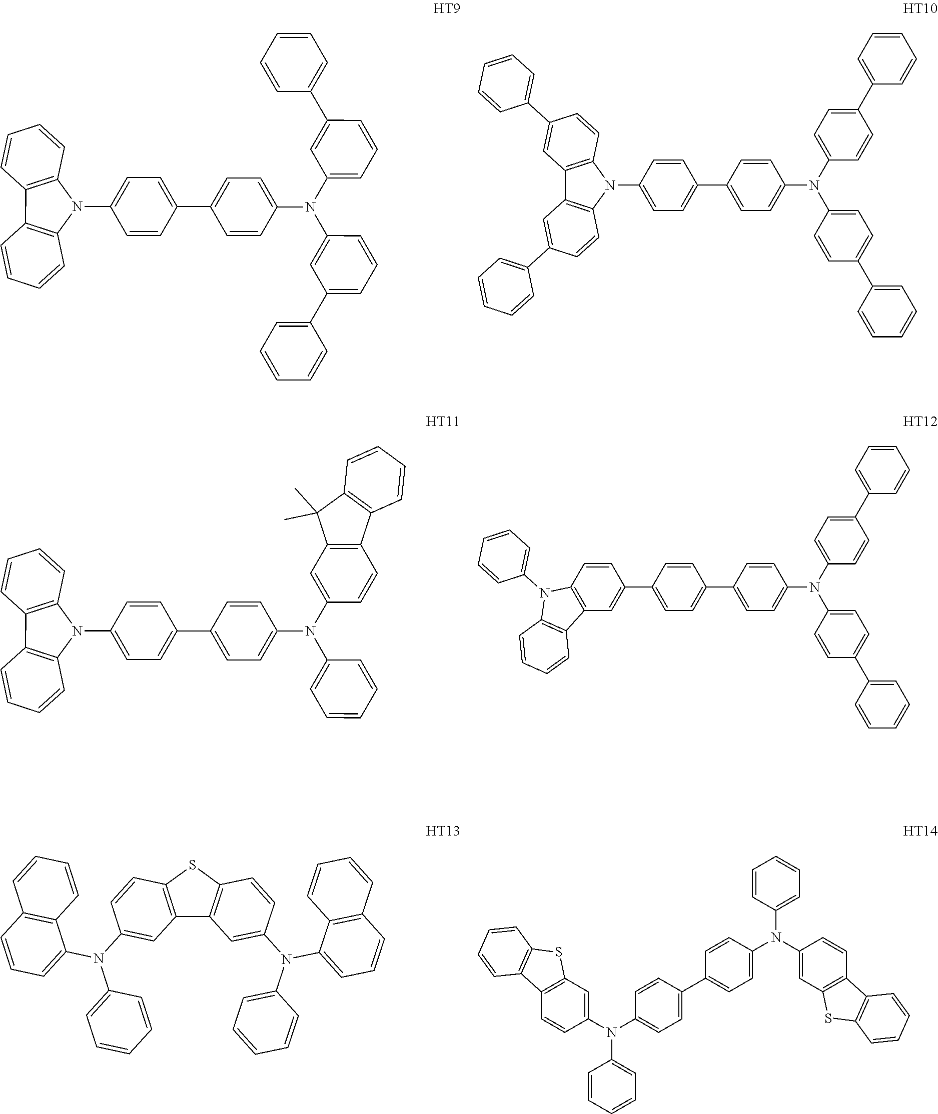

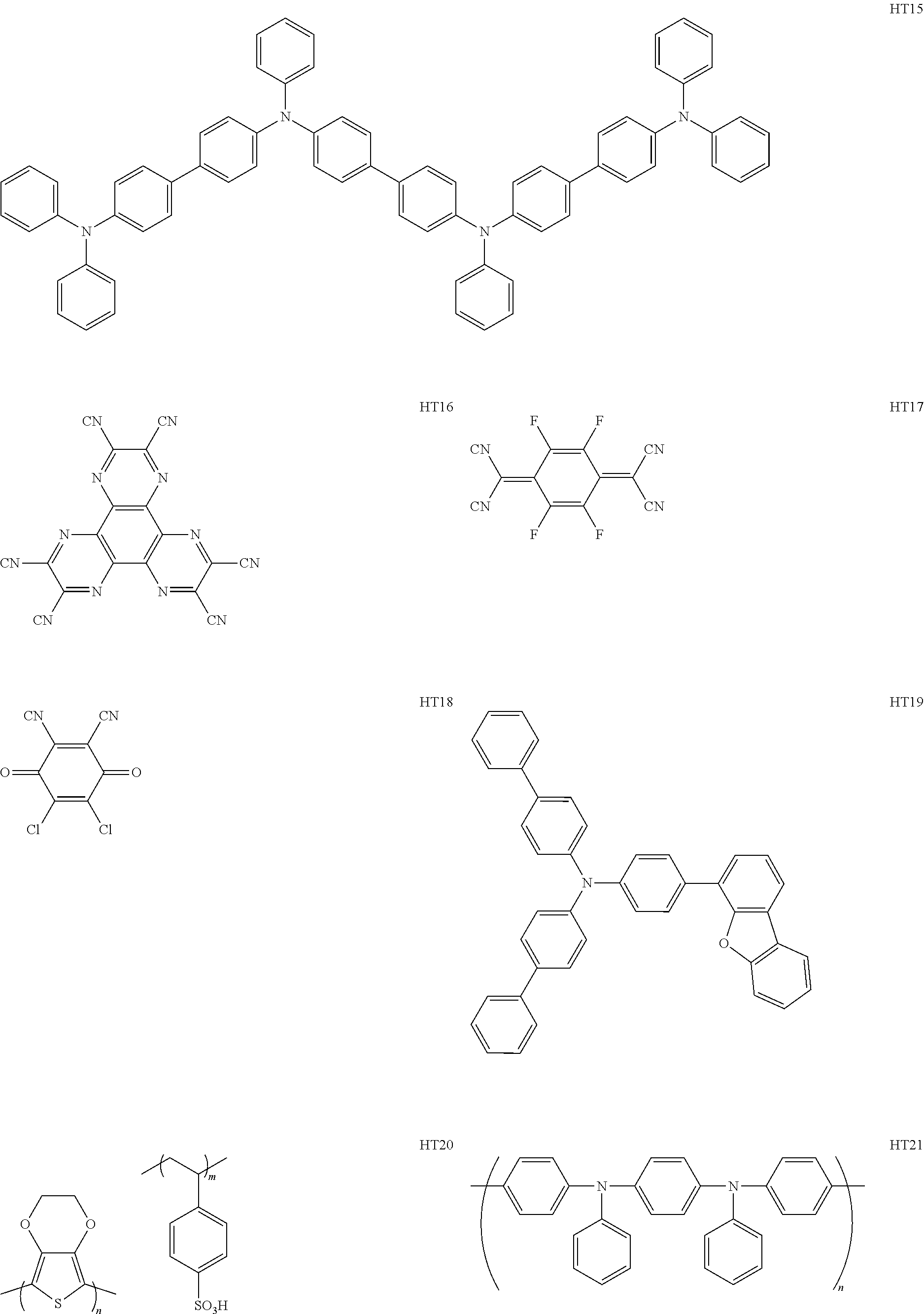

Examples of the light emitting material mainly related to the light emitting function include, in addition to the organometallic complex represented by General Formula [1], a fused ring compound (such as a fluorene derivative, a naphthalene derivative, a pyrene derivative, a perylene derivative, a tetracene derivative, an anthracene derivative, or rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and a polymer derivative such as a poly(phenylenevinylene) derivative, a poly(fluorene) derivative, or a poly(phenylene) derivative.

Specific examples of the compound used as the light emitting material are shown below, but the present invention is not limited thereto.

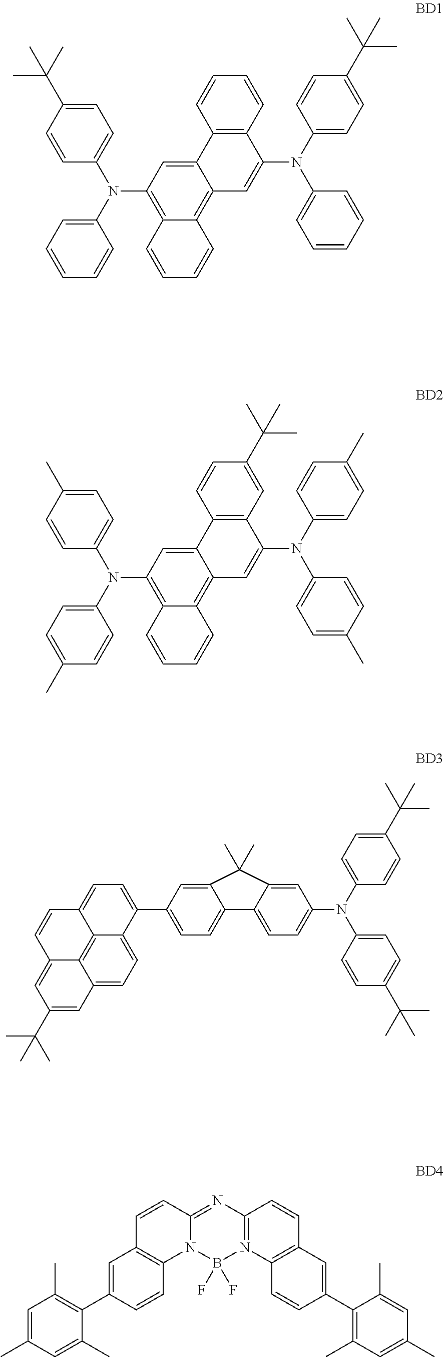

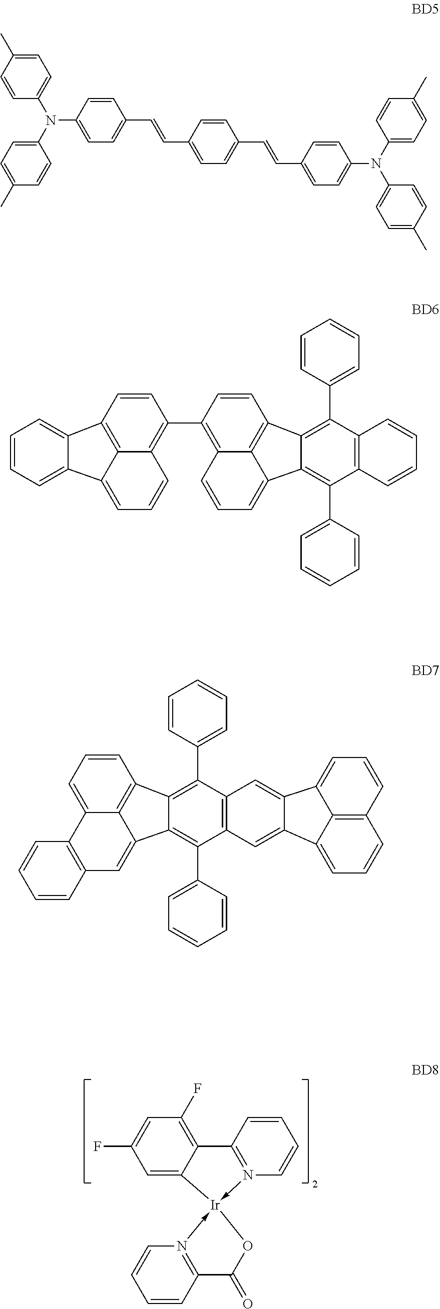

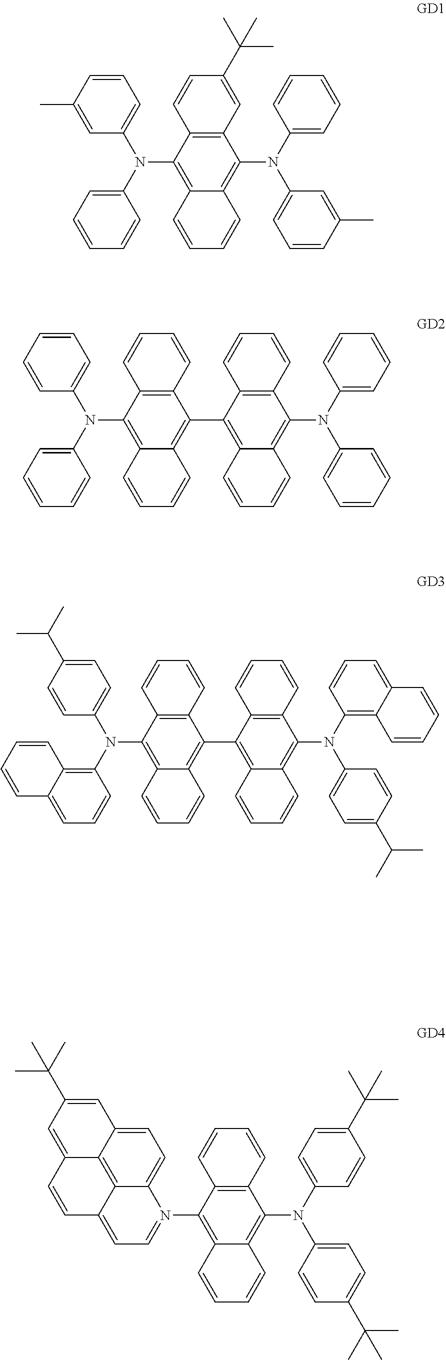

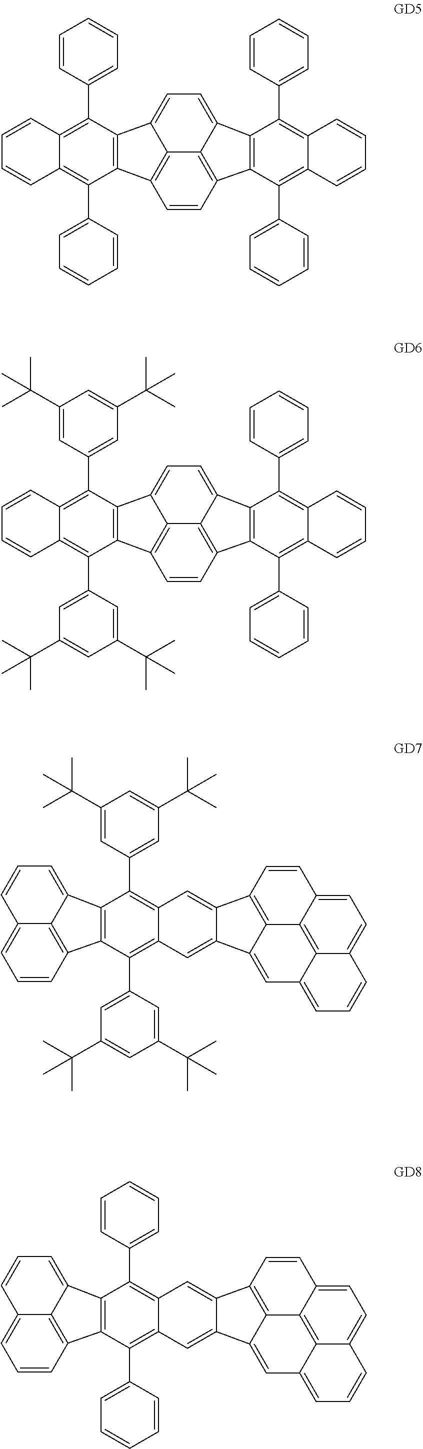

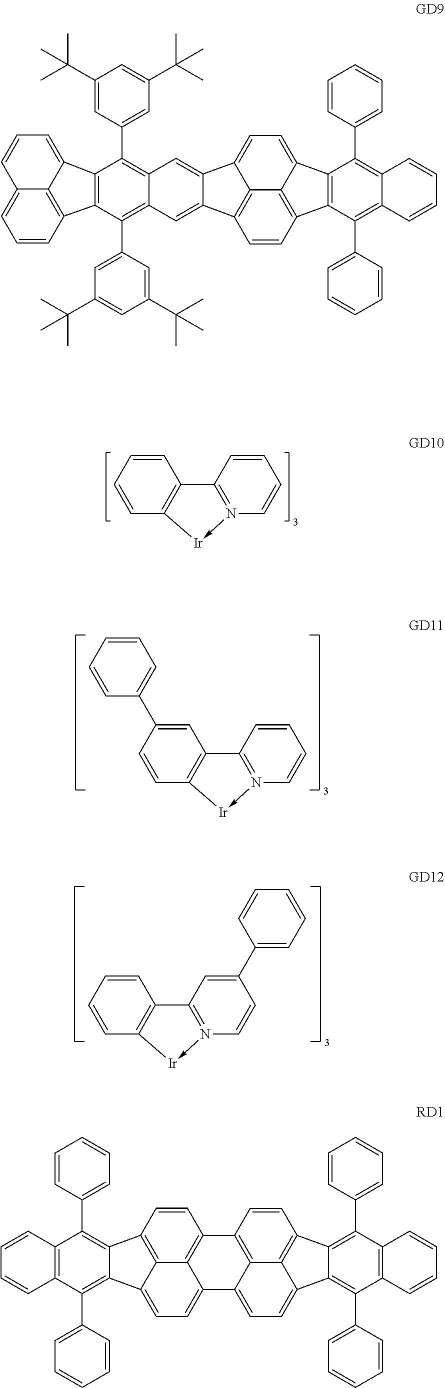

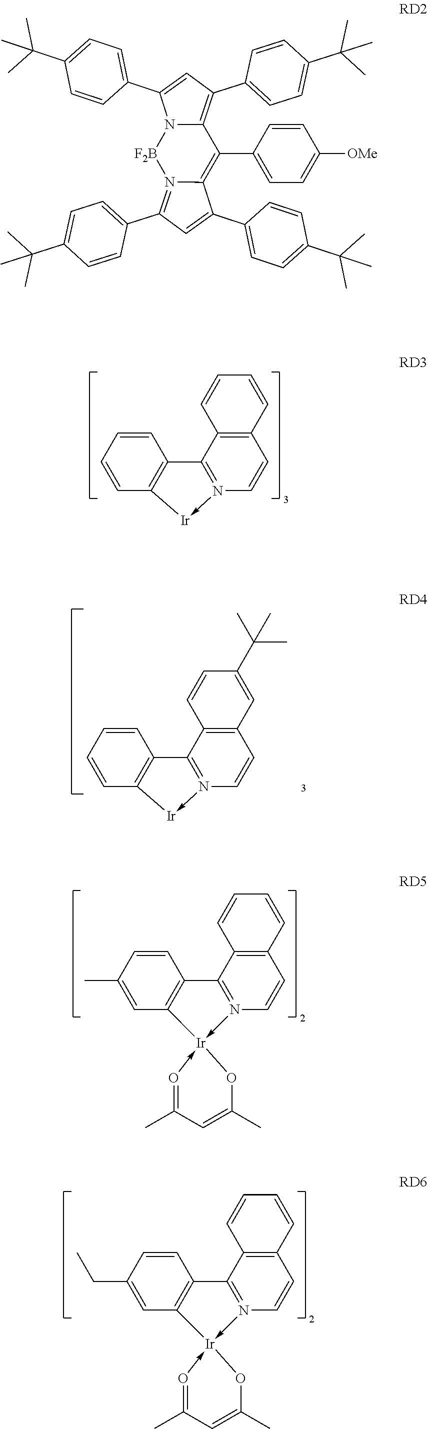

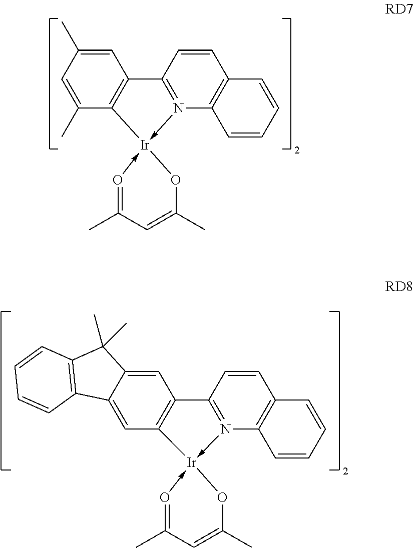

Examples of the host material or the assist material contained in the light emitting layer include an aromatic hydrocarbon compound and a derivative thereof, a carbazole derivative, a dibenzofuran derivative, a dibenzothiophene derivative, an organic aluminum complex such as tris(8-quinolinolato)aluminum, and an organic beryllium complex.

Specific examples of the compound used as the host material or the assist material contained in the light emitting layer are shown below, but the present invention is not limited thereto.

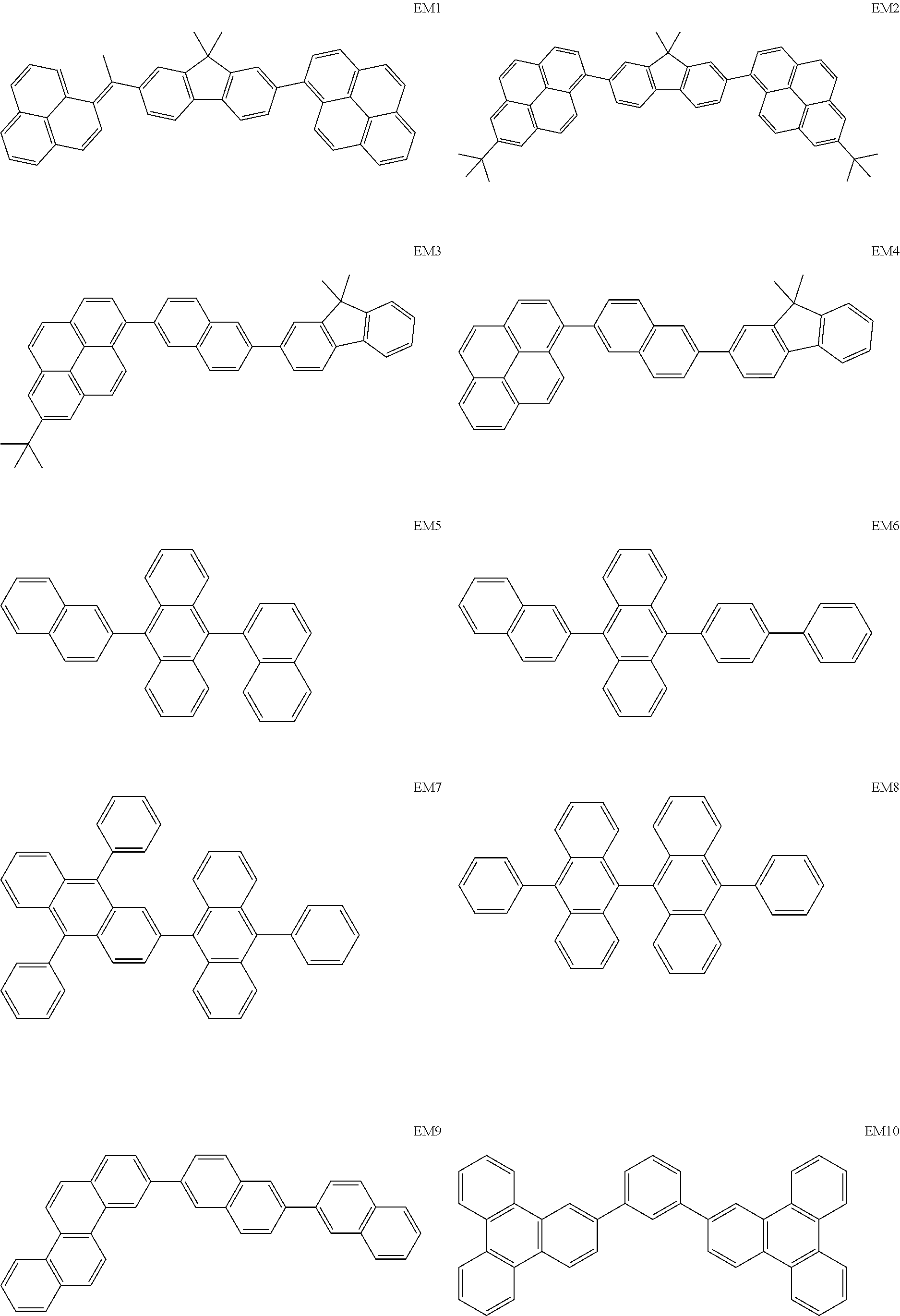

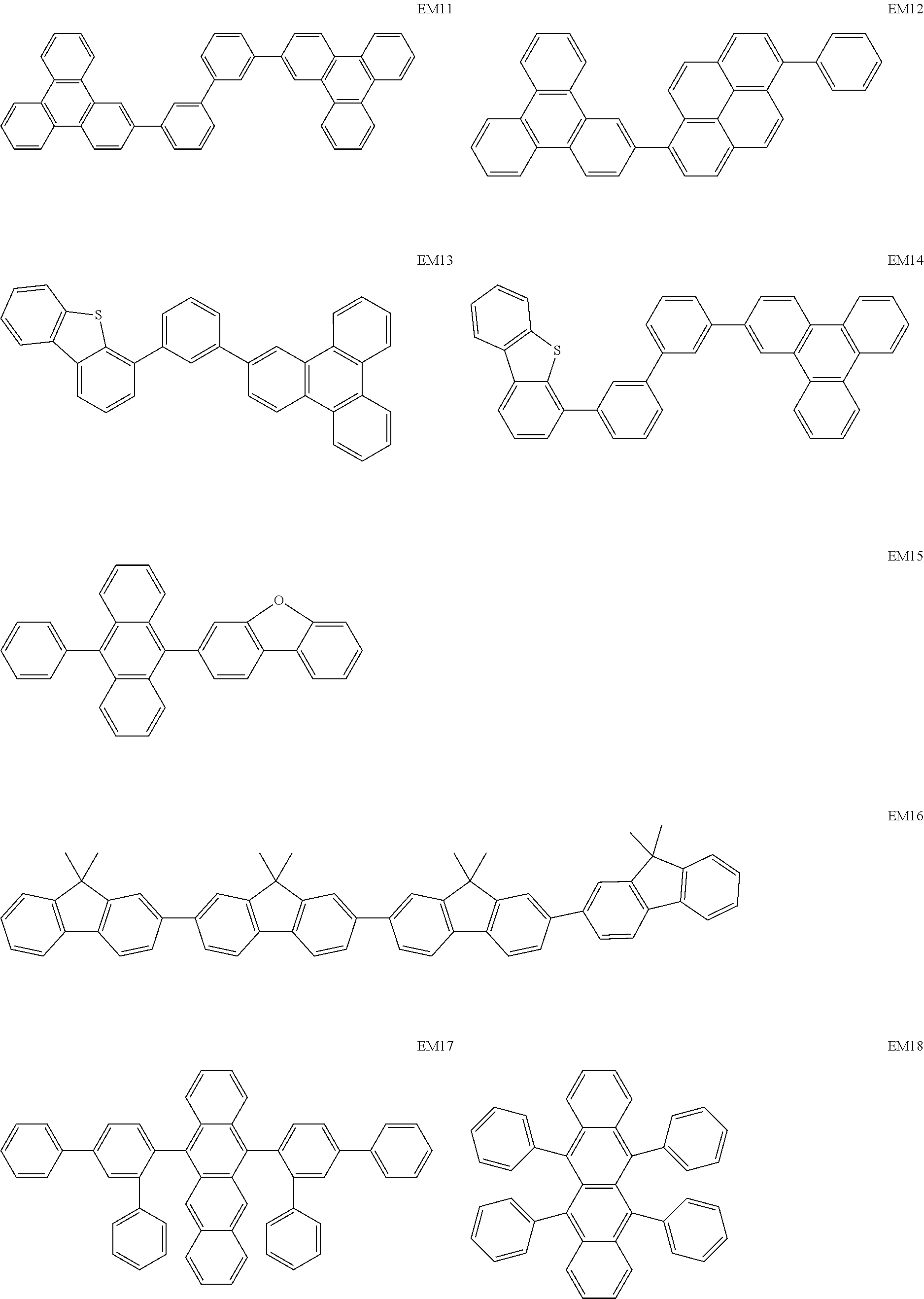

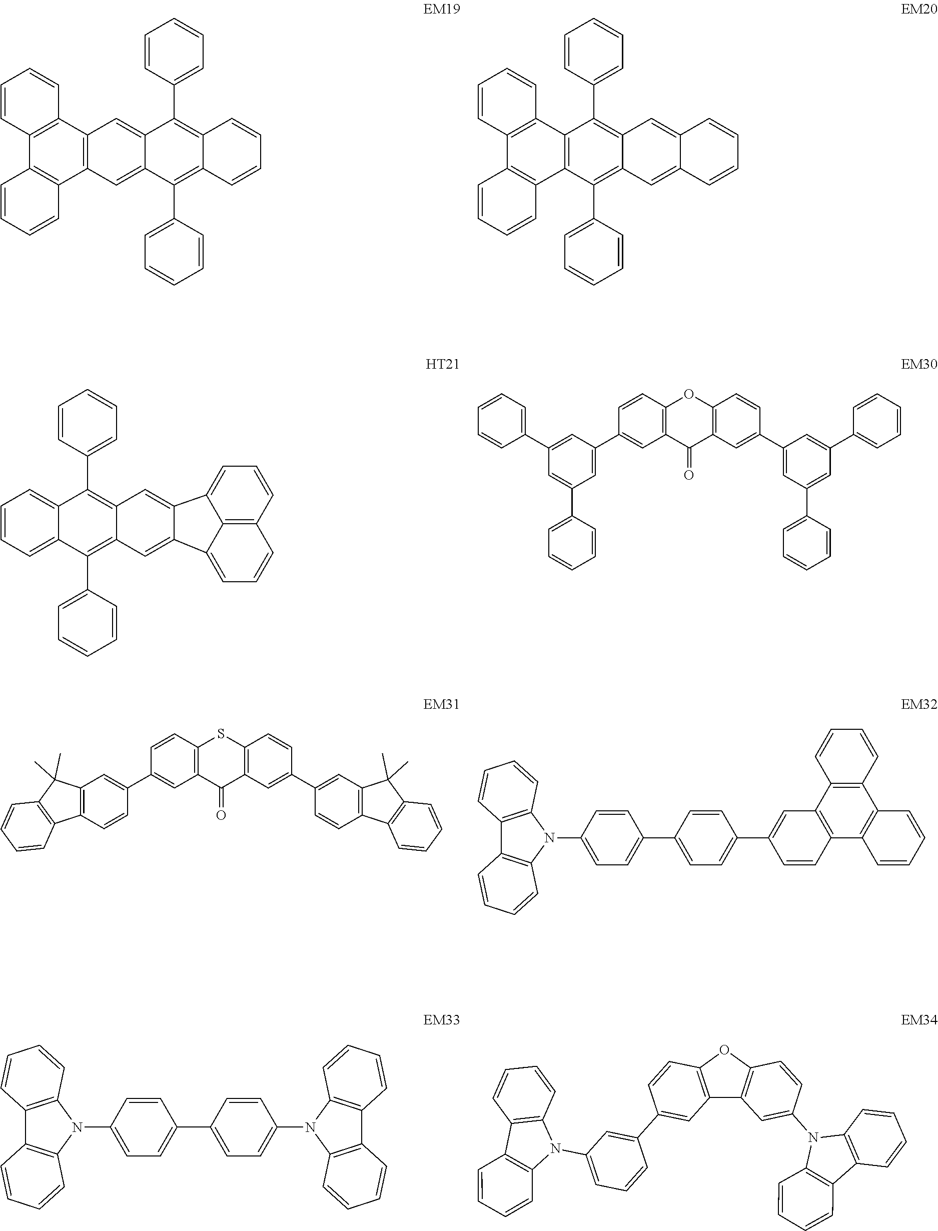

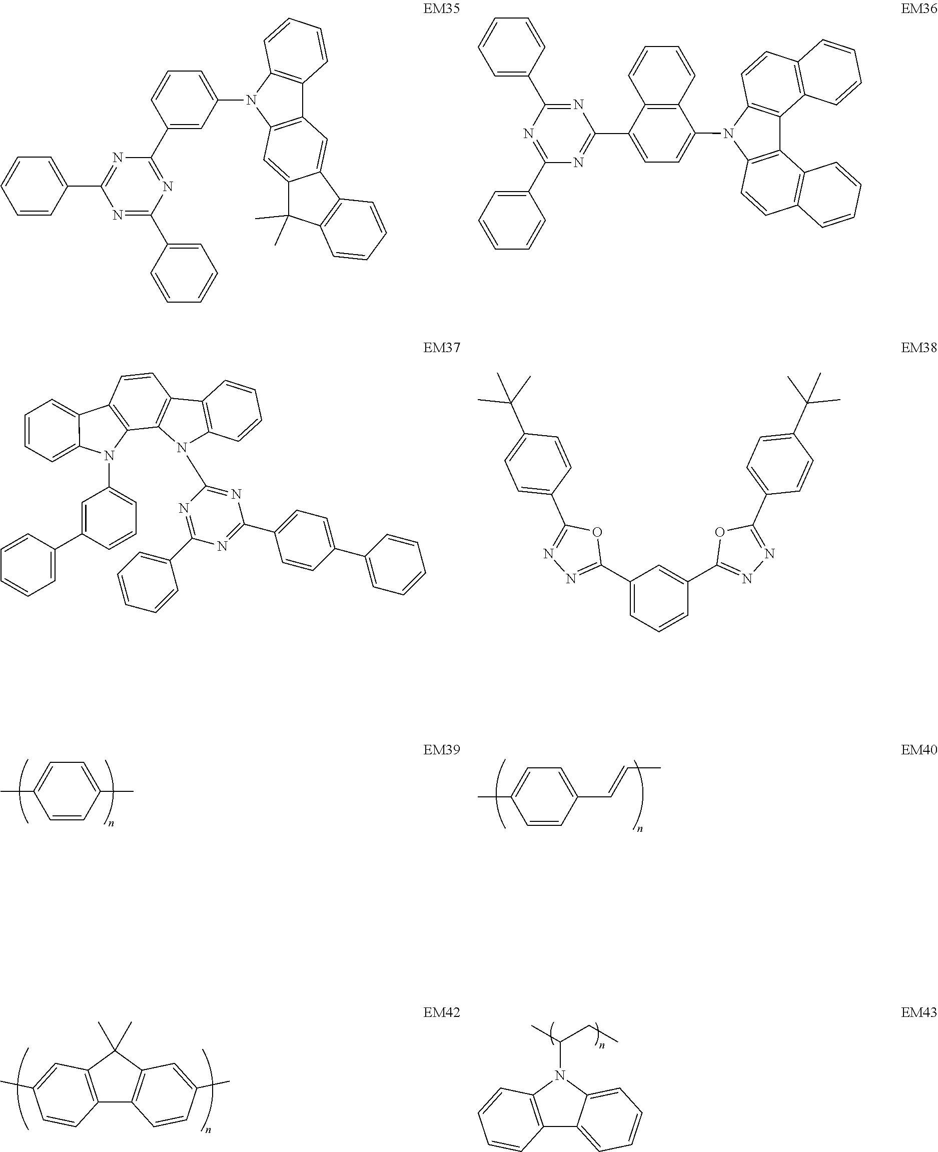

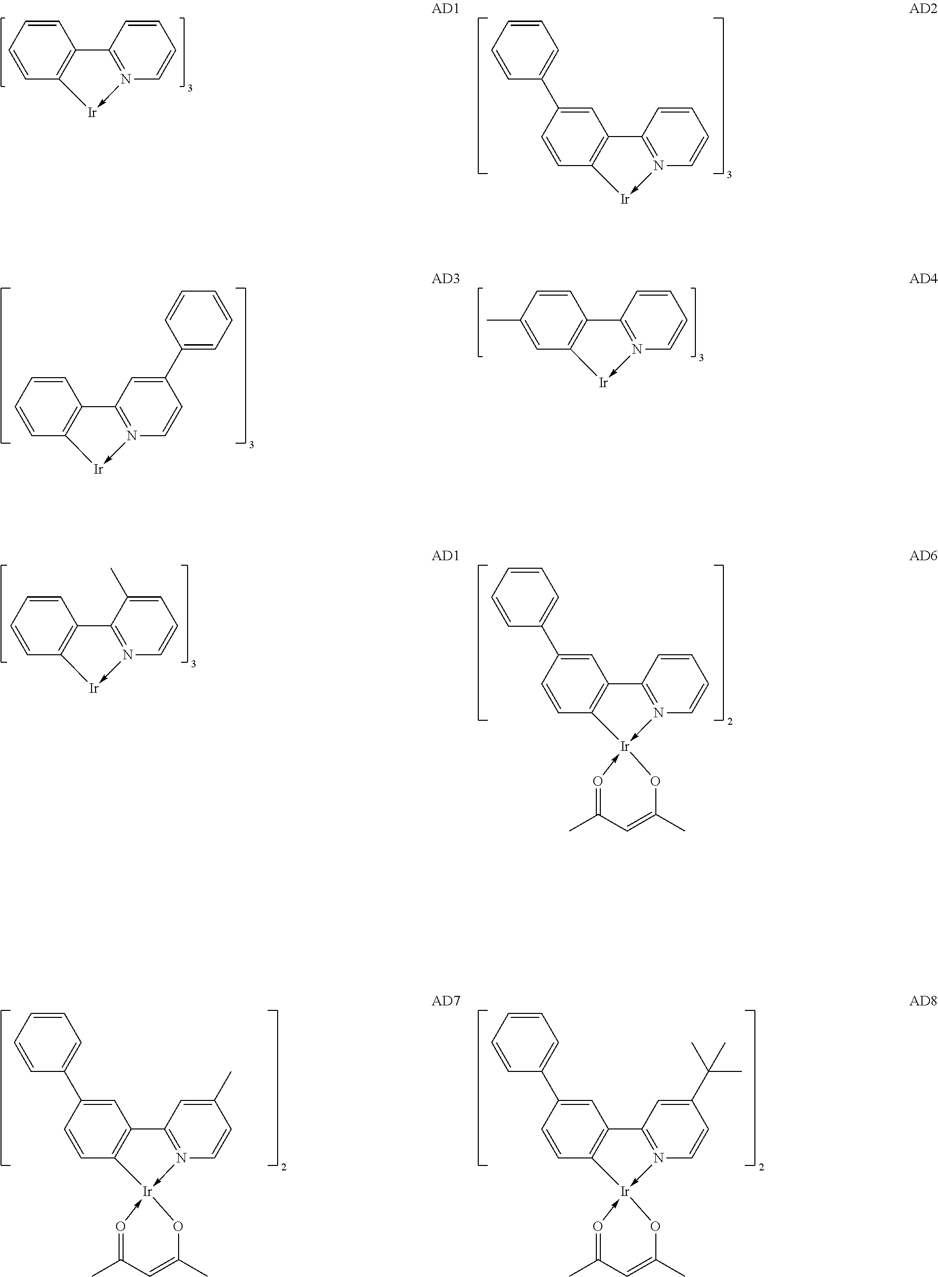

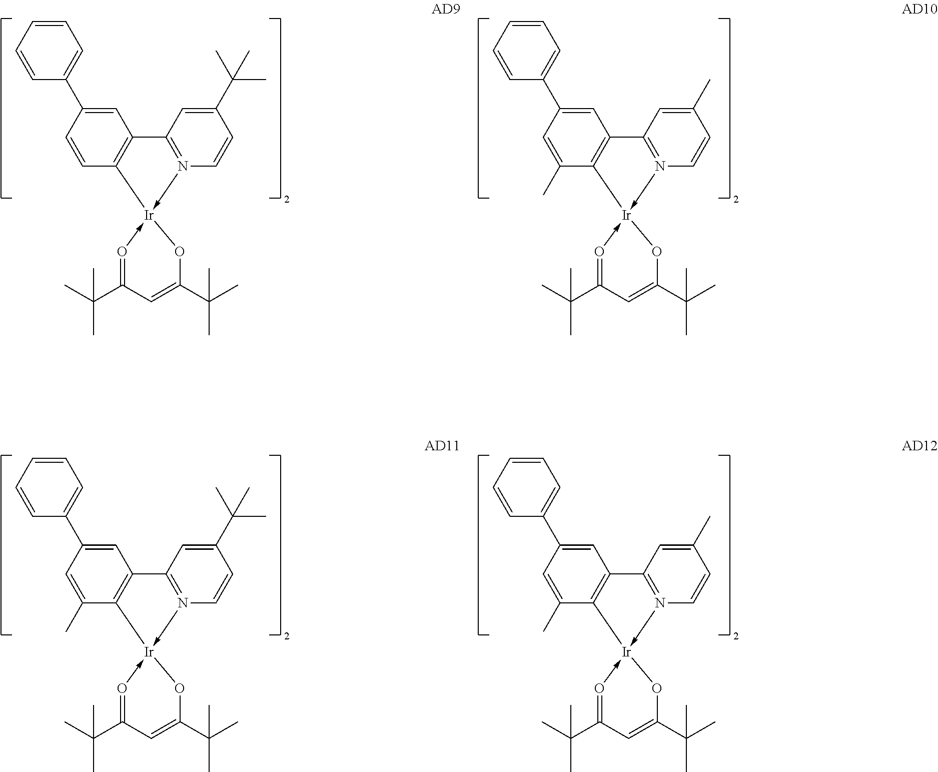

The electron transporting material can be arbitrarily selected from materials capable of transporting electrons injected from the cathode to the light emitting layer, and is selected in consideration of the balance or the like with the hole mobility of the hole transporting material. Examples of the material having an electron transporting ability include an oxadiazole derivative, an oxazole derivative, a pyrazine derivative, a triazole derivative, a triazine derivative, a quinoline derivative, a quinoxaline derivative, a phenanthroline derivative, an organic aluminum complex, and a fused ring compound (such as a fluorene derivative, a naphthalene derivative, a chrysene derivative, or an anthracene derivative). Further, the electron transporting material is also suitably used as the hole blocking layer. Specific examples of the compound used as the electron transporting material are shown below, but the present invention is not limited thereto.

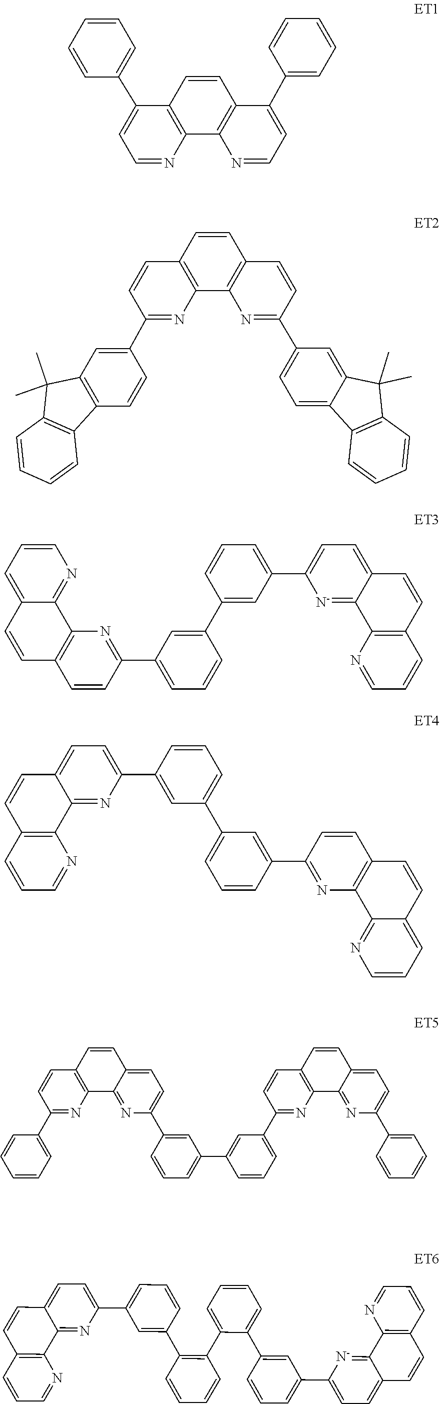

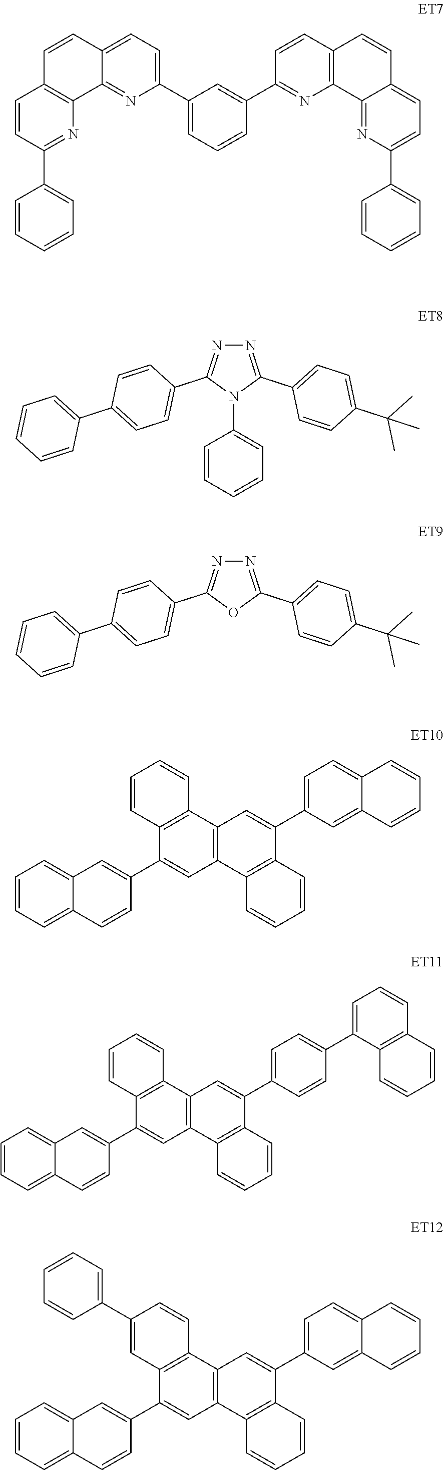

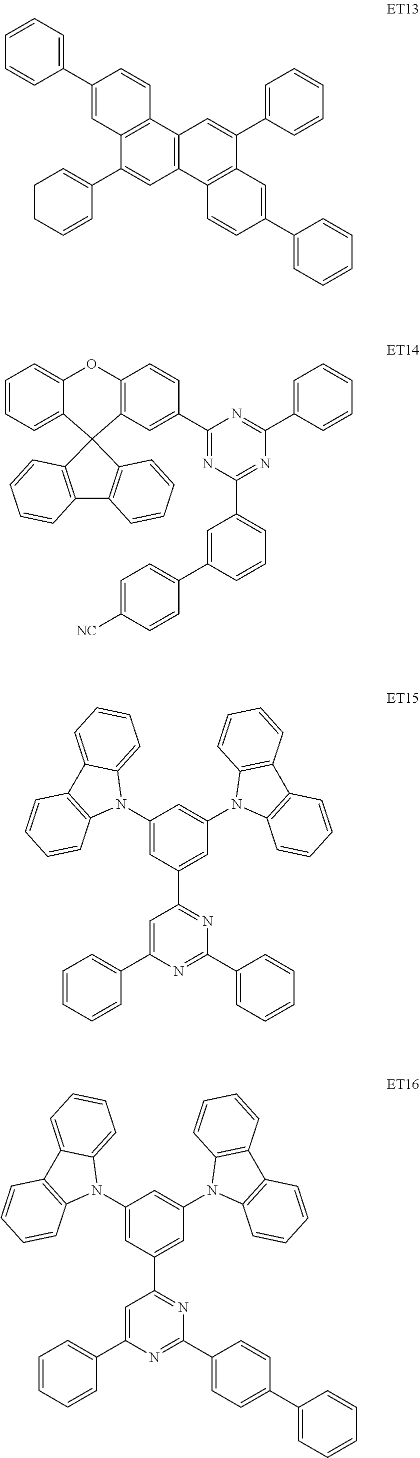

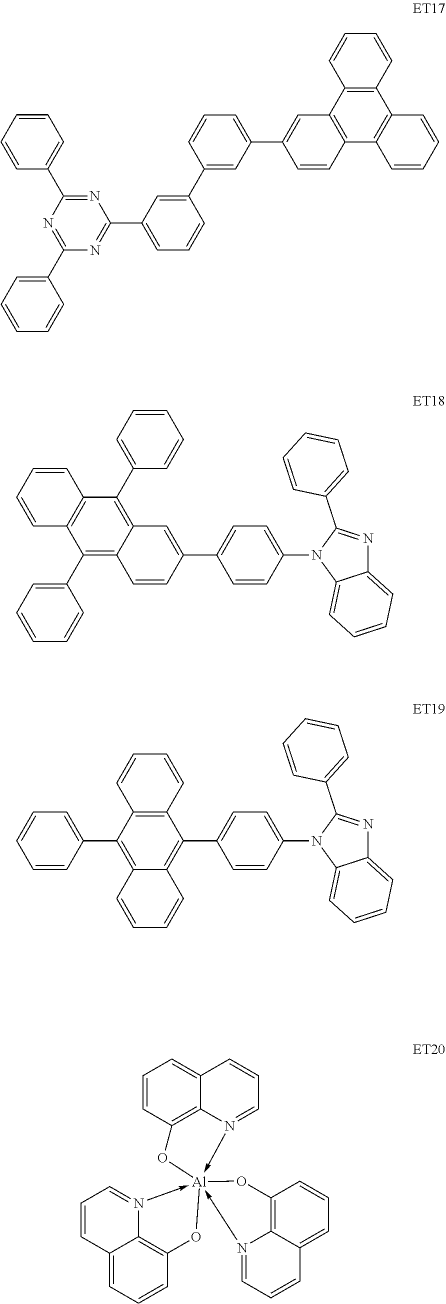

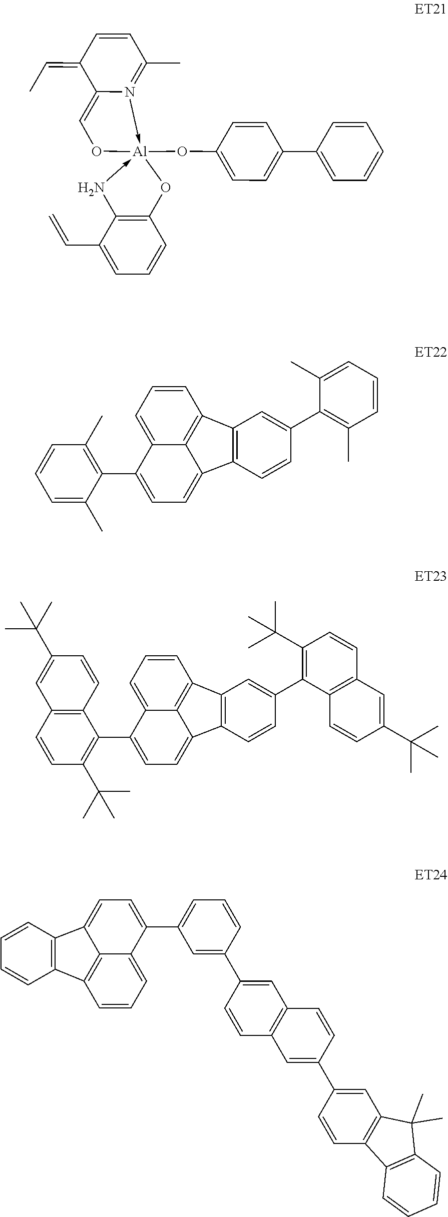

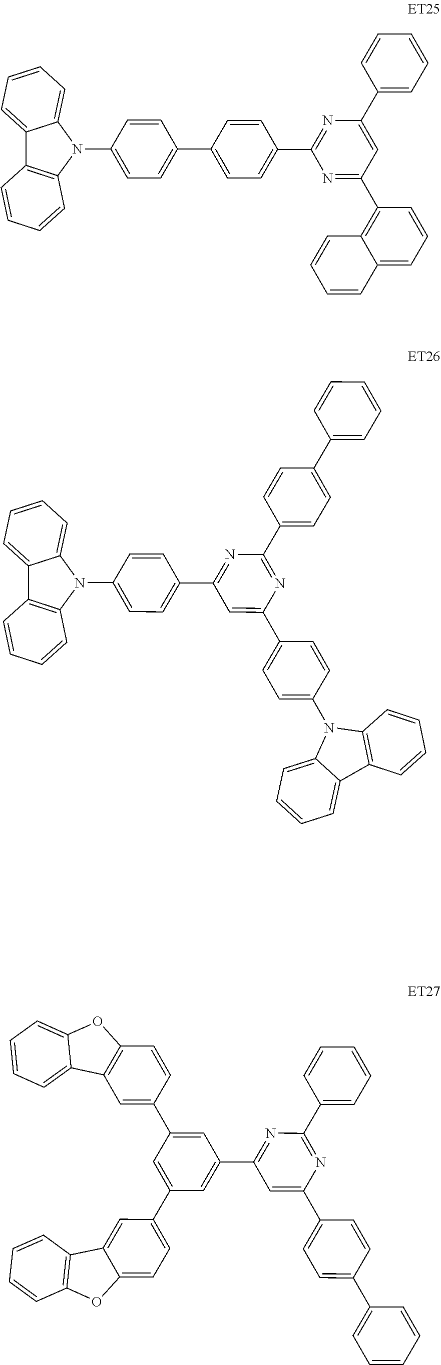 [SMILES: c1ccc(-c2cc(-c3cccc4ccccc34)nc(-c3ccc(-c4ccc(-n5c6ccccc6c6ccccc65)cc4)cc3)n2)cc1 ; c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

Hereinafter, constituent members constituting the organic light emitting element according to the present embodiment other than the organic compound layer will be described. The organic light emitting element may be provided by forming a first electrode, an organic compound layer, and a second electrode on a substrate. A protective layer, a color filter, or the like may be provided on the second electrode. When a color filter is provided, a flattening layer may be provided between the color filter and the protective layer. The flattening layer can be formed of an acrylic resin or the like.

As the substrate, quartz, glass, silicon, a resin, a metal, or the like may be used. Further, a switching element such as a transistor or a wiring is provided on the substrate, and an insulating layer may also be provided thereon. The insulating layer may be formed of any material as long as a contact hole can be formed and insulation with an unconnected wiring can be ensured in order to ensure conduction between the anode and the wiring. For example, a resin such as polyimide, silicon oxide, silicon nitride, or the like can be used as the material of the insulating layer.

A material having a work function as large as possible is suitable as the constituent material for the anode. Examples of such a material include a single metal such as gold, platinum, silver, copper, nickel, palladium, cobalt, selenium, vanadium, or tungsten, a mixture containing these metals, an alloy obtained by combining these metals, and a metal oxide such as tin oxide, zinc oxide, indium oxide, indium tin oxide (ITO), or indium zinc oxide. Further, a conductive polymer such as polyaniline, polypyrrole, or polythiophene can also be used. These electrode materials may be used alone or in combination of two or more kinds thereof. Further, the anode may be formed of a single layer or a plurality of layers. For example, a material obtained by laminating chromium, aluminum, silver, titanium, tungsten, molybdenum, or an ally thereof can be used when the material is used as a reflective electrode. The above-described material can function as a reflective film without having a role of an electrode. Further, a transport conductive layer formed of an oxide such as indium tin oxide (ITO) or indium zinc oxide can be used when the material is used as a transparent electrode, but the present invention is not limited thereto. The electrode can be formed by using a photolithography technique.

Meanwhile, a material having a small work function is preferable as the constituent material for the cathode. Examples thereof include an alkali metal such as lithium, an alkaline earth metal such as calcium, a single metal such as aluminum, titanium, manganese, silver, lead, or chromium, and a mixture thereof. Alternatively, an alloy obtained by combining these single metals can also be used. For example, magnesium-silver, aluminum-lithium, aluminum-magnesium, silver-copper, zinc-silver, or the like can be used. A metal oxide such as indium tin oxide (ITO) can also be used. These electrode materials may be used alone or in combination of two or more kinds thereof. Further, the cathode may be formed of a single layer or a plurality of layers. Among the examples, it is preferable to use silver and more preferable to use a silver alloy from the viewpoint of suppressing aggregation of silver. The alloy ratio is not limited as long as the aggregation of silver can be suppressed. For example, the alloy ratio of silver to other metals may be 1:1.

The cathode may be used as a top emission element by using an oxide conductive layer such as ITO or a bottom emission element by using a reflective electrode such as aluminum (Al), and the use thereof is not particularly limited. A method of forming the cathode is not particularly limited, but it is preferable to use a direct current sputtering method or an alternating current sputtering method from the viewpoint that the film coverage is satisfactory and the resistance is easily lowered.

A protective layer may be provided after formation of a cathode. For example, infiltration of water or the like to the organic compound layer is suppressed by making glass provided with a moisture absorbent adhere onto the cathode, and thus occurrence of display failure can be suppressed. Further, as another embodiment, a passivation film formed of silicon nitride or the like is provided on the cathode so that the infiltration of water or the like to the organic compound layer may be suppressed. For example, the cathode is formed and transported to another chamber without breaking the vacuum, and a silicon nitride film having a thickness of 2 μm is formed by a CVD method and then used as a protective layer. A protective layer may be provided by an atomic layer deposition method (ALD method) after film formation using the CVD method.

A color filter may be provided on each pixel. For example, a color filter prepared in consideration of the size of the pixel is provided on another substrate and this substrate and the substrate provided with the organic light emitting element may be bonded to each other, or a color filter may be patterned on the protective layer such as silicon oxide using a photolithography technique.

The organic compound layer (such as a positive hole injection layer, a positive hole transport layer, an electron blocking layer, a light emitting layer, a positive hole blocking layer, an electron transport layer, or an electron injection layer) constituting the organic light emitting element according to an embodiment of the present invention is formed by the following method. That is, the organic compound layer can be formed by a dry process such as a vacuum deposition method, an ionization deposition method, a sputtering method, or a plasma method. Further, a wet process of dissolving the material in an appropriate solvent to form a layer by a known coating method (such as a spin coating method, a dipping method, a cast method, an LB method, or an ink jet method) can also be used in place of the dry process. Here, when a layer is formed by a vacuum deposition method or a solution coating method, crystallization or the like is unlikely to occur and temporal stability is excellent. Further, a film can also be formed by combining the material with an appropriate binder resin when the film formation is performed by a coating method. Examples of the binder resin include a polyvinyl carbazole resin, a polycarbonate resin, a polyester resin, an ABS resin, an acrylic resin, a polyimide resin, a phenol resin, an epoxy resin, a silicon resin, and a urea resin, but the present invention is not limited thereto. Further, these binder resins may be used alone or in the form of a mixture of two or more kinds thereof, as a homopolymer or a copolymer. Further, the binder resins may be used in combination with known additives such as a plasticizer, an antioxidant, and an ultraviolet absorbing agent as necessary.

### <Device Formed of Organic Light Emitting Element>

The organic light emitting element according to the present embodiment can be used as a constituent member of a display device or a lighting device. Further, the organic light emitting element can also be used as an exposure light source of an electrophotographic image forming apparatus, a backlight of a liquid crystal display device, a light emitting device having a color filter in white light source, or the like.

The display device may be an image information processing device that includes an image input unit inputting image information from an area CCD, a linear CCD, a memory card, or the like and an information processing unit processing the input information and displays the input image on a display unit. Further, a display unit of an imaging device or an ink jet printer may have a touch panel function. The driving type of this touch panel function is not particularly limited, and may be an infrared type, a capacitance type, a resistive film type, or an electromagnetic induction type. Further, the display device may be used as a display unit of a multi-function printer.

An image can be stably displayed even for a long time with a satisfactory image quality by using a device formed of the organic light emitting element according to the present embodiment.

### <Display Device>

The display device according to the present embodiment has a plurality of pixels, and at least one of these pixels includes the organic light emitting element of the present embodiment. Further, this pixel includes the organic light emitting element according to the present embodiment and an active element. The display device may be used as a display unit of an image display device including an input unit for inputting image information and a display unit for outputting an image.

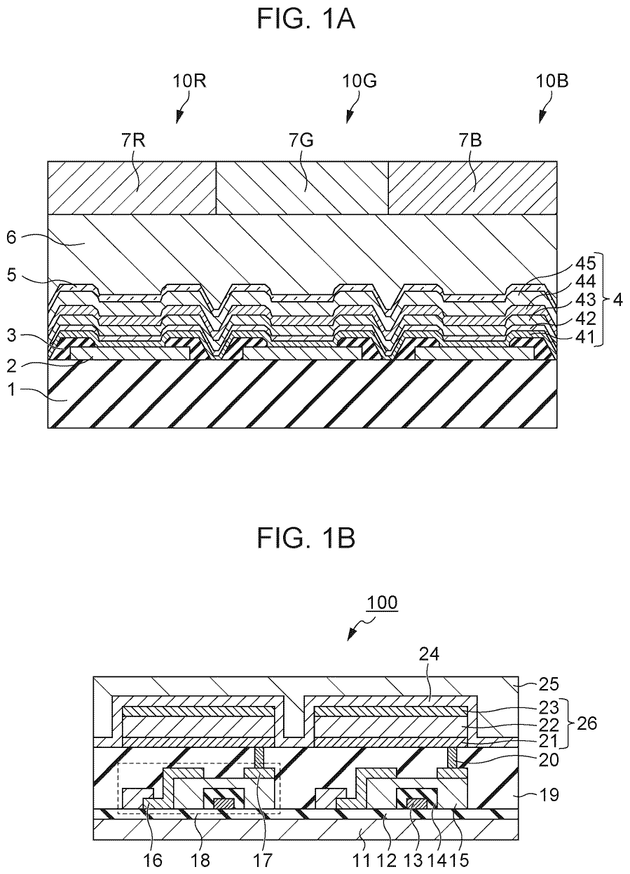

FIGS. 1A and 1B are schematic cross-sectional views showing examples of the display device according to the present embodiment.

FIG. 1A is a schematic cross-sectional view showing an example of a pixel constituting the display device according to the present embodiment. The pixel includes subpixels 10. The subpixels are divided into 10R, 10G, and 10B depending on the light emission thereof. The emission color of may be distinguished by the wavelength of light emitted from the light emitting layer, and light emitted from the subpixels may be selectively transmitted or may undergo color conversion through a color filter or the like. Each of the subpixels includes a reflective electrode 2 serving as a first electrode 2 on an interlayer insulating layer 1, an insulating layer 3 covering an end of the reflective electrode 2, an organic compound layer 4 covering the first electrode and the insulating layer, a transparent electrode 5, a protective layer 6, and a color filter 7.

The interlayer insulating layer 1 has a transistor and a capacitive element below or inside the layer. The transistor and the first electrode may be electrically connected to each other via a contact hole (not shown).

The insulating layer 3 is also referred to as a bank or a pixel separation film. The insulating layer 3 covers an end of the first electrode and is disposed to surround the first electrode. A portion where the insulating layer is not provided is a light emitting region that is in contact with the organic compound layer 4.

The organic compound layer 4 includes a positive hole injection layer 41, a positive hole transport layer 42, a first light emitting layer 43, a second light emitting layer 44, and an electron transport layer 45.

The second electrode 5 may be a transparent electrode or a reflective electrode or may be a semi-transparent electrode.

The protective layer 6 reduces infiltration of moisture to the organic compound layer. The protective layer is shown to be formed of a single layer, but may be formed of a plurality of layers. Each layer may be formed of an inorganic compound layer and an organic compound layer.

The color filter 7 is divided into 7R, 7G, and 7B depending on the color thereof. The color filter may be formed on a flattening film (not shown). Further, a resin protective layer (not shown) may be provided on the color filter. Further, the color filter may be formed on the protective layer 6. Alternatively, the color filter may be provided on a counter substrate such as a glass substrate and bonded thereto.

FIG. 1B is a schematic cross-sectional view showing an example of a display device including an organic light emitting element and a transistor connected to the organic light emitting element. An organic light emitting element 26 includes an anode 21, an organic compound layer 22, and a cathode 23. The transistor is an example of an active element. The transistor may be a thin film transistor (TFT).

A display device 100 of FIG. 1B includes a substrate 11 such as glass or silicon and an insulating layer 12 on the substrate 11. An active element 18 such as a TFT is disposed on the insulating layer, and a gate electrode 13 of the active element, a gate insulating film 14, and a semiconductor layer 15 are disposed on the insulating layer. The TFT 18 is also formed of the semiconductor layer 15, a drain electrode 16 and a source electrode 17. An insulating film 19 is provided on the TFT 18. An anode 21 constituting the organic light emitting element and the source electrode 17 are connected to each other via a contact hole 20 provided on the insulating film.

In addition, the electrical connection type between electrodes (the anode and the cathode) of the organic light emitting element 26 and electrodes (the source electrode and the drain electrode) of the TFT is not limited to the aspect shown in FIG. 1B. That is, any one of the anode or the cathode and any one of the source electrode and the drain electrode of the TFT may be electrically connected. The TFT denotes a thin film transistor.

In the display device 100 of FIG. 1B, the organic compound layer is shown to be formed of one layer, but the organic compound layer 22 may be formed of a plurality of layers. A first protective layer 24 or a second protective layer 25 is provided on the cathode 23 in order to reduce deterioration of the organic light emitting element.

In the display device 100 of FIG. 1B, a transistor is used as a switching element, but a different element may also be used as a switching element.

Further, the transistor used in the display device 100 of FIG. 1B is not limited to a transistor obtained by using a single crystal silicon wafer, but may be a thin film transistor having an active layer on an insulating surface of a substrate. Examples of the active layer include single crystal silicon, non-single crystal silicon such as amorphous silicon or microcrystalline silicon, and a non-single crystal oxide semiconductor such as an indium zinc oxide or an indium gallium zinc oxide. Further, the thin film transistor is also referred to as a TFT element.

The transistor in the display device 100 of FIG. 1B may be formed in a substrate such as a Si substrate. Here, the expression “formed in a substrate” denotes that a transistor is prepared by processing the substrate such as a Si substrate. That is, the concept of the transistor being formed in a substrate can also denote that the substrate and the transistor are integrally formed.

The light emission brightness of the organic light emitting element according to the present embodiment is controlled by the TFT which is an example of a switching element, and in a case where a plurality of the organic light emitting elements are provided in a plane, an image can be displayed by the light emission brightness of each organic light emitting element. Further, the switching element according to the present embodiment is not limited to a TFT, and may be a transistor formed of low-temperature polysilicon or an active matrix driver formed on a substrate such as a Si substrate. The formation can be made not only on the substrate but also in the substrate. Whether the transistor is provided in the substrate or the TFT is used is selected depending on the size of the display unit, and it is preferable that the organic light emitting element be provided on a Si substrate when the size of the display unit is, for example, about 0.5 inches.

The display device may include a plurality of a light emitting elements. The light emitting element may include a driving circuit. The driving circuit may be of an active matrix type to control light emission of each of the first light emitting element and the second light emitting element independently. The active matrix type circuit may be of a voltage programming type or a current programming type. The driving circuit has a pixel circuit for each pixel. The pixel circuit may have a light emitting element, a transistor that controls light emission brightness of the light emitting element, a transistor that controls the emission timing, a capacity that maintains the gate voltage of the transistor controlling the light emission brightness, and a transistor for connection to GND without using the light emitting element.

The distance between the light emitting elements constituting the light emitting device may be 10 μm, 7 μm, or 5 μm or less.

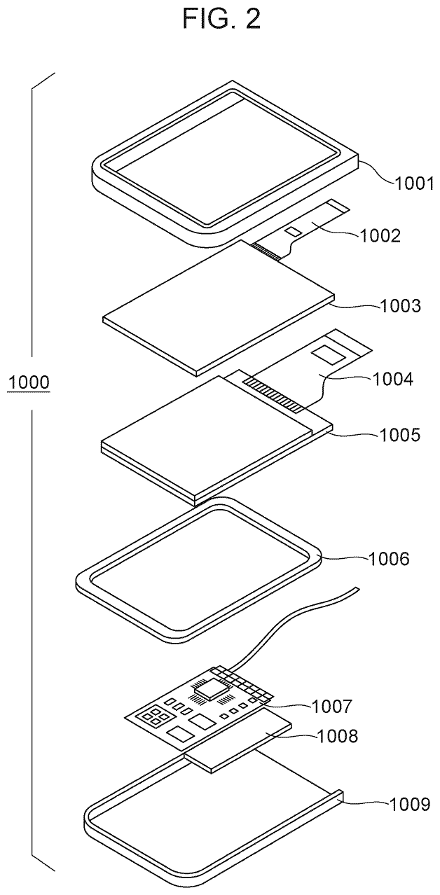

FIG. 2 is a schematic view showing an example of the display device according to the present embodiment. A display device 1000 may include a touch panel 1003, a display panel 1005, a frame 1006, a circuit board 1007, and a battery 1008 between an upper cover 1001 and a lower cover 1009. Flexible printed circuits FPC 1002 and 1004 are respectively connected to the touch panel 1003 and the display panel 1005. The organic light emitting element according to the present embodiment may be used in the display panel 1005. A transistor is printed on the circuit board 1007. The battery 1008 may not be provided unless the display device is a portable device, and does not need to be provided at this position even when the display device is a portable device.

### <Imaging Device>

The display device according to the present embodiment may be used as a display unit of a photoelectric conversion device such as an imaging device including an optical unit that has a plurality of lenses and an imaging element that receives light having passed through the optical unit. The photoelectric conversion device may include a display unit displaying information acquired by the imaging element. Further, the display unit may be a display unit exposed to the outside of the photoelectric conversion device or a display unit disposed in a viewfinder. The photoelectric conversion device may be a digital camera or a digital video camera.

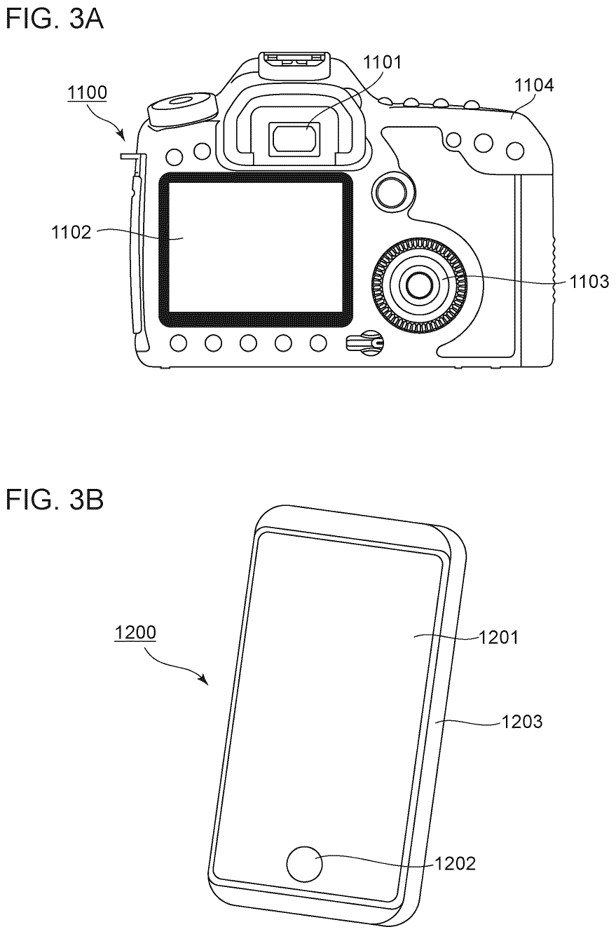

FIG. 3A is a schematic view showing an example of an imaging device according to the present embodiment. An imaging device 1100 may include a viewfinder 1101, a rear display 1102, an operation unit 1103, and a housing 1104. The viewfinder 1101 may include the display device according to the present embodiment. In this case, the display device may display not only an image to be imaged but also environmental information, imaging instructions, and the like. The environmental information may include the intensity of external light, the orientation of external light, the moving speed of a subject, and the possibility that a subject is shielded by a shielding material. The suitable timing for imaging is only a short time, and thus information is required to be displayed as early as possible. Therefore, it is preferable that a display device formed of the organic light emitting element according to the present invention be used from the viewpoint that the organic light emitting element has a fast response speed. The display device formed of the organic light emitting element can be more suitably used than a liquid crystal display device among devices required to have a high display speed. The imaging device 1100 includes an optical unit (not shown). The optical unit includes a plurality of lenses and forms an image on an imaging element accommodated in the housing 1104. The focal point can be adjusted by adjusting the relative positions of the plurality of lenses. This operation can also be automatically performed.

### <Electronic Device>

The display device according to the present embodiment may be used as a display unit of an electronic device such as a portable terminal. In this case, the display device may have both a display function and an operation function. Examples of the portable terminal include a mobile phone such as a smartphone, a tablet, and a head-mounted display.

FIG. 3B shows an example of an electronic device including the display device according to the present embodiment. A portable device 1200 includes a display unit 1201, an operation unit 1202, and a housing 1203. The housing 1203 may include a circuit, a printed circuit board including the circuit, a battery, and a communication unit. The operation unit 1202 may be in the form of a button or may be a touch panel type reaction unit. The operation unit may be a biometric authentication unit that identifies fingerprints, performs unlocking, and the like. The portable device including a communication unit can also be used as a communication device.

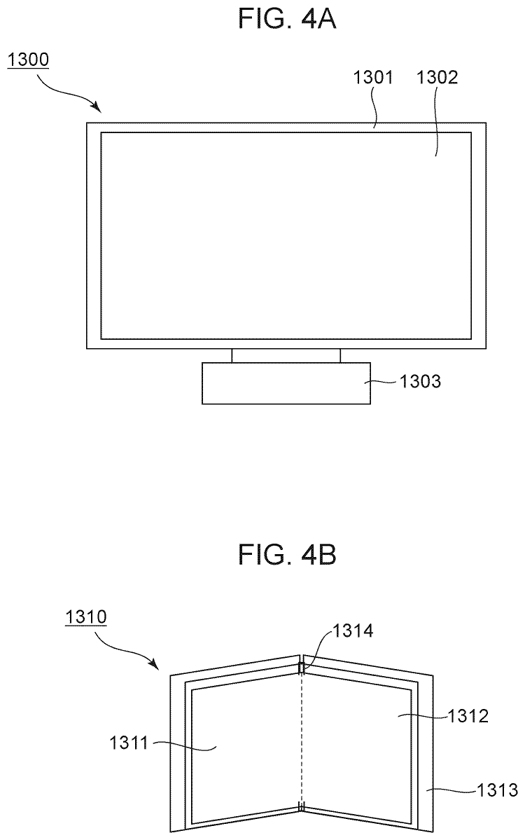

FIGS. 4A and 4B are schematic views showing examples of the display device according to the present embodiment. FIG. 4A shows a display device such as a television monitor or a PC monitor. A display device 1300 includes a frame 1301 and a display unit 1302. The display unit 1302 may be formed of the organic light emitting element according to the present embodiment. The display device 1300 includes a base 1303 that supports the frame 1301 and the display unit 1302. The base 1303 is not limited to the form shown in FIG. 4A. The lower side of the base 1301 may also serve as a base. Further, the frame 1301 and the display unit 1302 may be curved. The curvature radius thereof may be 5000 mm or greater and 6000 mm or less.

A display device 1310 of FIG. 4B is a so-called foldable display device that is formed to be foldable. The display device 1310 includes a first display unit 1311, a second display unit 1312, a housing 1313, and a bending point 1314. The first display unit 1311 and the second display unit 1312 may include the organic light emitting element according to the present embodiment. The first display unit 1311 and the second display unit 1312 may be one seamless display device. The first display unit 1311 and the second display unit 1312 can be divided at the bending point. The first display unit 1311 and the second display unit 1312 may each display different images or the first display unit and the second display unit may also display one image.

### <Lighting Device>

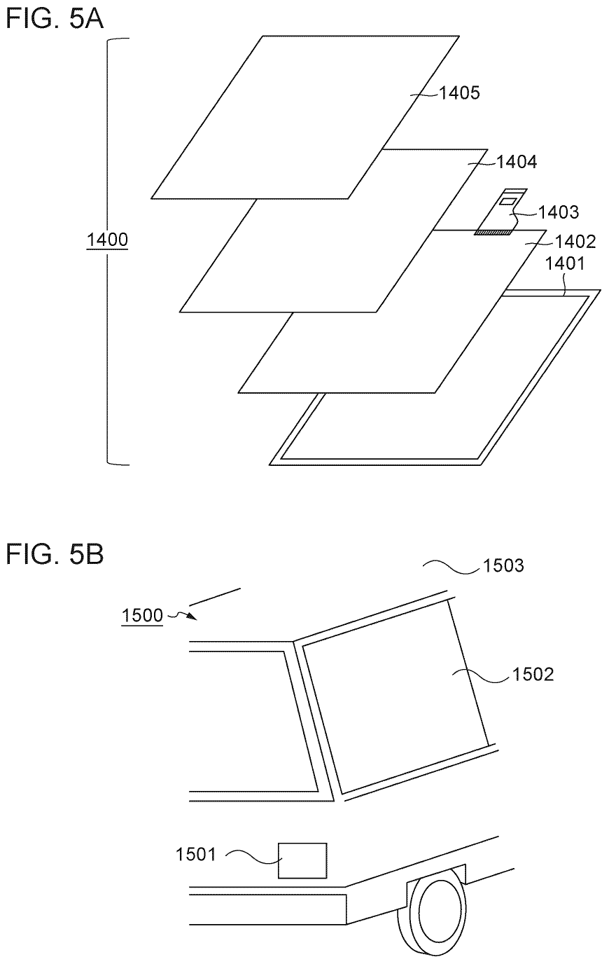

FIG. 5A is a schematic view showing an example of a lighting device according to the present embodiment. A lighting device 1400 may include a housing 1401, a light source 1402, a circuit board 1403, an optical film 1404, and a light diffusion unit 1405. The light source 1402 may include the organic light emitting element according to the present embodiment. The optical film 1404 may be a film that improves the color rendering properties of the light source 1402. The light diffusion unit 1405 effectively diffuses light of the light source 1402 by performing lighting up or the like and thus can deliver the light to a wide range. A cover may be provided on the outermost portion.

The lighting device is, for example, a device that lights up a room. The lighting device may emit light of white, neutral white, and any other colors from blue to red. The lighting device may include a light control circuit that controls light of these colors. The lighting device may include the organic light emitting element of the present invention and a power supply circuit connected to the organic light emitting element. The power supply circuit is a circuit that converts an alternating current voltage to a direct current voltage. The lighting device may include an inverter circuit. Further, white has a color temperature of 4,200K and neutral white has a color temperature of 5,000K. The lighting device may include a color filter. Further, the lighting device according to the present embodiment may include a heat radiation unit. The heat radiation unit releases heat inside the device to the outside of the device, and examples thereof include a metal with high specific heat and liquid silicon.

### <Moving Body>

The moving body according to the present embodiment may be an automobile, a ship, an aircraft, a drone, or the like. The moving body may include a machine body and a lamp provided on the machine body. The lamp may emit light to inform of the position of the machine body. The lamp includes the organic light emitting element according to the present embodiment.

FIG. 5B is a schematic view showing an example of the moving body according to the present embodiment, which is a view showing an automobile having a tail lamp as an example of the lamp for a vehicle. An automobile 1500 includes a tail lamp 1501 and may be in the form of turning on the tail lamp 1501 when a brake operation is performed. The tail lamp 1501 may include the organic light emitting element according to the present embodiment. The tail lamp 1501 may include a protective member that protects the organic light emitting element. The protective member is not limited as long as the protective member has a certain high degree of strength and is transparent, but it is preferable that the protective member be formed of polycarbonate or the like. The polycarbonate may be mixed with a furandicarboxylic acid derivative, an acrylonitrile derivative, or the like. The automobile 1500 may include a car body 1503 and a window 1502 attached to the car body 1503. The window 1502 may be a transparent display when the window is not used to confirm the front and rear of the automobile 1500. The transparent display may include the organic light emitting element according to the present embodiment. In this case, the constituent material such as the electrode of the organic light emitting element is formed of a transparent member.

The moving body according to the present embodiment may be a ship, an aircraft, a drone, or the like. The moving body may include a machine body and a lamp provided on the machine body. The lamp may emit light to inform of the position of the machine body. The lamp includes the organic light emitting element according to the present embodiment.

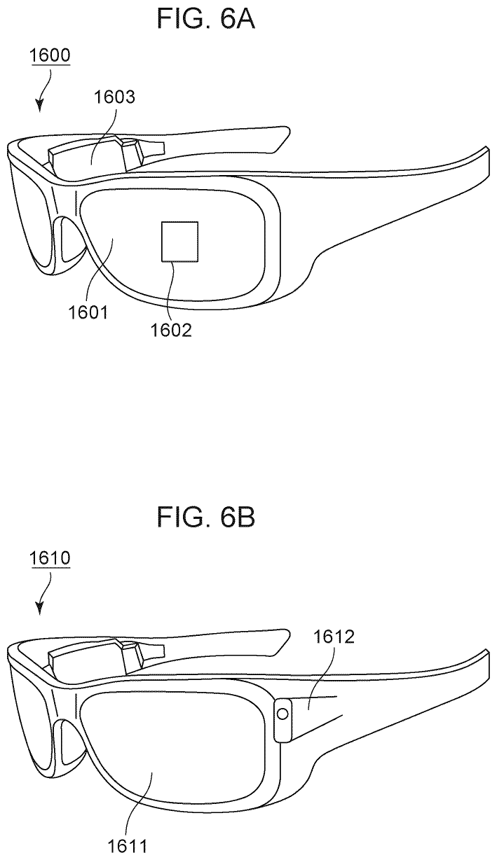

Application examples of the display device according to each of the above-described embodiments will be described with reference to FIGS. 6A and 6B. The display device can be applied to a system that can be mounted as a wearable device such as smart glasses, a HMD, or a smart contact. An imaging display device used in such application examples includes an imaging device capable of photoelectrically converting visible light and a display device capable of emitting visible light.

FIG. 6A shows glasses 1600 (smart glasses) according to one application example. An imaging device 1602 such as a CMOS sensor or a SPAD is provided on the front surface side of a lens 1601 of the glasses 1600. Further, the display device according to each embodiment described is provided on the rear surface side of the lens 1601.

The glasses 1600 further include a control device 1603. The control device 1603 functions as a power supply that supplies power to the imaging device 1602 and the display device according to each embodiment. Further, the control device 1603 controls the operations of the imaging device 1602 and the display device. An optical system for condensing light on the imaging device 1602 is formed on the lens 1601.

FIG. 6B shows glasses 1610 (smart glasses) according to one application example. The glasses 1610 include a control device 1612, and the control device 1612 is equipped with an imaging device corresponding to the imaging device 1602 and a display device. A lens 1611 is formed with the imaging device in the control device 1612 and an optical system for projecting light emitted from the display device, and an image is projected on the lens 1611. The control device 1612 functions as a power supply that supplies power to the imaging device and the display device and controls the operations of the imaging device and the display device. The control unit may include a visual line detection unit that detects the visual line of a wearer. The visual line may be detected by infrared rays. An infrared light emitting unit emits infrared light to the eyeballs of a user gazing a displayed image. A captured image of the eyeballs is obtained by detecting reflected light from the eyeballs to which infrared light has been emitted, using an imaging unit including a light receiving element. Degradation of the image quality is reduced by providing a reduction unit that reduces light from the infrared light emitting unit to the display unit in plan view.

The visual line of a user with respect to the displayed image from the captured image of the eyeballs obtained by capturing infrared light is detected. The detection of the visual line using the captured image of the eyeballs can be performed by employing any known method. As an example, a method of detecting the visual line based on a Purkinje image using reflection of light radiated to the cornea can be used.

More specifically, a visual line detection treatment is performed by a pupillary corneal reflection method. The visual line of the user is detected by calculating a visual line vector representing the orientation (rotation angle) of the eyeballs based on the pupil image and the Purkinje image included in the captured image of the eyeballs.

The display device according to an embodiment of the present invention includes an imaging device having a light receiving element and may control a displayed image of the display device based on visual line information of the user from the imaging device.

Specifically, the display device determines a first visual field region at which the user gazes and a second visual field region other than the first visual field region based on visual line information. The first visual field region and the second visual field region may be determined by the control device of the display device, or an external control device determines any of the regions and the result may be received. In a display region of the display device, the display resolution of the first visual field region may be controlled to be higher than the display resolution of the second visual field region. That is, the resolution of the second visual field region may be set to be less than the resolution of the first visual field region.

Further, the display region has the first display region and the second display region different from the first display region, and a region with high priority is determined from the first display region and the second display region based on visual line information. The first display region and the second display region may be determined by the control device of the display device, or an external control device determines any of the regions and the result may be received. The resolution of the region with a high priority may be controlled to be higher than the resolution of the region other than the region with a high priority. That is, the resolution of the region with a relatively lower priority may be decreased.

Further, the first visual field region and the region with a higher priority may be determined by using AI. The AI may be a model formed to estimate the angle of the visual line from the image of the eyeballs and the distance from the eyeballs of the image to the object in front of the visual line, using the image of the eyeballs and the direction in which the eyeballs of the image are actually gazing as teaching data. The display device, the imaging device, or an external device may have an AI program. When an external device has the AI program, the AI program is transmitted to the display device through communication.

When display is controlled based on visual line detection, an imaging device that captures an image of the outside can be preferably applied to smart glasses. The smart glasses can display captured external information in real time.

As described above, an image with a satisfactory image quality can be stably displayed for a long time by using a device formed of the organic light emitting element according to the present embodiment.

### EXAMPLES

Hereinafter, examples will be described. However, the present invention is not limited these examples.

### Example 1

### Synthesis of Exemplary Compound 8

An exemplary compound 8 was synthesized in the following manner.

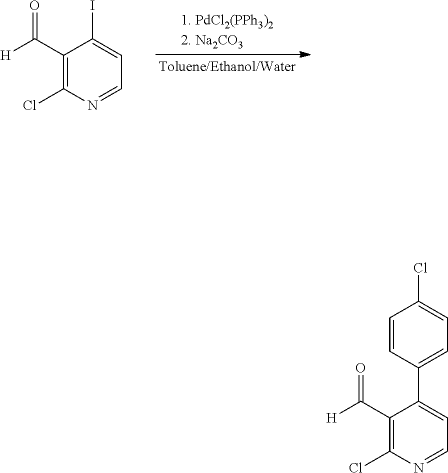 [SMILES: O=Cc1c(I)ccnc1Cl ; O=Cc1c(-c2ccc(Cl)cc2)ccnc1Cl]

### Intermediate 1

A 2,000 mL eggplant flask was charged with 59.64 g of 4-chlorophenylboronic acid, 100.00 g of 2-chloro-3-formyl-4-iodopyridine, 800 mL of toluene, 250 mL of ethanol, 600 mL of water, and 79.26 g of sodium carbonate in a nitrogen atmosphere. The mixture was heated to 90° C. from room temperature and stirred for 6 hours. Toluene and water were added thereto to extract an organic layer, magnesium sulfate was added to the extracted organic layer, and the resultant was filtered. After concentration, the resultant was washed with methanol, thereby obtaining 85.61 g of an intermediate 1 (yield of 90%). The structure thereof was identified by ¹H-NMR and GC-MS.

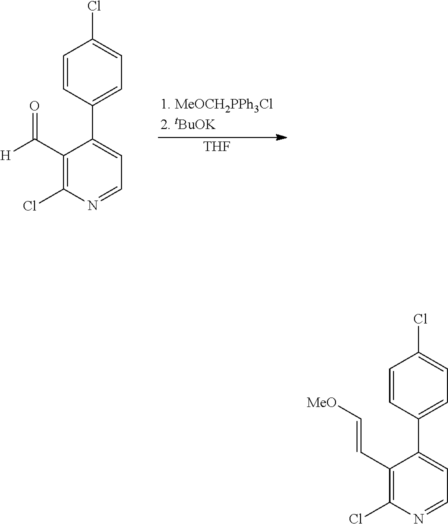

### Intermediate 2

A 1,000 mL three-necked eggplant flask was charged with 114.22 g of (methoxymethyl)triphenyl phosphonium chloride and 560 mL of dehydrated THF, and the mixture was stirred in a nitrogen atmosphere. 44.89 g of tert-butoxypotassium was added thereto little by little in a powder form while the reaction container was cooled in an ice bath, and the mixture was stirred for 30 minutes in the ice bath. After 30 minutes, 56.00 g of the intermediate 1 was added thereto in a powder form, the temperature was returned to room temperature, and the mixture was stirred for 1 hour. Toluene and water were added thereto, magnesium sulfate was added to the extracted organic layer, and the resultant was filtered. After concentration, column purification was performed with toluene, thereby obtaining 74.20 g of an intermediate 2 (yield of 88%). The structure thereof was identified by ¹H-NMR and GC-MS.

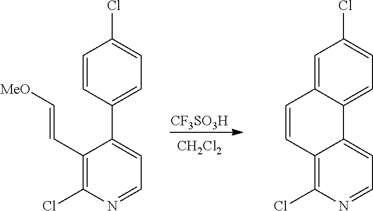

### Intermediate 3

A 2,000 mL eggplant flask was charged with 195 mL of trifluoromethanesulfonic acid and 930 mL of dichloromethane in a nitrogen atmosphere. 62.00 g the intermediate 2 was added dropwise thereto while the reaction container was cooled in an ice bath. The temperature was returned to room temperature, the mixture was stirred for 2 hours, a sodium hydroxide aqueous solution was added thereto for neutralization, and dichloromethane and water were used to extract an organic layer. Magnesium sulfate was added to the obtained organic layer, the resultant was filtered and concentrated, and the obtained solid was washed with methanol, thereby obtaining 41.73 g of an intermediate 3 (yield of 76%). The structure thereof was identified by ¹H-NMR and GC-MS.

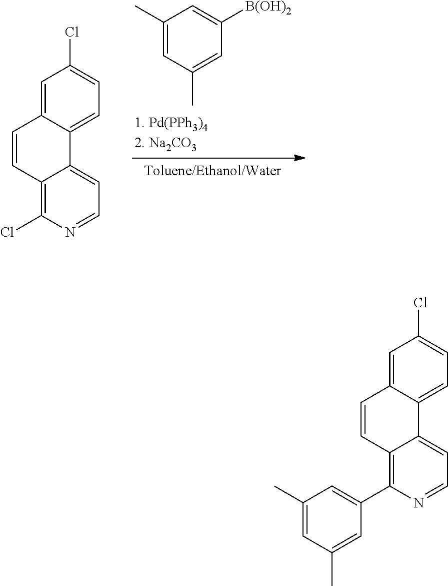 [SMILES: Clc1ccc2c(ccc3c(Cl)nccc32)c1 ; Cc1cc(C)cc(B(O)O)c1 ; Cc1cc(C)cc(-c2nccc3c2ccc2cc(Cl)ccc23)c1]

### Intermediate 4

A 500 mL eggplant flask was charged with 20.00 g of the intermediate 3, 11.44 g of 3,5-dimethylphenylboronic acid, 0.86 g of tetrakistriphenylphosphine palladium, 160 mL of toluene, 50 mL of ethanol, 120 mL of water, and 15.85 g of sodium carbonate in a nitrogen atmosphere. The mixture was heated to 90° C. from room temperature and stirred for 3 hours. After completion of the reaction, toluene and water were added thereto to extract an organic layer, magnesium sulfate was added to the extracted organic layer, and the resultant was filtered. After concentration, the obtained residues were subjected to column purification with toluene and washed with methanol, thereby obtaining 24.00 g of an intermediate 4 (yield of 93%). The structure thereof was identified by ¹H-NMR and LC-MS.

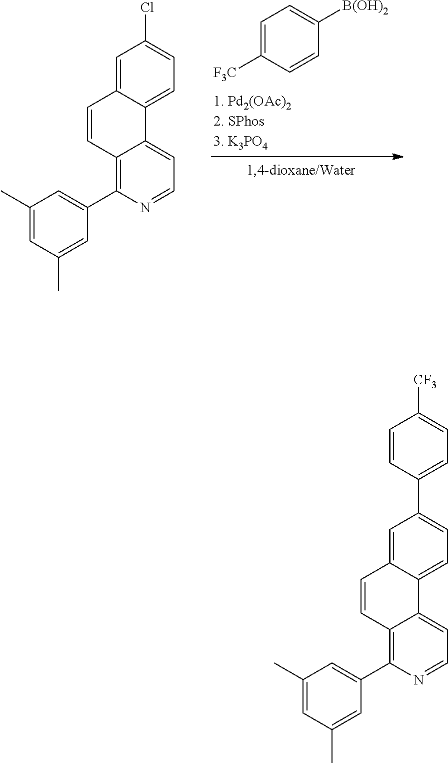 [SMILES: Cc1cc(C)cc(-c2nccc3c2ccc2cc(Cl)ccc23)c1 ; OB(O)c1ccc(C(F)(F)F)cc1 ; Cc1cc(C)cc(-c2nccc3c2ccc2cc(-c4ccc(C(F)(F)F)cc4)ccc23)c1]

### Intermediate 5

A 500 mL eggplant flask was charged with 16.00 g of the intermediate 4, 10.52 g of 4-trifluoromethylphenylboronic acid, 1.13 g of palladium acetate, 6.20 g of SPhos, 24.04 g of potassium phosphate, 240 mL of 1,4-dioxane, and 80 mL of water in a nitrogen atmosphere. The mixture was heated to 90° C. from room temperature and stirred for 2 hours. After completion of the reaction, water was poured thereto, the precipitated solid was filtered, and the obtained solid was washed with methanol and water. Thereafter, column chromatography was performed with toluene, thereby obtaining 17.45 g of an intermediate 5 (yield of 81%). The structure thereof was identified by ¹H-NMR and LC-MS.

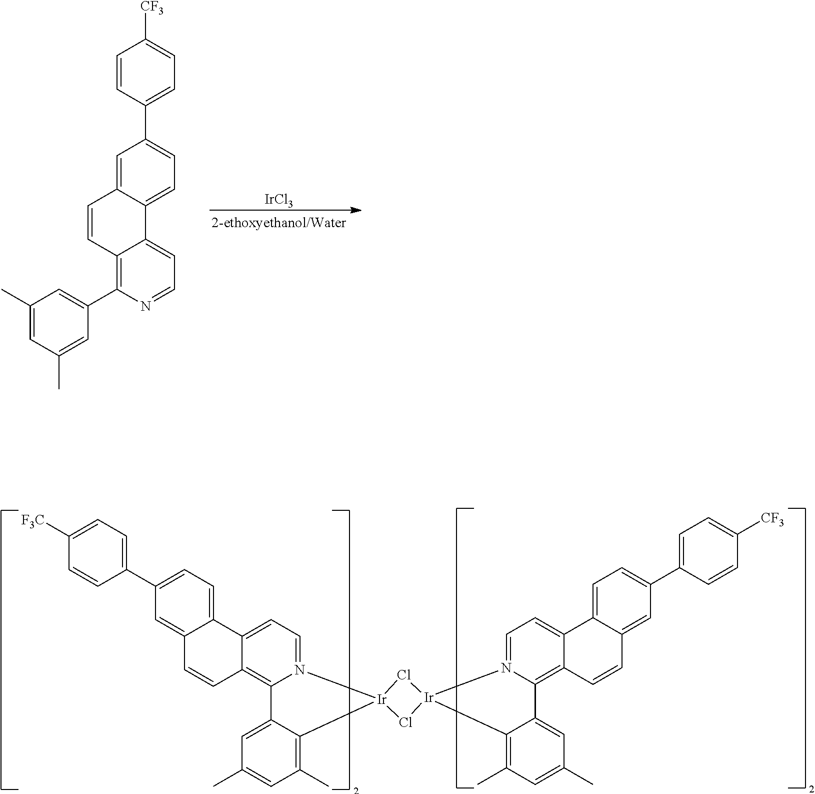

### Intermediate 6

A 500 mL eggplant flask was charged with 16.00 g of the intermediate 5, 6.44 g of an iridium chloride trihydrate, 206 mL of 2-methoxyethanol, and 103 mL of water in a nitrogen atmosphere. The mixture was heated to 120° C. from room temperature and stirred for 20 hours. After completion of the reaction, the precipitated solid was filtered, and the obtained solid was washed with methanol, thereby obtaining 13.0 g of an intermediate 6 (yield of 67%). The structure thereof was identified by ¹H-NMR and LC-MS.

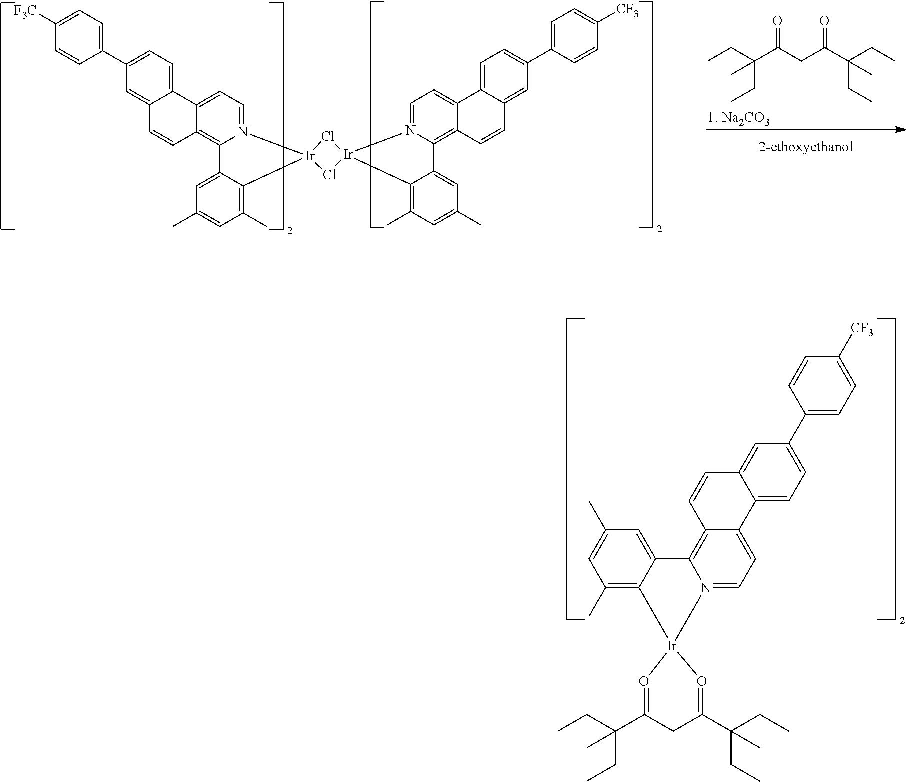

### Exemplary Compound 8

A 300 mL eggplant flask was charged with 6.00 g of the intermediate 6, 3.34 g of 3,7-diethyl-3,7-dimethylnonane-4,6-dione, 180 mL of 2-ethoxyethanol, and 1.47 g of sodium carbonate in a nitrogen atmosphere. The mixture was heated to 120° C. from room temperature and stirred for 3 hours. After completion of the reaction, the precipitated solid was filtered, and the obtained solid was washed with ethanol, thereby obtaining 5.70 g of a target exemplary compound 8 (yield of 80%). The structure thereof was identified by ¹H-NMR and LC-MS.

Further, the synthesized exemplary compound 8 was dissolved in toluene at a concentration of 1.0×10⁻⁵ M, the photoluminescence (PL) spectrum was measured, and as a result, red light emission with an emission wavelength of 620 nm was exhibited. [Evaluation of horizontal aligning properties of light emitting materials used in Comparative Examples 1 to 7]

Compounds A to G were synthesized in the same manner as in Example 1 as light emitting iridium complexes used in the device evaluation of Comparative Examples 1 to 7. Further, the permanent dipole moments and the horizontal alignment ratios were calculated by performing molecular calculation on the compounds A to G. The calculated permanent dipole moments and the calculated horizontal alignment ratios, and the types of substituents corresponding to R¹² in General Formulae [1] and [2] are listed in Table 1. In addition, a case where the corresponding substituent satisfied the condition of a para Hammett constant (op) of 0.5 or greater was evaluated as 0, and a case where the corresponding substituent did not satisfy the condition was evaluated as X in Table 1. [Evaluation of horizontal aligning properties of light emitting materials used in Examples 2 to 15]

A compound (1), a compound (3), a compound (6), a compound (8), a compound (12), a compound (15), a compound (16), a compound (19), a compound (20), a compound (24), a compound (31), a compound (33), a compound (34), and a compound (45) were synthesized by the same method as in Example 1 as the light emitting iridium complexes used in the device evaluation of Examples 2 to 15. Further, the permanent dipole moments and the horizontal alignment ratios were calculated by performing molecular calculation in the same manner as that for the compounds of Comparative Examples 1 to 7. The results are listed in Table 1.

TABLE 1

| | | | | Para Hammett |
|---|---|---|---|---|
| | Permanent | Alignment | Substituent | constant (σρ) of |
| Compound | dipole moment | prediction (%) | as R¹² | 0.5 or greater |
| Compound A | 2.3026 | 69.9 | — | × |
| Compound B | 3.0371 | 80.8 | H | × |
| Compound C | 1.8114 | 85.6 | F | × |
| Compound D | 2.6660 | 85.4 | H | × |
| Compound E | 1.8557 | 89.2 | F | × |
| Compound F | 1.5230 | 89.8 | F | × |
| Compound G | 3.9732 | 85.7 | CHF₂ | × |
| Compound (1) | 0.6949 | 92.3 | CF₃ | ○ |
| Compound (3) | 0.4603 | 96.9 | CF₃ | ○ |
| Compound (6) | 0.2628 | 90.1 | CN | ○ |
| Compound (8) | 0.6949 | 92.3 | CF₃ | ○ |
| Compound (12) | 0.3794 | 96.6 | OCOCF₃ | × |
| Compound (15) | 0.0810 | 95.2 | SiF₃ | ○ |
| Compound (16) | 0.4196 | 91.3 | COF | ○ |
| Compound (19) | 0.5360 | 91.6 | F | × |
| Compound (20) | 1.2518 | 94.8 | CF₃ | ○ |
| Compound (24) | 1.2066 | 91.0 | H | × |
| Compound (31) | 0.5071 | 100.0 | CF(CF)₃ | ○ |
| Compound (33) | 0.6671 | 96.3 | CF₃ | ○ |
| Compound (34) | 0.9854 | 95.4 | H | × |
| Compound (45) | 0.3031 | 95.6 | CF₃ | ○ |

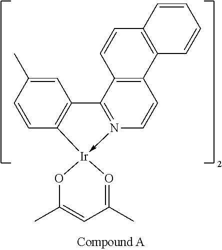

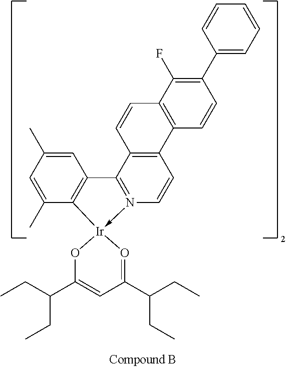

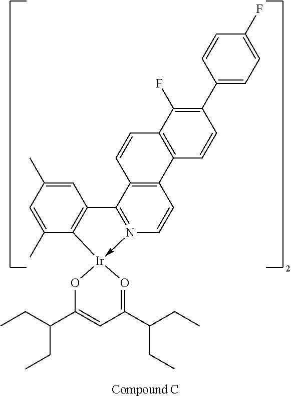

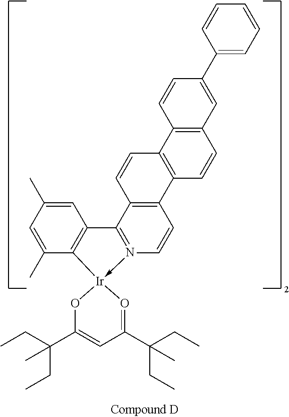

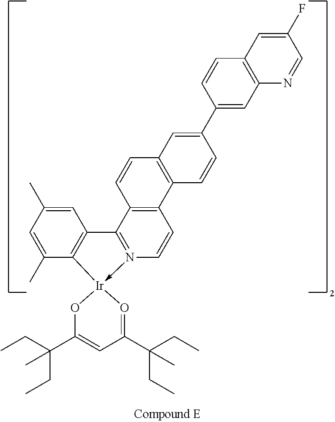

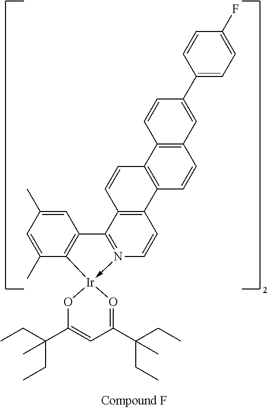

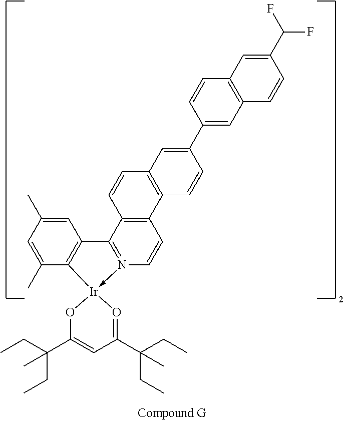

### Comparative Example 1

An organic light emitting element having a configuration in which an anode, a hole injection layer, a hole transport layer, an electron blocking layer, a light emitting layer, a hole blocking layer, an electron transport layer, and a cathode were provided in this order on a substrate was prepared by the following method using the compound A as a guest compound in the host molecule of the light emitting layer.

An ITO was formed into a film with a film thickness of 100 nm as an anode on a glass substrate using a sputtering method, and this film was used as a transparent conductive support substrate (ITO substrate). The organic compound layers and the electrode layers described below were continuously formed on the ITO substrate by vacuum deposition and by resistance heating in a vacuum chamber at 10⁻⁵ Pa. Here, the preparation was performed such that the electrode area reached 3 mm².

Hole injection layer (10 nm) HT16
Hole transport layer (30 nm)
Electron blocking (EB) layer (10 nm)
Light emitting layer (30 nm) host material, guest material:
compound A (4 wt %)
Hole blocking (HB) layer (20 nm)
Electron transport layer (20 nm)
Metal electrode layer 1 (1 nm) Liq
Metal electrode layer 2 (100 nm) Al

Next, the organic light emitting element was covered with a glass plate for protection in a dry air atmosphere and sealed with an acrylic resin-based adhesive material so that the organic light emitting element did not undergo element deterioration due to adsorption of moisture. In this manner, the organic light emitting element was obtained. IVL (current-voltage-brightness) measurement was performed on the obtained organic light emitting element by using the ITO electrode as an anode and the Al electrode as a cathode. The external quantum efficiency (relative value) of the organic light emitting element at 5 mA/cm² is listed in table 2. Here, the external quantum efficiency of the organic light emitting element formed of the compound (12) in Example 6 at 5 mA/cm² was set to 100%.

### Comparative Examples 2 to 7

In Comparative Examples 2 to 7, organic light emitting elements were prepared in the same manner as in Comparative Example 1 except that the guest material was changed to the compounds B to G listed in Table 1. Further, IVL measurement was performed on each of the obtained elements in the same manner as in Comparative Example 1. The results are listed in Table 2.

### Examples 2 to 15

In Comparative Examples 2 to 15, organic light emitting elements were prepared in the same manner as in Comparative Example 1 except that the guest material in the present example was changed to the compounds (1) to (45) listed in Table 1. Further, IVL measurement was performed on each of the obtained elements in the same manner as in Comparative Example 1. The results are listed in Table 2.

The compounds according to the present invention in Examples 2 to 15, which had a benzene ring, a naphthalene ring, or a benzoisoquinoline or naphthoisoquinoline skeleton containing a C4-C10 heterocyclic group in the ligand and had a permanent dipole moment of 1.5 or less, had greatly improved external quantum efficiency at 5 mA/cm² as compared with the compound having no benzene ring and having a permanent dipole moment of 1.5 or greater (Comparative Example 1) and the compounds corresponding to General Formula [1] or [2], but having a permanent dipole moment of 1.5 or greater (Comparative Examples 2 to 7). In this manner, the efficiency of the organic light emitting element can be improved by using a compound having a specific ligand structure with a small permanent dipole moment.

Further, the compound (1), the compound (3), the compound (6), the compound (8), the compound (15), the compound (16), the compound (20), the compound (31), the compound (33), and the compound (45), in which R¹² according to the present invention had a substituent with a para Hammett constant of 0.5 or greater, had improved efficiency as compared with the compound (12), the compound (19), the compound (24), and the compound (34), in which R¹² did not have a substituent with a para Hammett constant of 0.5 or greater. That is, this indicates that the compound according to the present invention had an effect of further improving the efficiency by proving a substituent with a para Hammett constant of 0.5 or greater at R¹².

TABLE 2

| | | External quantum |
|---|---|---|
| | | efficiency 5 |
| Preparation Example of | | mA/cm² (absolute |
| organic light emitting element | Compound | value: %) |
| Comparative Example 1 | Compound A | 87 |
| Comparative Example 2 | Compound B | 89 |
| Comparative Example 3 | Compound C | 93 |
| Comparative Example 4 | Compound D | 91 |
| Comparative Example 5 | Compound E | 93 |
| Comparative Example 6 | Compound F | 94 |
| Comparative Example 7 | Compound G | 87 |
| Example 2 | Compound (1) | 109 |
| Example 3 | Compound (3) | 108 |
| Example 4 | Compound (6) | 105 |
| Example 5 | Compound (8) | 112 |
| Example 6 | Compound (12) | 100 |
| Example 7 | Compound (15) | 107 |
| Example 8 | Compound (16) | 107 |
| Example 9 | Compound (19) | 102 |
| Example 10 | Compound (20) | 109 |
| Example 11 | Compound (24) | 102 |
| Example 12 | Compound (31) | 107 |
| Example 13 | Compound (33) | 111 |
| Example 14 | Compound (34) | 103 |
| Example 15 | Compound (45) | 110 |

As described above, according to the iridium complex according to the present invention, the element life of the organic light emitting element was found to be improved.

According to the present invention, it is possible to provide an iridium complex with a small permanent dipole moment and an organic light emitting element with high emission efficiency.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An iridium complex which is represented by General Formula [1] or [2],
wherein the iridium complex has a permanent dipole moment of 1.5 or less, 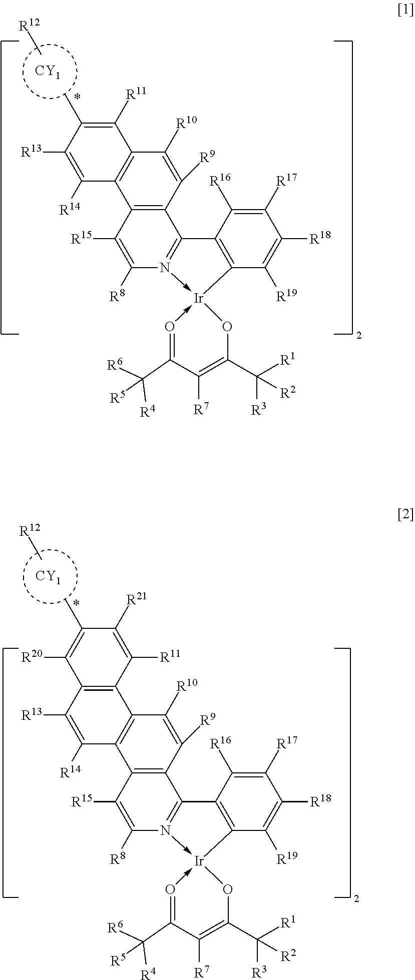
in General Formulae [1] and [2], R¹ to R²¹ each independently represent a hydrogen atom, a deuterium atom, a halogen atom, a substituted or unsubstituted alkyl group, a substituted or unsubstituted aryl group, a substituted or unsubstituted heterocyclic group, a substituted or unsubstituted alkoxy group, a substituted or unsubstituted aryloxy group, a cyano group, or a silyl group, and CY₁ represents a group represented by any of Chemical Formulae [3-1] to [3-3],
in Chemical Formulae [3-1] to [3-3], R²² to R²⁷ each independently represent a hydrogen atom, a halogen atom, a substituted or unsubstituted alkyl group, a substituted or unsubstituted aryl group, a substituted or unsubstituted heterocyclic group, a substituted or unsubstituted alkoxy group, a substituted or unsubstituted aryloxy group, a substituted or unsubstituted amino group, a cyano group, or a silyl group, and X₁ to X₆ represent a carbon atom or a nitrogen atom.

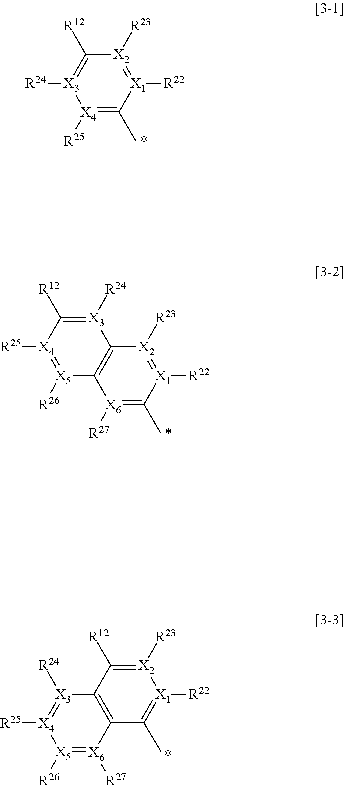

2. The iridium complex according to claim 1,
wherein R¹² represents an electron-withdrawing substituent with a para Hammett constant op of 0.5 or greater.

3. The iridium complex according to claim 1,
wherein R¹² represents —CF₃, —CN, —COF, —CF(CF₃)₂, —OCF₃, or —SiF₃.

4. The iridium complex according to claim 1,
wherein the iridium complex has a permanent dipole moment of 1.0 or less.

5. The iridium complex according to claim 1,
wherein CY₁ represents a benzene ring.

6. The iridium complex according to claim 2,
wherein R¹² represents —CF₃.

7. The iridium complex according to claim 1
wherein R¹⁷ to R¹⁹ represent a substituted or unsubstituted alkyl group.

8. The iridium complex according to claim 7,
wherein R¹⁷ to R¹⁹ represent an alkyl group having 1 to 4 carbon atoms.

9. The iridium complex according to claim 8,
wherein R¹⁷ to R¹⁹ represent a methyl group.

10. The iridium complex according to claim 1,
wherein the iridium complex is represented by the following structural formula.

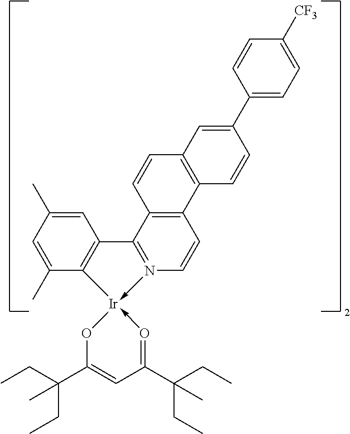

11. A light emitting ink composition comprising:
the iridium complex according to claim 1;
a first organic compound; and
a solvent.

12. An organic light emitting element comprising:
a first electrode;
a second electrode; and
an organic compound layer disposed between the first electrode and the second electrode,
wherein the organic compound layer contains the iridium complex according to claim 1.

13. The organic light emitting element according to claim 12,
wherein the organic compound layer includes a light emitting layer, and
the light emitting layer contains the iridium complex.

14. The organic light emitting element according to claim 13,
wherein the light emitting layer contains the iridium complex and a first organic compound, and
the first organic compound has a minimum excited singlet energy greater than a minimum excited singlet energy of the iridium complex.

15. The organic light emitting element according to claim 13,
wherein the light emitting layer contains a second organic compound different from the first organic compound, and
the second organic compound has a minimum excited triplet energy less than a minimum excited triplet energy of the first organic compound and greater than a minimum excited triplet energy of the iridium complex.

16. A display device comprising:
a plurality of pixels,
wherein at least one of the plurality of pixels includes the organic light emitting element according to claim 12 and a transistor connected to the organic light emitting element.

17. An imaging device comprising:
an optical unit that includes a plurality of lenses;
an imaging element that receives light allowed to pass through the optical unit; and
a display unit that displays an image captured by the imaging element,
wherein the display unit includes the organic light emitting element according to claim 12.

18. An electronic device comprising:
a display unit that includes the organic light emitting element according to claim 12;
a housing where the display unit is provided; and
a communication unit that is provided in the housing and communicates with an outside.

19. A lighting device comprising:
a light source that includes the organic light emitting element according to claim 12; and
a light diffusion unit or an optical film that transmits light emitted by the light source.

20. A moving body comprising:
a lamp that includes the organic light emitting element according to claim 12; and
a machine body where the lamp is provided.
